(19) United States
(12) Patent Application Publication
(10) Pub. No.: US 2025/0157685 A1
(43) Pub. Date: May 15, 2025

(54) CONDUCTIVE LINE, TRANSFER DEVICE, AND SPACE SOLAR BEAM ENERGY TRANSPORTATION METHOD

(71) Applicant: Katsuya NISHIZAWA, Nagano (JP)

(72) Inventor: Katsuya NISHIZAWA, Nagano (JP)

(21) Appl. No.: 18/959,705

(22) Filed: Nov. 26, 2024

Related U.S. Application Data
(63) Continuation-in-part of application No. PCT/JP2023/017215, filed on May 7, 2023.

(30) Foreign Application Priority Data
May 26, 2022 (JP) 2022-086263
Aug. 2, 2022 (JP) 2022-123161
Nov. 14, 2022 (JP) 2022-181631
Jan. 22, 2023 (JP) 2023-007722
Apr. 9, 2023 (JP) 2023-063114
Apr. 24, 2023 (WO) PCT/JP2023/016185

(51) Int. Cl. G21K 1/00; H02J 7/34

(52) U.S. Cl. CPC G21K 1/00; H02J 7/345; H02J 2207/50

(57) ABSTRACT

This application presents ideas for devices that solve energy generation problems and space exploration. This application show idea that is using device such using conductor/element or device. And this application show idea that is using device such using conductive line or carrier device. This application show idea that is using device such using photon or particle related device.

### TECHNICAL FIELD

This application claims the benefit of foreign priority to Japanese Patent Application No. JP2022-086263, filed May 26, 2022, which is incorporated by reference in its entirety.”

“This application claims the benefit of foreign priority to Japanese Patent Application No. JP2022-181631, filed Nov. 14, 2022, which is incorporated by reference in its entirety.”

“This application claims the benefit of foreign priority to Japanese Patent Application No. JP2022-123161, filed Aug. 2, 2022, which is incorporated by reference in its entirety.”

“This application claims the benefit of foreign priority to Japanese Patent Application No. JP2023-007722, filed Jan. 22, 2023, which is incorporated by reference in its entirety.”

“This application claims the benefit of foreign priority to Japanese Patent Application No. JP2023-063114, filed Apr. 9, 2023, which is incorporated by reference in its entirety.”

“This application claims the benefit of foreign priority to PCT Application No. PCT/JP2023/016185, filed Apr. 24, 2023, which is incorporated by reference in its entirety.”

“This application claims the benefit of foreign priority to PCT Application No. PCT/JP2023/017215, filed May 7, 2023, which is incorporated by reference in its entirety.”

“This application claims the benefit of foreign priority to Japanese Patent Application No. JP2024-058388, filed Mar. 31, 2024, which is incorporated by reference in its entirety.”

The present application is an invention for the transmission of energy from the space side to the ground or the air during space solar power generation by means of radio, laser, or fuel material (paragraph 0060, etc., contents of priority application 2), and an invention for wired power transmission and utilization by means of an orbital elevator or airborne platform and conductors, This application discloses a device for lightning protection using the method and equipment used in the above-mentioned transmission (paragraph 0061, related to priority claim application 4, priority claim application 3, etc.).

This application discloses three types of energy transmission from outer space to the earth (or a planet, satellite, or celestial body): wired, wireless, and fuel transportation.

This application also includes an idea (paragraphs 0001-0059) to use the phenomenon that occurs when an electric double layer transistor (or field effect transistor such as MISFET or MOSFET) is operated as a conductor, wiring, or electrode.

(This application has not been demonstrated to work at the time of filing.

### BACKGROUND TECHNOLOGY

This application relates to sheet, film, foil and wire conductor elements or wiring materials using carrier introduction by electric double layer transistors. Furthermore, this application relates to electronic components and devices such as motors, actuators, batteries, etc., using said wiring materials.

Also, using the fact that said conductor element can control the introduction of carriers into the conductor 101 by the gate electrode section 106,

Using a sensor of an input device that detects the environment in which said conductor element 1 is placed, and a control unit that controls the input of said sensor and the gate electrode 106.

The conductive element can control the high and low conductivity according to the measurements of the sensor (FIG. 10).

In the high state, carriers are introduced into 101 by the gate to form 104 and increase the positive conductivity, while in the low state, the gate is turned off and 101 is turned on, The low state is when the gate is turned off and no carriers are introduced into 101, or when the ionic species in the electrical double layer generated in 105 work to reduce the conductivity of the 104 portion of 101.

We propose to use the conductive element 1 of the present application containing 101 that can form the aforementioned 104 as a battery electrode.

As an example of the effect of controlling the high and low conductivity of the aforementioned by 106.

For example, there is an example in which said gate electrode 106 is turned on during charging and discharging of the battery, and 106 is turned off during storage of the battery or before the battery encounters an accident to reduce conductivity.

A battery that includes a sensor and a control unit will cause the control unit to turn 106 off when it senses a shock or acceleration, making the electrodes less conductive and preventing a short circuit with rapid discharge when the electrodes of the positive and negative electrodes contact each other with high conductivity during an internal short circuit (FIG. 9).

As shown in (b) and (a) of FIG. 1 of this application (or as shown in Representative FIG. 1 of the patent document).

There is a conductive layer 101 of conductive conductor, semiconductor or conductive polymer layer or carbon-based material (such as CNT or graphene graphite), there is a source electrode 102, drain electrode 103, gate electrode 106, and an ionic liquid of molten salt for example between 102-103 and 106 There is, (with 102 as GND).

Applying potential VGS to 106, 106 is charged and the ions contained in insulating layer 105, which can form an electric double layer, are aligned around 106 to form an electric double layer so that the VGS of 106 cancels out the VGS of 106.

It also forms a capacitor.

(Insulating layer 105 can be a separator layer such as a secondary battery containing ionic liquids.)

The result,

An electric double layer also appears near the carrier introduction layer 104 (inversion layer 104 in a MOSFET) of 101, (in a field-effect transistor) by the electric field effect, Carriers are introduced into the aforementioned 104 of the semiconductor substrate 101 (or conductor substrate 101, carbon conductor substrate 101, conductive polymer substrate 101, organic semiconductor substrate 101, carbon-based conductive material substrate 101, substrate 101 on which electricity can flow), and the carrier density n increases in the carrier introduction layer 104 of 101.

The configuration in which a protective layer 107 is placed over the carrier introduction layer 104 is known in the patent document 1.

In some cases, the protective layer 107 can be used in this application as well.

The 107 prevents electrochemical, etching, and other reactions from occurring in 104 and 101 at gate voltages that exceed a certain threshold in an electric double layer transistor. (Since this application is not an invention concerning protective layers, the explanation is omitted.)

<MISFET and electric double layer transistor>.

A capacitor is formed by 105, and 104 and 106 that sandwich 105.

When 105 is an insulating film, it is an MISFET.

When 105 contains an ionic liquid, it is an electric double-layer transistor with an electric double-layer capacitor section.

In the electric double-layer transistor,

At the interface between 104 and 105, the ions in the ionic liquid form an electric double layer to balance the charge in 104, forming an electric double layer capacitor in the 104-105-106 section.

The thickness of the layer in the electric double layer section is said to be in the 1 nm class.

In the electric double layer transistor,

By forming an electric double-layer capacitor such as ionic liquid, more charge can be stored in 104 than in the capacitor by the insulating layer of MISFET.

The principle or method is applied to this application,

In this application,

Using conductors 101, 101P, and 1012 of organic semiconductors, conductive polymers, carbon-based materials including graphite, graphene, and carbon nanotube CNTs, (and films of other general-purpose metals such as iron) as conductors (or conductors/semiconductors) to form 104 and 1042,

The gate electrode 106 and the insulator layer 105 (which can form an electric double layer) are provided, and VGS is applied to form 104 and 1042 to improve the conductivity of the conductors including 104 and 1042 and 104.

Also, In batteries with high electromotive force or energy density, or batteries that use flammable electrolyte or other materials, using the fact that the formation of 104 (and 104I, which acts to reduce conductivity contrary to 104 depending on the type of 101 material) is controlled by the voltage value of VGS applied using 106, The environmental data (acceleration, etc.) in which the battery is placed, which can lead to battery damage, is detected by the sensor of the input device.

VGS is controlled so that it does not produce 104 to reduce the conductivity of the battery electrodes that use 104.

We propose to reduce the conductivity of the electrodes to prevent internal shorts of electrode origin when the battery is stored, damaged, or before it is destroyed (FIGS. 9 and 10)

The 108 of the body B section can be defined in 101 as shown in FIG. 2.

105 in FIGS. 1 and 2 can form an electric double layer, in which case 105 can be made thinner.

The scales of 101 and 101P, 104, and 105 in the drawings are not described to match the scales of the actual product.

(This is a schematic diagram.)

MISFET: Abbreviation for Metal-Insulator-Semiconductor FET.

In MISFETs and electric double-layer transistors, the capacitor section of the gate electrode is configured to be charged with electric charge.

The self-discharge of the capacitor section should be small.

The gate leakage current and leakage current should be low.

### <Dielectric Breakdown of Gate Section>

The gate part of the conductor element constitutes a capacitor, but there is a limit to the VGS that the capacitor can withstand (absolute maximum rated voltage VGSA between GS), and if a high voltage VGS is applied, the insulation of the gate part is destroyed.

If a voltage exceeding VGSA is 106 applied, the aforementioned capacitor section is destroyed and 104 can no longer be formed.

(P2 in FIG. 9)

<Fuse-like 2-terminal type conductor using breakdown of the gate section

On the other hand, when the device of this application is used as a 2-terminal wire 1-2TER as shown in (B) of FIG. 8, the voltage applied to said 2 terminals has an absolute maximum rating value due to VGSA.

When a voltage exceeding VGSA is applied to the 1-2TER at 106, the capacitor is destroyed and 104 is lost, and the conductivity between the two terminals of the 1-2TER that lost 104 may be used like a fuse.

When multiple 1-2TERs are connected in series as a conductor 1WIRE and used in a network for power transmission, when lightning strikes and a high voltage is applied such that 106 exceeds VGSA, the capacitor part is destroyed in the conductor, 104 is gone and the conductivity of the 1-2TER is reduced, making it difficult for current to flow between the two terminals of the 1-2TER, which may have the effect of preventing large currents from flowing and spreading across the power grid that includes multiple 1-2TERs.

### <Conductivity Perspective>

Conductivity SIGMA is SIGMA=1/Resistivity RHO=Charge q×Carrier density n×Carrier mobility MU and,

The above 104 with increased carrier density n can increase conductivity SIGMA.

In this application, this mechanism is used to Carriers are introduced and injected into conductors and semiconductors, increasing said density n, the conductor element 1 using 104 with increased conductivity is proposed.

In addition, the resistance R of the conductor is,
R=resistivity RHO×conductor length L/area A
and R=resistivity RHO×conductor length L/area A,

For the cross-section of an object,

The area A that contributes to conductivity should be large.

Carrier density n is the ratio of the carrier density of inorganic materials to the carrier density of inorganic materials.
10 to the 22nd to the 23rd power for metals,
10 to the 17th power for semiconductors, insulators to the power of 10 to the fourth power.

There are also chemically doped conductive polymers with high carrier density.

In this application, organic semiconductors with high mobility, CNTs, graphene, graphite, and other carbon materials, as well as iron and other resourceful materials are used as 101 to increase the carrier density by electric double-layer transistors (even without chemical doping), And

We propose to use it as a conductor device that can control the conductivity by controlling the voltage of the gate electrode.

If the carrier density n can be increased to the 20-21 power of 10 or more in the electric double layer transistor, it may be possible to form a conductive element 1 with high conductivity by combining it with an organic semiconductor with high mobility.

In the configuration of stacking 1012 on 101P in FIG. 11, 1012 can be a thin metal film and 101P can be a porous film made of conductive carbon-based material, and we propose to increase or decrease conductivity by forming a carrier introduction layer 104 (and 104I) on the metal film 1012 while reducing the usage amount of metal elements.

Even for carbon materials such as CNTs, which are expected to have high mobility, it may be possible to make a good conductor by multiplying the high mobility with the high carrier density due to the formation of the electric double layer.

<101P to increase the area of the carrier introduction layer 104

The resistance R of a conductor is R=resistivity RHO×conductor length L/conductor area A,

For the cross-section of an object, it is preferable that the area A contributing to conductivity can be increased.

As shown in (a) of FIG. 1 and FIG. 11, 104 formed at the interface of the conductor element 1 with flat 101 and 105 can be considered thin with its thickness of about 1 nm,

There may be a problem that the area that becomes the 104 part to improve the conductivity of the conductor (conductor area A mentioned earlier) is small, and even if 104 is formed, the resistance R of the conductor element cannot be lowered as intended.

Therefore, By forming 104 using 101P including a comb shape, rod, pillar, and porous layers as shown in (b) and (c) of FIG. 11, or by forming a layer of second conductor 1012 on top of 101P by stacking, depositing, etc., and forming a carrier introduction layer 1042 on 1012, 104 or 1042 with a larger area of conductivity than the area of 104 that occurs in the flat 101 and 105 in (a) of FIG. 11, the conductor area A area can be increased, and the conductivity of the conductor can be improved (by reducing the resistance R of the conductor).

(101P can be used to increase the surface area per volume of conductor that can form an electric double layer, and the area where the carrier introduction layer 104 or 1042 is formed (conductor area A) can be increased.)

Comparing the cross-sectional schematic diagrams of devices (A), (B), and (C) in FIG. 11, the configuration of (B) and (C) is such that 104 and 1042 can be taken as a larger area than in (A), so the configuration using 101P as in FIG. 11 (B) and (C) is preferably used in this application.

In addition, in metallic materials, the metal can corrode.

Furthermore, in metallic materials,

Although it is necessary to prevent metal from corrosion, etc. (it may be necessary to protect the material with a protective layer as in Patent Document 1), it is not necessary to protect the metal from corrosion, etc,

A general-purpose metal such as iron, which is ubiquitous in the earth (including aluminum, copper, etc. to reduce the amount of metal used in conductors and save resources and weight), is laminated and deposited on a porous conductive carbon material conductor 101P as 1012,

The carrier introduced 1042 may be formed by an electrical double layer formed on the surface of said 1012,

For example, the conductor element 1 may be formed by 1042 formed in 101P within the porous electrode.

### <Application of Element 1>

We propose to form 104 in films of organic semiconductors, conductive polymers, carbon materials, and metallic materials such as iron, and to use them for the conductive parts of electrodes in secondary batteries and conductors in motors.

### <Film Electrode Applications>

We propose the use of conductor element 1 in the form of film, sheet or foil for electrode type conductor element 1FILM, conductor part of electrode of secondary battery, conductor part of semiconductor devices such as solar battery, light receiving element, light emitting element, etc., and hardware such as display device, computer, robot, vehicle, aircraft, transportation device, etc.

We propose the use of 1FILM as shown in FIGS. 6, and 2ACT actuator using EAP.

The use of metal electrodes in actuators may be reduced to lower the cost and weight of metal resources.

In robot suits and space suits worn by humans, if the weight of secondary batteries and actuators/motors can be reduced, the aforementioned suits may become lighter and easier for humans to carry.

### <Conductor Applications>

We propose to use the conductor element 1 as a conductor type element 1WIRE as shown in FIG. 5 for the conductive part of electric wires and motors.

The above-mentioned conductor element 1 and 1WIRE are also envisioned for internal wiring, power distribution, and power transmission applications in power transmission and distribution networks, aerial platforms, base stations, and structures.

In the configuration shown in FIG. 5, the conductors are arranged as 106, 105, 104, and 101 from the center of the cross-section of the conductor, but in a configuration in which this arrangement (1WIRE) is reversed (1WIRE2), they could be arranged as 101, 104, 105, and 106 from the center of said cross-section.

In FIG. 5,

106 at the center of the conductor is a gate electrode made of a composite material of a metallic fiber such as aluminum and a carbon-based conductive material, and is placed at the center of the cross section as a gate electrode and wire core material,

A voltage is applied to 106 to electrify it,

A capacitor is formed with 105 and 104 of 101 surrounding it, and 101 (the outer conductor of the coaxial cable) including 104 is used as the conductor of the conductor.

1WIRE 106 to withstand mechanical forces such as bending as a conductor,

For reasons such as the aforementioned composite material's ability to be used as a gate electrode for applications that store electrical charges, we devised a configuration of 1WIRE conductor with 106, which can be made into the composite material described in FIG. 5, as the central core wire.

The 1WIRE in FIG. 5 is one of the examples of conductors in the conductor element of this application,

The form of the conductor type conductor element of this application is not limited to the example shown in FIG. 5.

For example, 1FILM may be processed (patterning, cutting, etching, etc.) to make a conductor device.

<Whether the gate electrode is built into the conductor element 1>

The 3-terminal and 2-terminal elements described in FIG. 8 were considered in this application.

The 1WIRE and 1FILM of this application are 3-terminal elements that use a gate electrode 106.

On the other hand,

For example, for use in applications where conductive films and conductors are joined together to form long wiring,

A 2-terminal device was considered.

FIG. 8 (b) shows a 2-terminal conductor element 1 (1-2TER).

When the conductor 101 of conductor element 1 is a semiconductor, the 1-2TER operates like a so-called constant-current diode in which the source and gate of a FET are shorted.

Even when the conductor 101 is a conductor such as carbon-based material, etc., it cannot flow more than the allowable current.

U1 is the gate driver section (or resistor, etc.) that drives the gate 106 from Vcc during high-side switching.

There may be a resistor between SG and S.

U1 may include a sensor, gate drive circuit, and control unit.

In the configuration of (B) above, it may be possible to drive 106 from Vcc by U1 when wires are connected to each other and potential is applied, and conductor elements employing 1-2TER may be easier to handle as conductors or conductive films, sheets, or electrodes than 3-terminal types.

For use in the power generation part of large-scale solar cells in ground and space solar power plants, space structures, space stations, etc,

In the case of 1-3TER, it is assumed that a circuit to drive the gate electrode and its wiring network can be provided,

However, with the 1-2TER, the application of voltage to the gate electrode can be done internally with the 1-2TER, facilitating the construction of large-scale solar power generation systems and large-scale circuits.

In addition to solar cells, the 1-2TER can also be used in conductor elements used for electrodes and wiring of electronic components, batteries, motors, actuators, sensors, and other devices.

Conductor element 1 can be operated as a low-side switch type instead of a high-side switch type, or as an example of an electric circuit of a general transistor component.

(Conductor element 1 is also a transistor.)

The advantage of the 3-terminal type is that the magnitude of the voltage VGS applied to 106 and the polarity of VGS can be varied.

For example, in the thermoelectric conversion element 2TCE shown in the drawing, It is possible to apply voltages that may have different polarity and magnitude to the n-type and p-type semiconductor sections individually, n-type and p-type materials in completely different material systems.

The p-type material has more carriers and the n-type material has fewer carriers, even if there is a difference in carrier density.

The voltage of the n-type gate electrode is higher than that of the p-type gate electrode,

The voltage of the n-type gate electrode can be made higher than that of the p-type gate electrode to artificially generate carriers in the n-type section, which may be controlled as the amount of carriers commensurate with the p-type.

### <Use in Thermoelectric Conversion Elements>

A thermoelectric conversion element 2TCE using the aforementioned 104 with increased carriers is devised.

If 1 is a P-type or N-type semiconductor and the carrier density can be increased by controlling the gate electrode while maintaining semiconductor mobility, it may be possible to use it in a thermoelectric conversion device.

As shown in FIG. 11, the thermoelectric conversion device may be made with gate electrodes 106N, 106NG and 106P, 106PG corresponding to N-type and P-type, respectively, and voltage VGSN can be applied to 106N and voltage VGSP to 106P, respectively, thus increasing the carriers in the P-type and N-type portions.

In addition, if it is possible to increase the carrier density of carbon-based materials, especially organic semiconductors and some inorganic semiconductors (including inorganic semiconductors such as copper oxides as shown in Patent Document 1 and perovskite semiconductors used in so-called perovskite solar cells), the restriction on the resources of certain elements will be removed and the amount of resources will be limited. If it is possible to increase the carrier density of even perovskite semiconductors (including perovskite semiconductors used in solar cells), it may become possible to mass-produce thermoelectric conversion devices by using 104(101) semiconductor materials with unlimited resources. (Known thermoelectric conversion devices use Bi2Te3 alloys, which use Te and other elements with limited resources.)

When thermoelectric elements are widely used from wearable devices to waste heat power generation, physical batteries for satellites, and thermal batteries, and especially when they are widely used for wearable applications, it may be desirable to be able to produce them inexpensively and in large quantities.

<When conductor element 1 uses semiconductors and insulators>

When 101, 101P, and 1012 of 1 are made to form 104 and 1042,

The combination of 101 and 1012 may be used to form not only 101 and 1012 of the conductor, but also 101 and 1012 of the material part of the combination that behaves as a semiconductor.

For example, if 1012 is
Aluminum nitride AlN
(and boron nitride BN and boron nitride nanotubes BNNT,
silicon carbide SiC, and
gallium nitride GaN,
Diamond C,
Titanium oxide TiO2,
tin oxide SnO2,
zinc oxide ZnO,
indium tin oxide ITO,
indium gallium zinc oxide IGZO)
Semiconductor layers with high band gap Eg (of materials that can be taken as insulators in everyday life), such as AlN with high Eg (such as AlN with high Eg), (said semiconductor/insulator such as AlN with high Eg) 1012 may be formed to function as n-type or p-type semiconductor layer 1042.

A semiconductor device may be configured using said 1042.

The aforementioned 1042 may be used to configure electrodes or transparent electrodes (including solar cells, light emitting devices, laser devices, ultraviolet laser devices, EL or LCD display devices).

101 and 1012 include graphene, CNTs, some organic semiconductors, and the said ZnO, SnO2, TiO2, ITO, and IGZO are materials used for transparent electrodes.

101, 101P and 1012 include semiconductors and conductors.

For example, they may include group 14 elements listed in the periodic table of elements, said group 14 elements may include diamond C as a high band gap material, silicon Si and germanium Ge as low band gap semiconductor materials, and tin Sn and lead Pb as conductor materials.

### BACKGROUND OF THE APPLICATION

The first reason is to reduce the use of copper due to the rising cost of metal resources caused by the increasing demand for electric vehicles.

However, hybrid electrodes combining carbon materials or conductive polymers with electrodes made of mesh of aluminum or copper may also be used in this application device, however. The intention of this application is to reduce the amount of copper and other metals used for wiring materials.

This application is not limited to the use of copper.

A gate electrode containing aluminum may be used in 106 to form 104.

The second reason is the problem of recycling metal resources for large equipment, structures, and buildings used in space.

The inventor discloses the wiring and electrodes of large solar cells and secondary batteries, or aircraft, spacecraft, satellites, and structures (orbital rings, orbital elevator devices) containing the aforementioned electronic components in Patent Document 2, JP A 2022-058853, or JPA 2022-105726, etc., related to said Document 2. (orbital ring device, orbital elevator device) that contain the aforementioned electronic components.

The structures and aircraft claimed in the second patent document may include secondary batteries, e.g., lithium ion batteries, for electric aircraft as well as electric vehicles, said lithium ion batteries including copper foil and aluminum foil.

For solar cells as well, metal electrodes are utilized, although the electrodes are not as thick as those of lithium-ion batteries.

The equipment and structures are proposed to be incinerated upon atmospheric entry after mission accomplishment.

If the device/structure contains copper, a finite resource, it will be incinerated and fall to somewhere on Earth, such as the oceans, after atmospheric entry.

When incineration residue containing copper falls into the ocean, mixes, sinks, and spreads, then, recovery of copper resources (like as recycling copper from home appliances above ground) is difficult.

Metallic elements launched from the ground may diffuse and become rarefied when they fall to the ground, such situation making reuse and resource recovery difficult.

When a large structure in space needs to be replaced after its service life, it would be desirable to exchange parts for renewal by low-cost transportation means (so-called orbital elevators, etc.) between space and the ground.

Even if the structure does not contain metal atoms, it may contain sulfur, which leads to the generation of SOx, for example, and a large amount of sulfur may become SOx upon atmospheric entry, resulting in a high environmental burden.

It would be highly desirable if parts to be renewed could be exchanged in so-called orbital elevators, etc.

However, (Preferably, it would be much more desirable if the parts to be renewed could be exchanged by a so-called orbital elevator, etc.). But, in case a large structure has an accident and burns down to the ground, or if it is necessary to reduce the labor required to manually or robotically retrieve a large structure, even by means of an orbital elevator,

There may be times when it is desirable to remove a structure from orbit and incinerate it by atmospheric entry (or incinerate it as a result of an accident) all at once (like blowing up and demolishing a building on the ground).

If this is done repeatedly, the construction and utilization of large-scale structures in space may not be sustainable in the future (and may not lead to sustainable development).

The third reason is resource-saving actuator applications for robots.

In electric vehicles, a large proportion of the equipment is rechargeable batteries. Among robots, including vehicles, unmanned aerial vehicles, and humanoid and multi-legged robots, those that have a long travel distance after recharging, such as transportation equipment, may use more metal resources in their batteries.

On the other hand, humanoid, multipedal, and other robots with short travel distances that are connected to the power grid and receive power supply can reduce the capacity of rechargeable batteries and energy storage devices. And motors and actuators for movement (including artificial muscles and actuators using dielectric elastomers as described in Non-Patent Document 1) and wiring materials are expected to account for a higher proportion of the cost of the product.

If the use of copper and other resources for motors, actuators, and power distribution materials could be reduced, metal resources would be less restricted, and this might contribute to the widespread use of robot products.

I/We also believe that it is necessary to reduce the weight of batteries and motors for robots and robot suits.

The fourth reason is lightweight actuator and wiring material applications.

If copper wiring (and aluminum wiring) can be made into carbon-containing materials in the applications mentioned in the three reasons above, it may lead to weight reduction of wiring materials for motors, actuators, and batteries.

For example, when lithium-ion polymer batteries used in mobile computers and drones are disassembled, it can be confirmed that the metal components that make up most of the battery are the active material-coated aluminum electrode and copper electrode.

Therefore, we thought that if we could reduce the amount of metal used, it would lead to weight and cost reductions in batteries, vehicles, airplanes, and robots.

This application is intended to construct lightweight electric wires, motors, and batteries.

Various machines and devices that use motors and batteries, transportation equipment such as electric vehicles, electric aircraft, and drones, industrial machinery such as electric agricultural machinery and ships, office and industrial machinery such as printers and processing machines, refrigerators, For household appliances such as washing machines and portable/battery-powered vacuum cleaners, electric wires, and mobile computers. For wearable devices.

For the above four reasons/perspectives, the challenge is to reduce the amount of metal used in wiring materials, wiring components, and electrodes,

In order to solve this problem, this application proposes the idea of incorporating a means of generating an electric field effect in wiring materials and electrodes so that carbon materials and organic conductive materials, which are usually not as conductive as metal materials, can be used to increase the carriers in the electric double layer transistor mechanism.

We also propose motors, actuators, electronic components, electrodes, battery electrodes, and batteries that incorporate the aforementioned means.

For safe devices and systems, this application proposes a mechanism to improve conductivity in carbon-based conductive materials, which are considered to have a less restricted amount of elements, and proposes a system 3 (3.3WIRE, 3BATT) to detect danger and change conductivity in electronic components and batteries using the above mechanism.

<Remarks>—The inventor believes that in the short term, there will be no problem if space development is conducted with devices and structures such as copper.

In addition, the aforementioned metals should be used for devices that must be made of copper and other metals not only for their electrical conductivity but also for their mechanical material properties and various other properties.

However, in the long term, assuming that humans will expand into space and operate in space, we believe that it may not be desirable to reenter the earth and disperse the earth's copper resources (finite resources) in a state that is difficult to recycle, and we propose the aforementioned element 1.

In terms of abundance of resources, the Earth and near-Earth satellites and planets (Venus and Mars) have carbon, which is the basis for the carbon-based conductive materials that we wish to utilize in this application.

(In addition to C, silicon Si may also be used to form conductive elements by this method; Si has been confirmed on the Moon in the form of SiO2.)

The conductor 101 is a carbon-based conductor that can be used as a copper electrode foil in a secondary battery or as a conductor in a motor.

The 101 conductors of this application are carbon-based conductors (including graphite, graphene, carbon nanotubes, and may include organic semiconductors, conductive polymers, inorganic semiconductors, inorganic conductors, and metals such as iron).

### <Examples or Assumptions>

<Battery with High Energy Density>

When the conductor element of this application is used as a foil element in a rechargeable battery, a lithium-ion battery containing ionic liquid or a rechargeable battery device with higher electromotive force than a lithium-ion battery using the wide potential window of ionic liquid can be assumed.

For example, a fluoride shuttle battery (FSB), a fluoride ion battery in which fluoride ions (anions) are transferred, is known in contrast to a lithium ion battery in which lithium ions (cations) are transferred.

The literature on fluoride ion batteries can be found in Patent Literature 3.

Paragraphs to of the Patent Document 3 describe the components of a fluoride ion battery (which may be a primary or secondary battery).

The FSB has a positive electrode current collector for collecting the positive electrode active material layer and an anode current collector for collecting the negative electrode active material layer.

The shape of the current collector is, for example, foil, mesh, or porous.

The electrolyte layer is said to be a liquid electrolyte.

In the present application, the current collector (201NEC and 201PEC, which are the negative and positive electrode current collectors) can be formed as a layer on top of 101, including the carrier introduced 104.

When 101 is a carbon material, the conductivity of the portion of 201NEC/201PEC close to 104 (the area of 201NEC/201PEC close to 101 near 104) may improve the current collection performance of the current collector and electrodes in the present application configuration with 104 than without 104.

### <Battery and Element 1 Including a Sensor>

The use of a PTC thermistor is known as an element to protect the battery in the patent document 4.

In this application, we propose a battery device including a sensor 3SEN, a gate driver 3CGATE, and a control section/control section 3C that controls the gate electrode 106 of the conductor element 1 of this application, in which a sensor attached to the battery can sense inputs such as a strong shock being applied to the battery.

A battery with high energy density (or high power density) should be prone to explosion or combustion, etc., when it is damaged by being skewered (bent inside the battery and damaged by the separator, etc.) in an accident or other accident, causing a short circuit in the internal electrodes, which releases the stored energy in the battery (by causing an internal short circuit). This is why we have developed this application.

Therefore, this application proposes a safety mechanism as shown in FIG. 9 and FIG. 10 in the event of an internal short circuit, such as when a battery is skewered by a nail or other means.

The signs (predictive signs: changes in impact/acceleration, changes in flight altitude, changes in speed, battery strain due to battery swelling or deformation of other components surrounding the battery, changes in sound such as collision noise, sound changes and abnormalities detected when ultrasonic waves are probed or echoed on the battery or other protected object, changes in odor, sensors to detect chemical substances, threats to batteries captured by cameras, atmospheric pressure changes, temperature changes) of an accident (accidents: Battery skewering, 3BATT on-board batteries being crashed or destroyed in a traffic accident, aircraft carrying 3BATT crashing, etc.) that destroys the battery are detected by the sensors in the control and control section,

then, by turning off the gate of the conductor element 1 of this application and lowering the conductivity of the internal electrodes of the battery,

and then by lowering the conductivity of the internal electrodes of the battery, the gate of the conductor element 1 is turned off to prevent accidents such as internal shorts between the electrodes of the internal positive and negative electrodes, which are in a highly conductive state, causing rapid discharge and ignition.

A battery for transportation equipment, such as an automotive battery or an aircraft, wherein said control unit in the battery

C1, an automotive computer mounted on the transportation equipment, and a camera mounted on C1 detects a danger in the external world of the transportation equipment (an object that is about to collide with itself by the camera),

C1 transmits the control signal to the battery controller 3CBATT through the signal communication path.

The 3CBATT then controls the gate driver circuit 3CGATE according to the received signal/data in accordance with the stored procedure, and the voltage VGS applied from 3CGATE to 106 of the 2BATT is varied to control the gate electrodes of the conductor elements.

The voltage control of 106 may then reduce or eliminate 104 of 101 or generate 104I and reduce the conductivity of the internal electrodes of the 2BATT.

### <Conductor Element 1 Whose Conductivity is Controlled by a Sensor>

Regardless of the form of the battery, even if it is in the form of an electrical conductor or a sheet, film, or foil electrode, it may be detected by the sensor/input device described above, and the VGS of the gate electrode may be controlled by the control unit according to the result.

Attach an acceleration sensor or a speedometer to the motor (actuator) to detect the speed as a sensor,

When the motor using the conductor element 1 is in a speed range higher than the specified speed or accelerating at an acceleration higher than the specified speed, it is detected by said sensor connected to the control section,

The gate electrode 106 may be controlled from said control unit to turn off the capacitor to reduce conductivity and prevent the motor from increasing its speed.

The sensor and control unit may also be used in the case of an actuator that can be used in a robotic suit.

The gate electrodes of the conductor element may be controlled according to the results of the external wireless communication input.

### <Applications for Electricity and Power, and Signaling Applications>

The conductor device that can be configured by this application is assumed to be used for electric power transmission.

The use for signaling applications is not denied.

The conductor element 1 of the present application may be used for wiring to detect sensors and sensor signals for sensing the aging and environment of various parts of buildings and structures (space structures, buildings, tunnels, roads, and other structures and buildings), which may be large in scale.

The aforementioned element 1 may be used for wiring of signals and electrical power to operate sensors or input devices including temperature sensors and cameras, and output devices including motors and buzzers.

### PRIOR ART LITERATURE PATENT DOCUMENT

### Non-Patent Document

The problem is to increase the carrier density of conductive materials and to improve conductivity.

The problem was also to be able to control conductivity, to construct a device that can control conductivity by performing the aforementioned control using the measurement results from a sensor as a starting point, and to provide a safe device and a safe battery.

In spacecraft, electric aircraft, electric vehicles, and electric transportation equipment, the reduction of metal usage in electrode materials of rechargeable batteries was a challenge.

I/We thought it was also necessary to reduce the metal usage in motors.

It was necessary to devise a carbon-based conductor wiring that could replace wiring materials such as metal foil and metal wire, which are used in rechargeable batteries and motors and have limited resources, or a conductor wiring that could reduce the use of metal materials.

The carrier density of carbon materials such as graphene and carbon nanotubes based on covalent carbon, carbon fibers, organic semiconductors, conductive polymers, and organic or inorganic semiconductors that can be fabricated by coating, is sometimes lower than that of metal conductors, so it was necessary to increase the carrier density n.

Carbon-based wiring materials such as carbon nanotubes, graphene, organic semiconductors, and conductive polymers, which contain many covalent bonds, tend to have a lower carrier density n than metals due to difficulties in carrier introduction, injection, and doping, even though they have high carrier mobility.

It is also undeniable that carbon-based wiring materials become unstable due to ionization of their molecular framework by doping, or that doping causes a decrease in mobility.

Therefore, I/We wanted to increase the carrier density n while maintaining high mobility.

<Means for Solution> Using the portion 104 in which the carrier injection of the conductive material 101 in the electric double layer transistor has taken place and using it in the portion of the conductive material/conductor element 1 in conductors/conductor wire/conductive line, batteries (including chemical batteries and physical batteries), electronic components, actuators and motors, etc.

The said conductive elements 1 are used in vehicles, transportation equipment, aircraft, robots, or appliances, products, and parts that use batteries and motors to reduce the weight and cost of conductors.

This application proposes a conductive material, wiring material, and conductive element made of conductive polymer, organic semiconductor, inorganic semiconductor, or conductive carbon material, conductive material, using carrier injection into 104 part of the electric double layer transistor, and having said 104 introduced and injected with carriers. And we propose rechargeable batteries, motors, actuators, and electronic components made of said wiring materials using 104.

In the present application, the carrier density n is increased while maintaining high mobility by injecting carriers into semiconductor or conductor materials, which have high mobility but are difficult to doping and limited in carrier density improvement, through the electric field effect.

As a result, the increase or decrease of carrier density n can be controlled by 106, in a rechargeable battery, the gate electrode can be controlled to increase the carrier density n during battery charging and discharging, and to decrease the carrier density n during battery storage and when the battery is not in use,

During storage, even if a short circuit occurs in the rechargeable battery due to the low conductivity of the electrodes, the high resistance of the electrodes prevents a large current from flowing during the short circuit, thereby preventing battery ignition accidents. (FIG. 9, FIG. 10)

### <Lithium-Ion Batteries can be Destroyed by Overcharging, External Short Circuits, and Internal Short Circuits.>

Patent document 4 is a patent related to the configuration of a lithium-ion battery as a rechargeable battery with a safety element. The patent document 4 uses a PTC element as a safety element to ensure safety against overcharging.

An example of an internal short circuit is a breakdown or short circuit of the internal structure of the battery caused by an external shock. If the cathode and anode contact each other inside the battery, a large current flows and causes a short circuit, and if the electrolyte and active materials are highly reactive, the battery burns or explodes.

Internal shorts can also occur when metal from the electrode, electrolyte, electrolyte solution, or active material precipitates during charging and discharging of the battery and passes through the separator, or when the separator or electrode is defective during manufacture or contains foreign matter or impurities.

FIG. 9 shows a case of a short circuit between the cathode and anode electrodes inside a battery, as illustrated by skewering a metal nail T1 inside the battery.

In the case of the above skewering, the charge of gate electrode 106 flows to the other electrode, and the charge stored in 106 and 104 is lost, resulting in 101 with lower conductivity than 104. Even if there is an internal short circuit between the cathode and anode 101, the low conductivity of 101 may make it difficult for a rapid internal short circuit discharge to occur.

Before the battery is skewered, the battery is provided with a sensor, for example, an acceleration sensor, and the gate voltage VGS is changed in response to changes in acceleration applied to the battery, changes in temperature, changes in air pressure (and changes in usage conditions such as altitude inferred from the sensor measurements) to control the conducting element to reduce the conductivity of the battery electrodes, The system may be prepared for internal short circuits.

In the event of an accident (e.g., traffic accident) involving an electric aircraft or electric vehicle equipped with a battery, the sensor device installed in the battery (acceleration, temperature, air pressure, humidity, special smell, smell of fire, etc.) may be used to prevent an internal short circuit of the battery due to external shock damage to the battery, When the voltage VGS of gate 106 is changed and controlled so that VGS is not applied, the carrier introduction layer of 104 is made not to be introduced, and as a result, the electrical conductivity and conductivity of 101 containing 104 is lowered, which is disclosed as a device in this application.

Even if 101 of the positive electrode and 101 of the negative electrode in the battery with reduced conductivity have an internal short circuit, the low conductivity of 101 prevents a sudden internal short circuit current, and is intended to prevent heating, combustion, and explosion caused by the internal short circuit.

A gate voltage VGS is applied between gate 106 and source to increase the carrier density of 104 and improve conductivity.

The result is a conductor, which is a conductor and a transistor, capable of forming 104 in a conductor 101, and a conductor element 1.

By changing the voltage VGS, the conductivity can be controlled,

For example,

When the rechargeable battery is used, VGS is applied to make the electrodes conductive and charge/discharge the rechargeable battery,

When the rechargeable battery is not in use or in storage, the application of VGS is stopped, the potential of VGS is reset or controlled, the carrier density n is reduced, and conductivity is lowered, which may reduce reactions, ignition, and heat generation when there is a short circuit between electrodes. (This application needs to be demonstrated.)

The use of ionic liquids with a wide potential window may enable the use of batteries that use oxidation-reduction or electrochemical reactions with high potential.

If the conductivity of carbon-based conductive materials, which are lighter than copper and aluminum, can be improved and used in the wiring of secondary batteries and motors, it will lead to weight reduction and resource conservation in robot suits, space suits (including wearable devices), electric vehicles, and electric aircraft.

The carrier introduction layer 104 (channel 104) formed by the conventional electric double layer is as thin as 1 nm, so there may be a problem that the area that becomes a conductor is small.

However, as shown in FIG. 11 (FIG. 11), by using 101P, (which may be a porous layer,) 104 can be formed, or by forming a second conductor 1012 on 101P and forming a carrier introduction layer 1042 on 1012, it is possible to increase the area and improve the conductivity of the conductor.

(The surface area per volume of the conductor can be increased.)

The problem of 104 is that the layer of the electric double layer transistor is thin and the area cannot be earned, but by using 101P in this application, the area of 104 can be increased and the conductivity of the conductor element 1 can be improved.

In case 104I is generated instead of 104, the polarity of the electrode voltage VGS is switched from the state of good conductivity where 104 is formed, and VGS that generates 104I is applied to generate 104I, and the conductivity of the conductor element 1 can be reduced from the bare conductor state.

There is still a risk of increasing the time required to charge the capacitor in the porous case.

The device 1 of this application requires charging and discharging time to charge and discharge the capacitor section containing the electric double layer in order to achieve the desired mode of operation.

### BRIEF DESCRIPTION OF THE DRAWINGS

FIG. 1A An explanatory diagram of an electric double layer transistor.

FIG. 1B An explanatory diagram of the device/element.

FIG. 2 A connection diagram of External Circuit EXC1 and Conductor/conductive Element1.

FIG. 3A An explanatory diagram of a conductive element 1FILM in the form of a film, sheet, or foil. An explanatory diagram of the case where the copper foil with active layer for LiPo batteries is made according to 1 of this application (this is an example and is not intended to be limited to LiPo batteries)

FIG. 3B An explanatory diagram of electrode/device/element.

Double-sided electrode type that can be used by stacking two 201s for one gate electrode part. (type where both the front and back of 1 FILM are electrodes.)

FIG. 4 An example of a battery 2BATT using the conductive element of the present application. <Same application, FIG. 1, FIG. 4>

FIG. 5 An example of a conductor 2WIRE utilizing the present application. (Including a motor coil)

(The copper core part of a coaxial cable-like cable is used as a gate electrode 106, 106 is covered with 105, the outer periphery of 105 is covered with a cylindrical 101, and a gate voltage VGS (VG) is applied to 106. 104 is the wire-type conductive element 2WIRE that is to be generated when 101 and 104 are connected to each other.

FIG. 6 An explanatory diagram of an actuator using EAP (201EAP) using the present application (EAP: electroactive polymer. The configuration in FIG. 6 can also be applied to a piezo actuator using EAP as a piezoelectric element. A magnetostrictive element having a configuration in which a magnetic field is generated by the coil 2 COIL of 5 and applied to the magnetostrictive material is also considered.

FIG. 7A An explanatory diagram of a conversion element.

FIG. 7B An explanatory diagram of a conversion element.

FIG. 8A An explanatory diagram of an element. (3-terminal type 1-3TER)

FIG. 8B An explanatory diagram of an element. (2-terminal type 1-2TER)

FIG. 9 An explanatory diagram for preventing a short circuit when a battery (2BATT) using the present application is skewered with a metal nail. <FIG. 9 of the same application>

FIG. 10 A battery or battery device/battery system 3BATT including 2BATT and a protection sensor 3SEN or/and a gate driver 3CGATE, and a battery controller 3CBATT.

FIG. 11A An explanatory diagram of the interface. (Flat 101-105)

FIG. 11B An explanatory diagram of the interface.

FIG. 11C An explanatory diagram of the interface.

FIG. 12 An explanatory diagram of transmitting photons from the light emitting unit 1 to the light receiving unit 2 and transporting energy to the ground, aircraft, spacecraft, transportation equipment, and carriers or cars (3.3 KAGO).

Also, an explanatory diagram for lightning protection by short-circuiting the atmosphere/thunder cloud 2 THCL with a conductive cable 1 WIRE/12.

Left: An explanatory diagram of the elevator 10 having a cage part 15 and 3 KAGOs that connect the ground part 14 and the structure by a cable 12.

Right: An explanatory diagram of a system in which the ground section 14, aircraft 3, aerial platform, etc. are connected by cables 12.

FIG. 13 An explanatory diagram of a lightning protection method/device/system that irradiates photons/laser rays from the light-emitting part 1 in the sky to the thundercloud 2 THCL (light-receiving part 2 which is the atmosphere in the sky/air)

FIG. 14 An explanatory diagram of energy transport method.

Illustration of the method of energy transport from outer space to the earth describing the configuration of this application, including the light emitting 1 and transmitting 1 and the light receiving 2 and receiving 2, and the aircraft 3, ground 4, user 6, clouds and areas of the troposphere and stratosphere.

[FIG. 15] An Explanatory diagram of transporting energy from the receiver 2 or photo receiver 2 and aircraft 3 to the energy demand point on the ground.

FIG. 16 An explanatory diagram of transporting energy. An explanatory diagram of the launch device. An explanatory diagram of launching the fuel raw materials to the SSPS by the launch means 9, and an explanatory diagram of produce fuel using electricity obtained from SSPS, and an explanatory diagram of use the fuel by dropping it towards the ground. An explanatory diagram of the launch device 2MS/2MS-SYS-SPIN (FIG. 1N of priority application 6) is included as an example of the launch means 9.

FIG. 17 An explanatory diagram of a system for obtaining reduced substances 5M and 5MC and transporting the substances 5M and 5MC to the ground. Collected from celestial bodies such as the moon and asteroids Reducing resources/metal oxides 5MOX5 using 1PP or SSPS power/energy, Obtain the reduced substances 5M and 5MC An explanatory diagram of a system for transporting the 5M/5MC to the ground.

FIG. 18A An explanatory diagram of energy transport to the ground.

FIG. 18B An explanatory diagram of energy transport to the ground.

FIG. 19A An explanatory diagram of a device or a robot or formation flight of aircraft using the aircraft 3. (a) Aircraft formation flight (Aicraft Robot/doll/Ad-balloon/air robot) charging and operation use.

FIG. 19B An explanatory diagram of a device or a robot or formation flight of aircraft using the aircraft 3. (b) Aircraft (three flying car) charging and operation (Eg Flying car taxi/delivery car) use.

FIG. 20 An explanatory diagram of wireless power transmission. An explanatory diagram when managing the tag and the object attached to the tag by delivering power/energy to the tag 2TAG by wireless power transmission from the aircraft 3 or the unmanned aerial vehicle 3DRONE. (Example 6)<FIG. 7 of the same application>

FIG. 21A An explanatory diagram of devices/robots and exhibits.

An explanatory diagram of an exhibit formed using aircraft formations/groups (3FORM). An explanatory diagram of a device or a robot or formation flight of aircraft using the aircraft.

FIG. 21B An explanatory diagram of devices/robots and exhibits. An explanatory diagram of a device or a robot or formation flight of aircraft using the aircraft.

Example: An illustration of a device/robot that sprays/paints using a paint machine (3A1-AM).

FIG. 22 An explanatory diagram of an unmanned flying robot. An explanatory diagram of an unmanned flying robot 3 that is equipped with a robot arm and tools (e.g., a saw).

### (Example 8)<Same Application 2, FIG. 9>

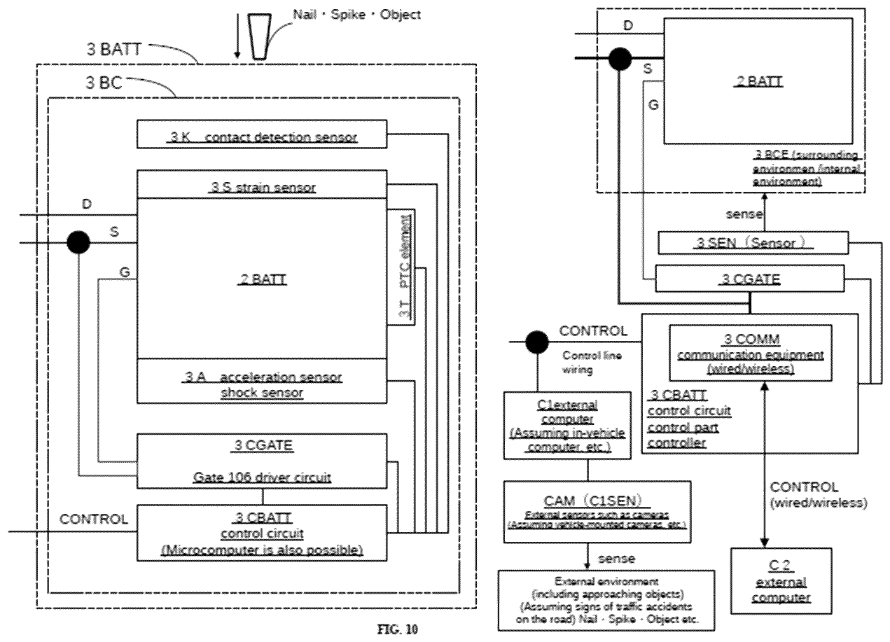

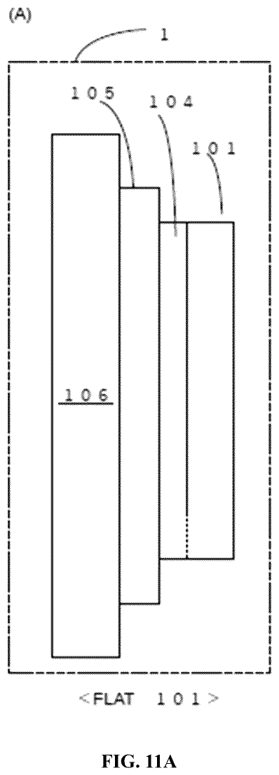

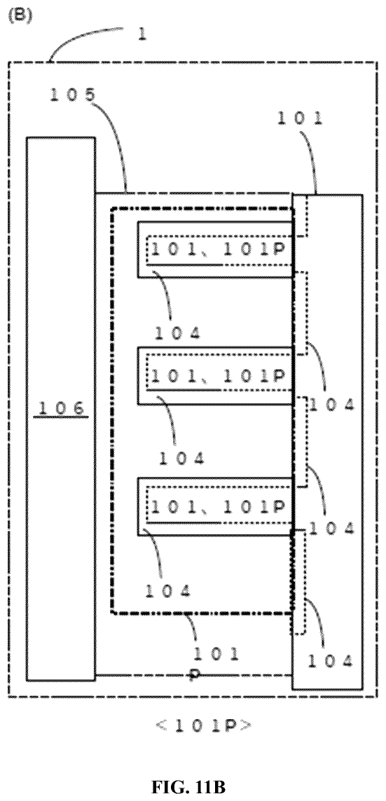

FIG. 23 An explanatory diagram of laser/photon/particle beam/muon particle beam rays. In this application, an explanatory diagram of laser rays when laser is irradiated from a plurality of light emitting units 1 to a light receiving unit 2 in a quasi-zenith orbit group, a laser energy focus, and laser energy scattering after passing through the focus. (Explanatory diagram of the claim that it is difficult for the energy to reach people's houses on the ground during laser irradiation in the present application)<FIG. 10 of the same application>

FIG. 24 An explanatory diagram of a system of an aircraft. An explanatory diagram of a system of an aircraft 3 that can output energy obtained from a light receiving section 2 to the outside as various types of energy such as electric power, light, fuel, chemicals, etc. (It is also an explanatory diagram of the aircraft 3 equipped with a hot air balloon 3HAB and propulsion device 3TH that may be operated using energy from the aircraft 3's battery, fuel, or SSPS.)

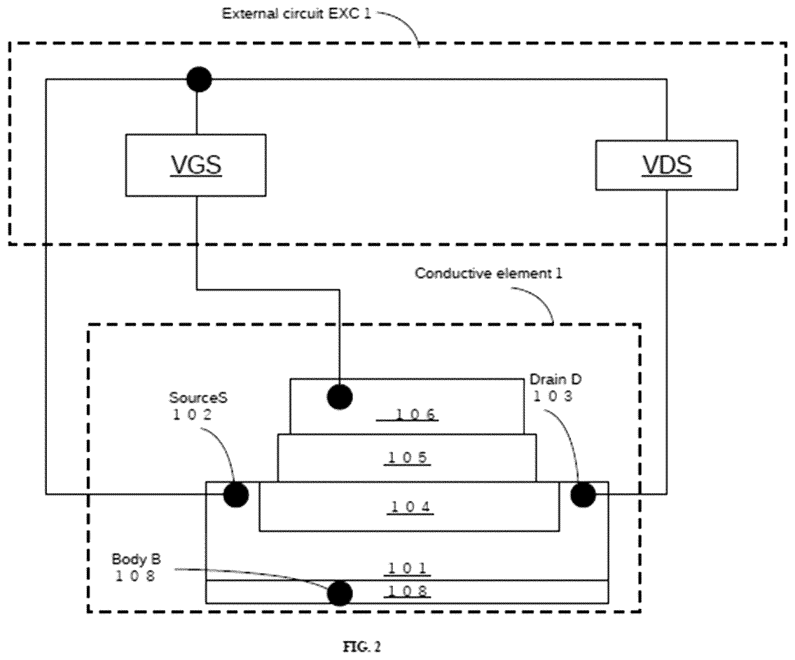

### <Same Application, FIG. 2, 11>

FIG. 25 An explanatory diagram of water supply device 3 and how to use water.

Water obtained by collecting rainfall, rainwater, and snow or water supplied from 4H2O on the ground is input into 3, which may be equipped with a light receiving unit 2, and the water is delivered to places where there is demand or where fires should be extinguished.

FIG. 26 An explanatory diagram of an elevator and a platform. An explanatory diagram of an orbital elevator 10 and an aerial platform 3.

FIG. 27A An explanatory diagram of the elevator/lifting device and the structure. An explanatory diagram of the (orbital/space) elevator 10 and the annular/ring space structure 1

FIG. 27B An explanatory diagram of device.

FIG. 28 Example of an accelerator using photons (/particle) of the structure/device.

FIG. 29A An explanatory diagram of the device/system.

An example including the process of slowing down space muon SM1 or fast muons and irradiating and coupling them to the target atoms.

FIG. 29B An explanatory diagram of the device/system. An example including the process of slowing down fast muons.

FIG. 30 An explanatory diagram of the particle decelerator/accelerator system and elemental particle generation/collision system and atom transmutation system.

FIG. 31 An explanatory diagram of atom transmutation system.

FIG. 32A An explanatory diagram of the device.

FIG. 32B An explanatory diagram of the device.

FIG. 33A An explanatory diagram of changing the emission direction of photons/particles by the deflection means.

FIG. 33B An explanatory diagram of changing the emission direction of photons/particles by the deflection means.

FIG. 34 An explanatory diagram of an attempt to record with a laser using a liquid immersion exposure system with a liquid section NVLQ for immersion exposure.

FIG. 35 An explanatory diagram of an example including a system for supplying liquid NVLQ when immersion exposure is performed.

FIG. 36 An explanatory diagram of when liquid NVLQ is used for contact exposure in photo lithography or etc.

FIG. 37 An explanatory diagram for immersion exposure using liquid NVLQ.

FIG. 38 An explanatory diagram of atom transmutation system.

FIG. 39 An explanatory diagram of atom transmutation system. <Conductor Element 1 Configuration>

For the above element 1, 101 is composed of carbon-based materials including organic semiconductors, or conductive polymers, or carbon materials, or graphene, or carbon nanotubes or semiconductors or metals or, or nanotubes, or sheets.

105 is an insulator layer.

106 is a gate electrode.

102 and 103 are the source and drain portions in 101, including 104, where current flows by carriers. 104 is a carrier introduction layer formed in 101.

(104 is the channel portion of the transistor.)

### <Increase of the Interface>

I/We will focus on the interface where 104 is formed in 101 that touches 105.

The thickness of said electric double layer is about 1 nm.

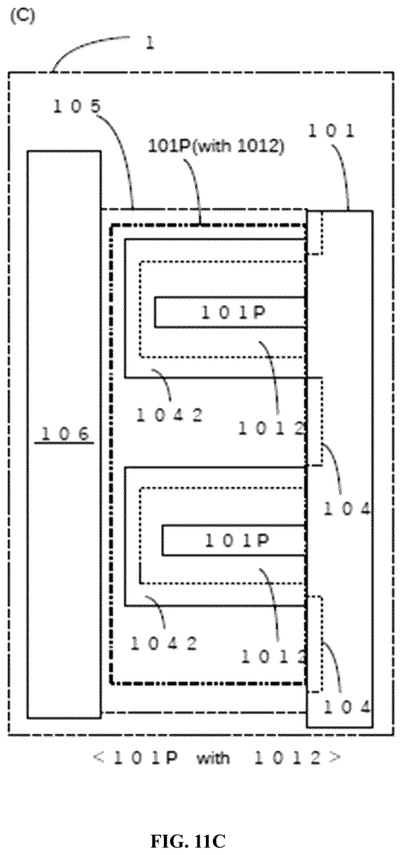

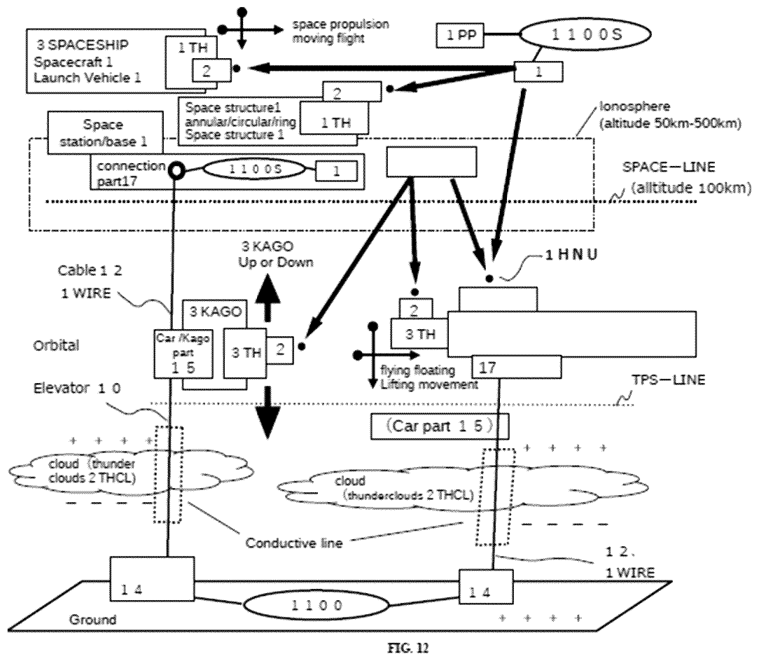

As shown in (A) of FIG. 12 (FIG. 11 of this application), if the surfaces of 101 and 105 touching each other are flat, 104 formed at the boundary of 101 and 105 may be a flat area of about 1 nm.

So, If 101P is used as shown in (B) of FIG. 12 (FIG. 11 of this application), the ratio of the surface of conductors 101 and 101P in contact with the ionic liquid to the total volume of conductor layer 101P can be increased, (and gaps with respect to the total volume are also generated, resulting in the so-called porous film 101P), and when VGS is applied to gate 106, the surface area of 104 is increased, resulting in an increase in the area of 104 of 101P as a conductor (conductor area A), and, the conductivity of the conductor element 1 including 104 formed in 101P can be improved.

(By using 101P, the area A can be increased, and the conductivity can be greatly increased by forming 104.)

(Also, if conductivity can be decreased by forming 104I, the decrease can be increased.)

101P is the 101 portion when 101 is a comb-shaped, pillar, or porous electrode/conductor material.

A second conductor 1012 can be laminated on the surface of 101 or 101P as shown in (c) of FIG. 12 (FIG. 11 of this application).

The 1012 may be a metal such as iron, an inorganic material that can be a semiconductor or conductor such as Si, or a carbon-based conductor material.

The thickness of 1012 may be in the several nanometer class.

The 1012 may be used with a carrier introduction layer 1042 or 1042I formed by applying VGS to the gate 106.

(The second conductor 1012 may be a conductor material formed on the surface of 101 or 101P. 1012 may be thinner than 101.)

The above-mentioned configuration in which 101P is used to increase the surface area of 104 and 1042, resulting in an increase in the area of 104 and 1042 as conductors, which may be used in the conductor element of the present application to improve conductivity and increase the control range of conductivity.

The conductor elements 1, conductors, coils, motors, sheets/films/foil of conductors, batteries, and electronic components (photoelectric conversion elements, thermoelectric conversion elements) may be used in the present application.

### <Control of Gate Electrode According to the Type of 101 (Carrier Type and Material Compatibility)>

This application disclose/expression a conductive element that controls the conductivity of 101 according to the polarity of the positive and negative of VGS applied to 106 and the magnitude of the voltage, and becomes a conductor for conductors, batteries and electronic components.

When a metal (iron, copper, silver, gold, etc.), of which electrons are carriers in numerous/majority/large numbers, is used as 101,

When voltage is applied to a gate electrode where anions are arrayed on the surface of 101 and when voltage is applied to an electrode where cations are arrayed on the surface of 101, the positive and negative polarity of the arrayed ions increases or decreases the conductivity of said metal.

Depending on the magnitude and polarity of the voltage applied to 106 when 101 of the metal, 104 and 104I can be formed.

In this application, the gate electrode increases the conductivity of 101 and 104 for use in conductive elements and electrode wires, and decreases the conductivity of 101 for purposes such as protecting high-energy batteries from internal short circuits, 104, or utilizing the application of voltage to 106 such that 104 is formed, 104 is eliminated, or 104I is produced.

In addition, the components that make up the device 1 have combinations that cause chemical reactions, corrosion, and etching, and if this is caused by polarity or voltage magnitude, the gate electrode is set with this in mind.

### <Example of Manufacturing of Conductor Element 1> <Manufacture of 1FILM>1.

### <Manufacture of 1FILM>

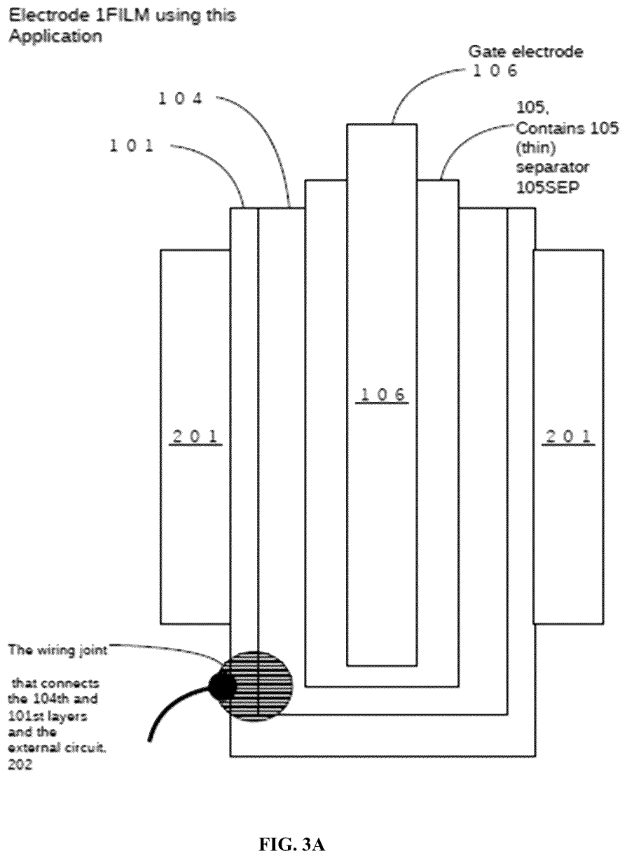

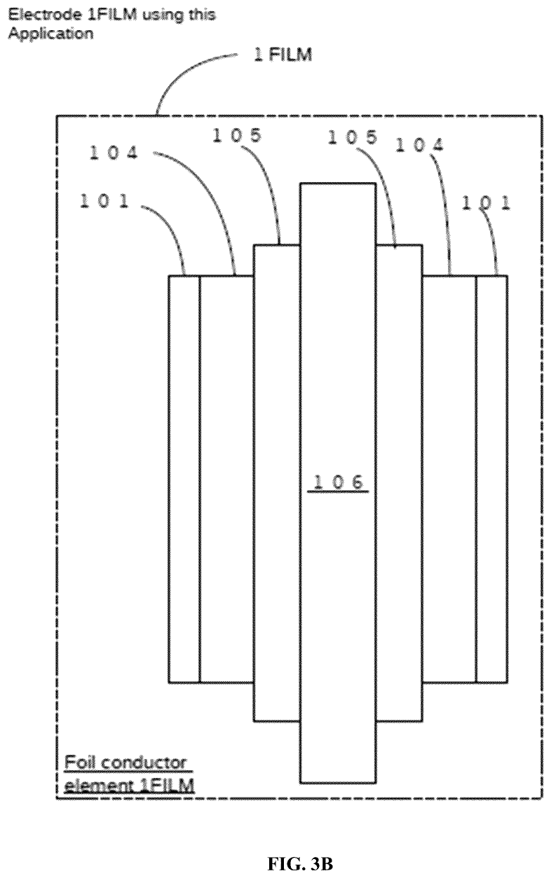

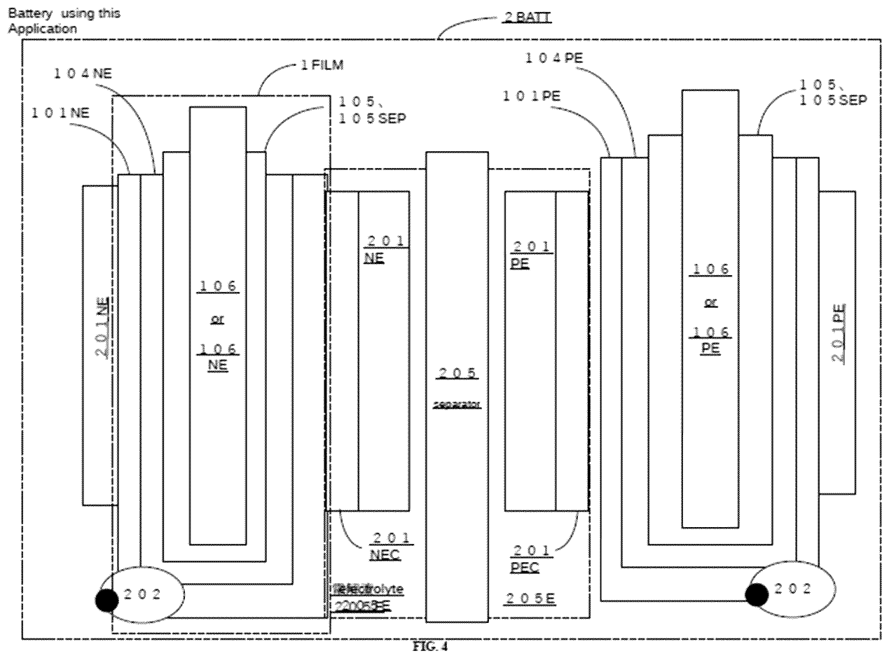

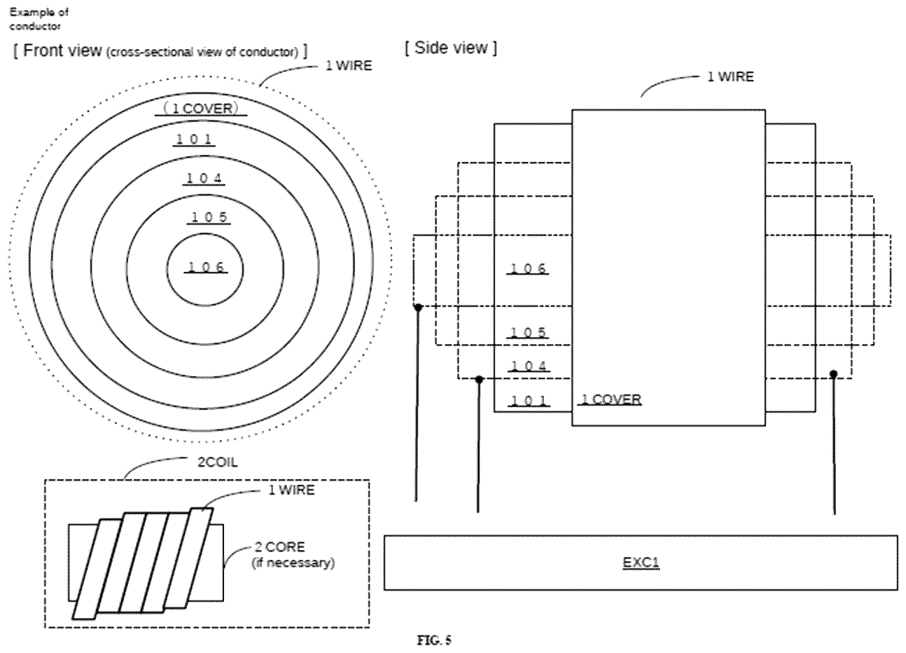

The manufacturing of the film or foil 1FILM of the conductor element 1 shown in FIG. 3 will be discussed.

1. prepare the foil or film of gate electrode 106.

(Metal mesh may be combined with carbon material.) Gate electrode film 106 is used.

2. apply/coat 105 to 106. 105 may be a layer 105SEP with separator function that can insulate preventing contact between 106 and 104/101, and contains materials to constitute an electric double layer transistor, and ionic liquid.

3. After 105 application and film formation, 101 is applied. 101 may contain 101P. (After coating and film forming 101P, 1012 may be formed on 101P.)

3A. 105 may be applied to a layer of 106 and laminated with a sheet containing 101 or 101P.

3B. 105 may be applied to a layer of 101 and laminated with a sheet of 106.

*The ionic liquid must be soaked into 101P.

### <Manufacture of 1WIRE>

The manufacturing of 1WIRE conductor shown in FIG. 5 is discussed below.

1. prepare a gated wire 106. (The wire 106 may be made of a composite material of thin metal wire such as aluminum and carbon material, and a thread-like material with mechanical strength may be included in the composite material. 106 is mainly an electrode wire for charging the capacitor section that forms the electric double layer, and may combine several materials to achieve this purpose while also providing the necessary opportunity and strength as a conductor. (Multiple materials may be combined for the purpose of providing strength.)

2. Apply 105 to 106.

105 can form an electric double layer and can include 105SEP that has a separator function. 3.

3. After 105 coating and film formation, 101 is applied.

101 can include 101P.

(3-2. After coating and film forming of 101P, 1012 may be formed on 101P.)

After coating and film forming, 101 can be arranged to surround 105.

For example, a sheet of 101 or a thin wire 101 or any other material that can be wrapped around a sheet of 101 or a thin wire 101 can be used to cover a sheet of 106 coated with 105 without gaps.

(The 105 can be braided or wound so that it surrounds the 101 wire, just as the thin conductors of the braided copper wire of the outer conductor of a coaxial cable are arranged so that they wrap around the dielectric.)

4. The bare wire will be 1 WIRE.

(4-2. Multiple 1WIREs may be used to make a stranded/twisted wire.)

5. If 1WIRE is an insulated wire, a 1COVER covering for insulation shall be applied over 101.

Multiple 1WIRE bare wires may be bundled together (by braiding, etc.) and insulated by applying 1COVER insulation.

### <Conductor Element 1 Using 101P or 1012 Described in FIG. 11>

When implementing this application, it is better to use 104 or 1042 formed in (B) or (C) described in FIG. 11 than to use flat 104 with flat 101 in (A) in FIG. 11, because the surface area of 104A per unit volume (conductive area A) can be increased and the conductivity of the conductive element 1 P and 101P 104 and 1042 can be used.

Therefore, 101P may be used in the examples of this application.

### <For Electrodes, Batteries, and Electronic Components>

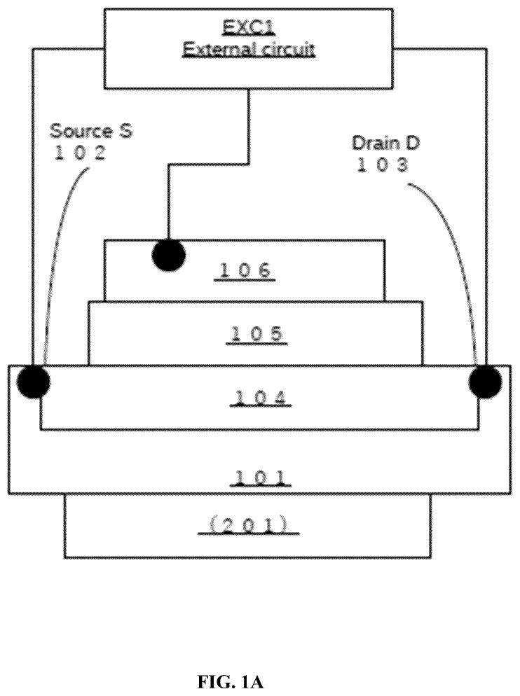

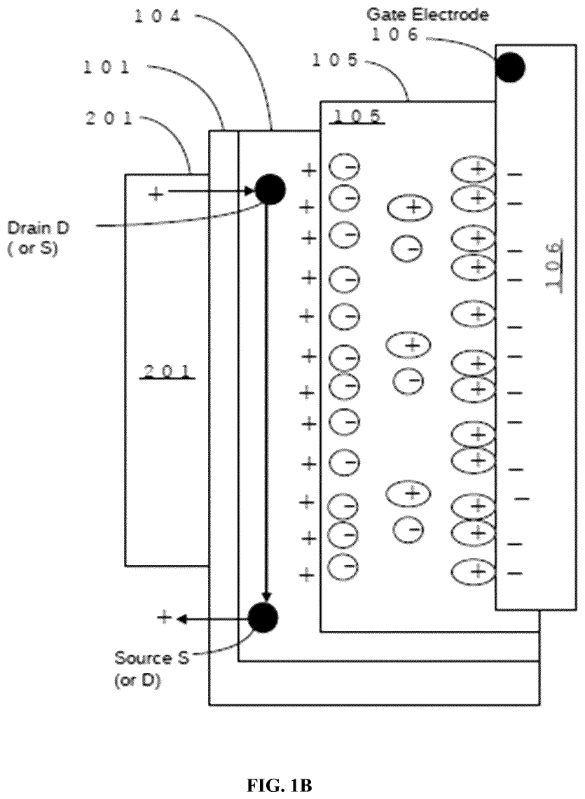

FIG. 1 shows an illustration of an electric double-layer transistor (A) and the device (B) of this application, and FIG. 3 shows an illustration of a copper foil with an active layer for a LiPo battery, etc., as an example.

(This is an illustration of the conductor element 1FILM in the form of a film, sheet, or foil.)

FIG. 4 is an example of a battery 2BATT that uses the conductor elements 1 and 1FILM of the present application.

### <Mechanical and Electrical Conversion Applications>

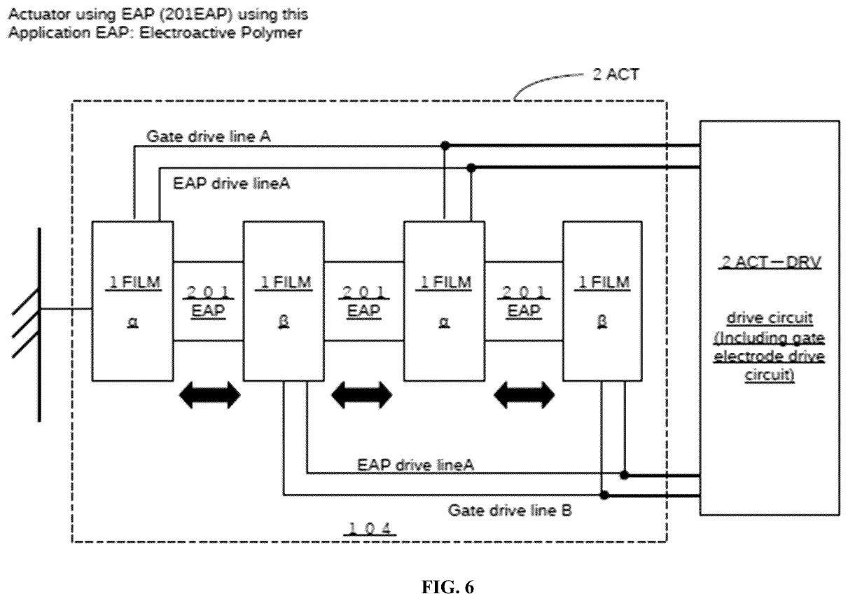

FIG. 6 is an illustration of an actuator using EAP (201EAP) that utilizes the present application. The configuration of FIG. 6 can also be converted to a piezoelectric actuator that uses piezoelectric material instead of EAP.

In the configuration of FIG. 6, instead of EAP and 1FILM, a magnetostrictive element with a configuration in which a magnetic field is generated and applied to the magnetostrictive material by a magnetostrictive material and 2COIL is also possible.

In FIG. 6, the piezoelectric element using 1FILM (and 1WIRE) of this application for the wiring section of the vertical displacement type piezoelectric actuator and the electrode section of the piezoelectric element is the element 2ACT with the piezoelectric element section as EAP.

After applying the voltage for gate drive from 2ACT-DRV to gate drive lines A and B to increase conductivity, the voltage for EAP drive is applied from 2ACT-DRV to operate the actuator.

EAP drive voltage is applied from 2ACT-DRV to the source (or gate) of the alpha (positive electrode) of 1 FILM connected to EAP drive line A and the beta (negative electrode) of 1 FILM connected to EAP drive line B to drive the EAP and piezo layers.

The element that can perform electro-mechanics with EAP or piezo sandwiched by 1FILM in the configuration shown in FIG. 6 can be operated as an actuator, and can be used for sensors that receive mechanical force due to the movement of humans or objects, generate electricity, or sense mechanical force.

### <Applications for Photoelectric and Thermoelectric Conversion>

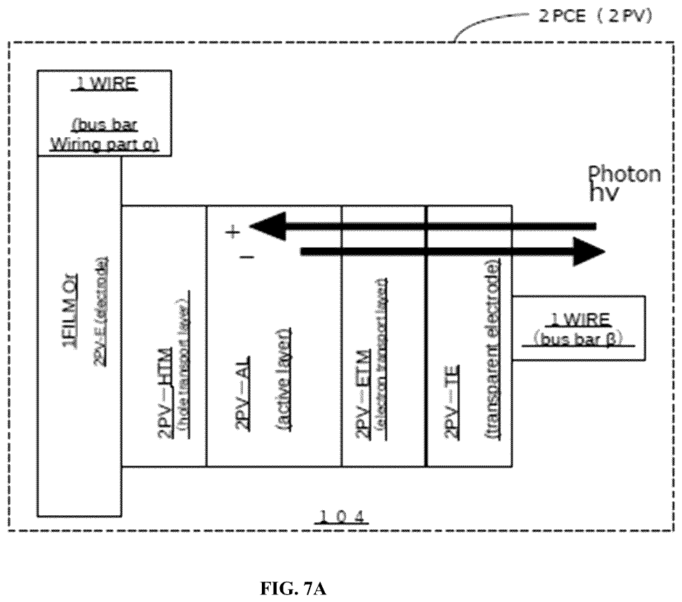

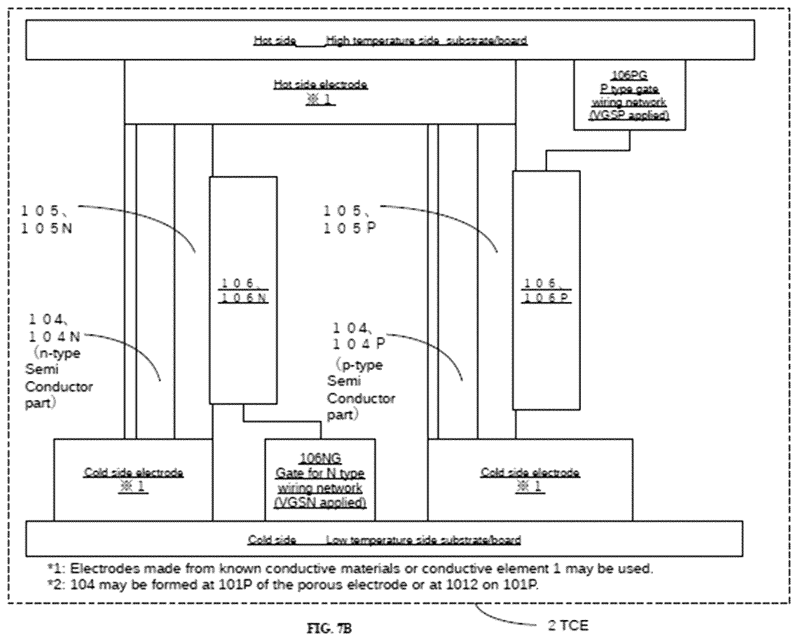

FIG. 7 (FIG. 7A) is an illustration of 2PCE, a photoelectric conversion device, and 2TCE, a thermoelectric conversion device, which use this application.

Figure illustrates a solar cell device (2PV) and a light-emitting device such as an LED/laser diode that uses this application.

The conductor elements of this application are used for the electrodes and semiconductor parts of the above devices.

### <For Conductors>

FIG. 5 shows an example of a conductor/device 2WIRE that uses this application.

It includes a motor coil 2COIL that can be configured using a conductor.

The copper core wire portion of a coaxial cable-like cable is used as the gate electrode 106, 106 is covered with 105, 105 is covered with a cylindrical 101 around the periphery, and 104 is made to be generated in 101 when gate voltage VGS (VG) is applied to 106 in a conductor type conductor element 2WIRE.

(It is possible to reverse the arrangement of 106 to 104m 101 in FIG. 5.)

<With or without integration of the gate terminal 106 and its control unit into the conductive element 1>

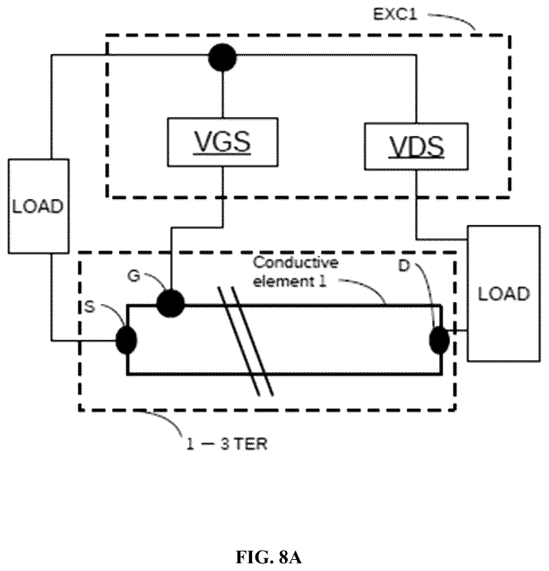

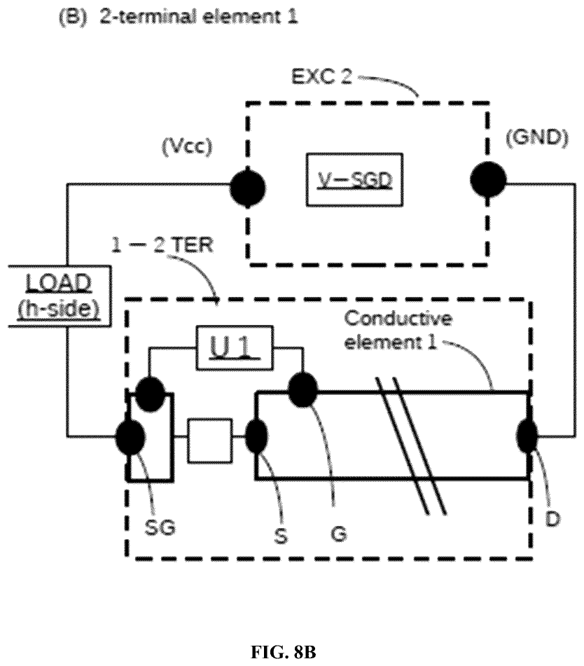

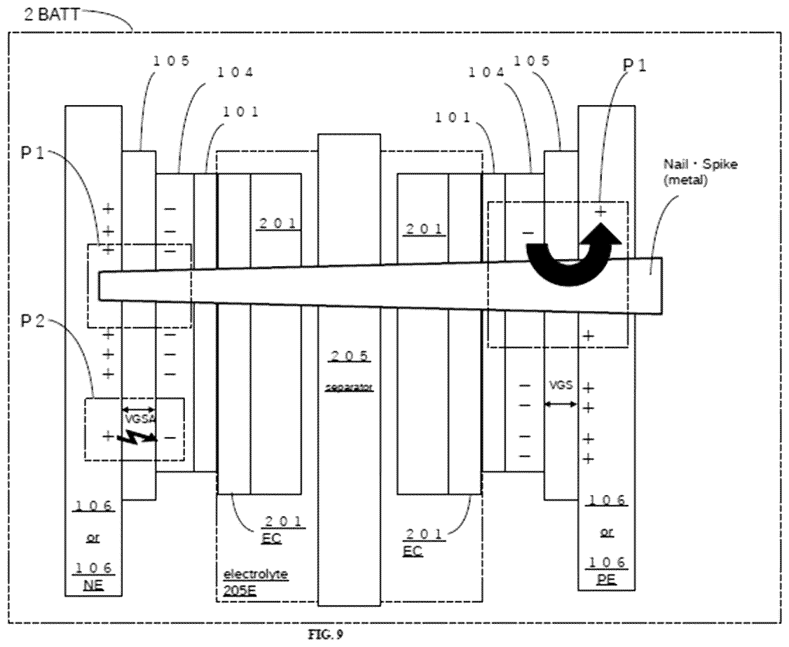

FIG. 8 illustrates the conductive elements (3-terminal type 1-3TER and 2-terminal type 1-2TER) that use this application.

This application is

The 1-3TER terminal configuration is used,

However, when extending conductors by connecting them in series with conductors, etc., the 1-2TER configuration can be used to simplify the extension of conductors by using the 1 conductor element since it is only necessary to connect both ends of the 2-terminal element when connecting them.

The form of conductor element 1 and 1-2TER in this application is intended for use in electric wires and conductors (including coils and motors that use conductors).

In other cases, it may be used for electronic components in which some large-area and large-scale electrodes are deployed or stored in the element.

(Electronic components: solar cells, LEDs, LDs, OLEDs, digital signage, LCDs, batteries, capacitors, piezoelectric, magnetostrictive, and EAP actuator elements, microelectromechanical system elements, MEMS and NEMS elements, inkjet heads, digital mirror devices, image sensors (Thermal image sensor, various electric circuits, thermal image sensor)

### <Use as a Battery 2BATT>

FIG. 3 and FIG. 4 show examples in the case of secondary batteries. In a lithium-ion polymer LiPo battery, active material and cathode material are applied to the reverse side of a copper foil.

In this application, there is a configuration in which a gate foil 106 is made and a separator layer 105SEP that can contain ionic liquid is provided, electrode layers 101 and 101P are coated on the outside of the gate foil, and active material 201 is coated on the outside of the separator layer.

In the said LiPo battery, when aluminum metal or a composite material of that metal and other materials is used for the gate element, there may be an application to replace or reduce the metal, which is heavier and has a higher material cost than carbon-based materials such as copper.

For example, in a system that uses a copper electrode and an aluminum electrode, such as a lithium ion battery, by using the conductor element of this application for the positive electrode and aluminum foil for the negative electrode, the amount of copper used can be reduced compared to the existing configuration that uses copper for the positive electrode, while the conductivity of the positive electrode can be turned on and off by the gate mentioned above and the gate 106 of the positive electrode can be turned off when the battery is stored. By turning off the gate 106 of the positive electrode during storage, it is possible to prevent heat generation due to a short circuit during storage (in the contact between the low-resistance positive electrode and the existing aluminum negative electrode, the aluminum side has low resistance, but the positive electrode has high resistance, and so prevent a large current flows during an internal short circuit and the LiPo battery is not likely to swell or catch fire or explode), leading to increased battery safety. This may lead to a reduction in the use of limited metal elements while increasing battery safety.

<Use of Battery System 3 and 3BATT with Sensors and Control Unit>

FIG. 9 is an illustration/figure of short-circuit prevention when a battery (2BATT) using the present application is skewered by a metal nail (nail), and FIG. 10 is an illustration of 3BATT and its protection mechanism including 2BATT, (for protection use) sensor 3SEN, gate driver 3CGATE and battery controller 3CBATT.

FIG. 10 uses the conductor element 1 of this application as a foil for the battery electrode, and the sensor 3SEN and the gate driver 3CGATE connected to the gate 106 of the battery are connected to the controller 3CBATT, and the controller 3CBATT measures and obtains sensor values for the environment 3BCE around the battery according to the sensor type of 3SEN using 3SEN, and 3CBATT controls 3CGATE according to the sensor values measured and obtained, and 3CGATE controls VGS of 106 of 2BATT.

3BATT controls 106 of 2BATT using control unit 3C and sensor 3SEN (3A, 3T, etc. as specific examples of sensors) and controls the voltage applied to 106 when 2BATT is not charging or discharging, or when it is stored, or when 2BATT is destroyed and an internal short circuit can occur, and 104 is lost The purpose is to make the battery safe by making the resistance of the positive and negative electrodes of the 2BATT high, making it difficult for a large current to flow between the positive and negative electrodes in the event of an internal short circuit, and preventing battery destruction (ignition or explosion).

3BATT uses control unit 3C and sensor 3SEN (3A, 3T, etc. as examples of sensors) to control 106 of 2BATT of 3BATT, and when 2BATT is not charging and discharging, or when 2BATT is stored or 2BATT is destroyed and an internal short circuit can occur, the voltage applied to 106 is controlled and 104 is lost. (and eliminate 104 or generate 104I)

The purpose is to make the battery safe by making the resistance of the positive and negative electrodes of the 2BATT high, making it difficult for a large current to flow between the positive and negative electrodes in the event of an internal short circuit, and preventing battery destruction (ignition or explosion).

With the conductor element 1, the present application seeks to provide a lightweight and safe battery that is lighter than copper-containing batteries, eliminates resource limitations derived from metallic elements or reduces the amount of metallic resources used, and provides for internal short circuits in batteries.

The previously mentioned 3BATT is one example of System 3. As other examples, as described in the “Description of the Code” section of this application, in the sections

<Acceleration Sensing Type Elements> and <Temperature Sensing Type Elements>, the system 3 using sensors and conductor elements 1 can be used in the form of the battery system 3BATT as well as the wire system 3WIRE and others.
<Use of 101 and 1012, which are Close to Insulators, for Conductor Element 1

A material that is normally regarded as a near insulator due to its wide band gap, etc., may be used for 1012, and a carrier-introduced 1042 may be formed in 1012 and used as the conductor element of this application.

Materials 101 and 1012 that emit higher energy photons than ultraviolet LEDs, deep ultraviolet LEDs, or photons emitted by them (which can be said to be usually insulators with a high band gap) may be used in this application.

(Semiconductor devices with a high band gap, such as aluminum nitride, or even insulators may be used for 101 and 1012.)

<Ionic liquids and molten salts>

In devising this application, there were difficulties in procuring ionic liquid reagents on an individual basis, so this application was filed at the idea level. Ionic liquids are not easily obtained at the time of application and can be expensive.

### <Use of Deep Eutectic Solvents>

Although ionic liquids are disclosed as an example, it is not limited to ionic liquids, as long as the above-mentioned carrier introduction can be performed on the material portion 101 to form a carrier-introduced portion 104. For example, instead of an ionic liquid, a flame-retardant and low vapor pressure solvent such as a deep eutectic solvent can be used to dissolve an electrolyte that can generate an electric double layer (a substance that generates cations and anions necessary for the formation of an electric double layer) and include it in an insulating layer 105 of the conductor element 1, conductor 1WIRE, etc.

Deep Eutectic Solvent (DES): A solvent that becomes liquid at room temperature by mixing a hydrogen bond donor compound and a hydrogen bond acceptor compound in a certain ratio. It has features such as low vapor pressure, flame resistance, high thermal stability, high electrochemical stability, wide potential window, and easy dissolution of any substance, etc. It is sometimes cheaper than ionic liquids. There are also naturally occurring deep eutectic solvents that are considered to have low environmental impact.)

Batteries, secondary batteries, capacitors, transistors, conductors, and electronic components may be composed of deep eutectic solvents. (They may be used for the insulating layer 105 and the medium containing the electrolyte in batteries, secondary batteries, capacitors, and electrochemical devices. It may also be used for the conductor element 1, conductor 1WIRE, battery electrode 1FILM, cable 12, etc.)

The composition of the present application can be any substance, portion, or means of generation necessary to generate an electric double layer formation at the interface between the insulating layer 105 and the materials 101 and 104. (This may be realized by other configurations, not limited to ionic liquids as described above.)

Although embodiments of the invention have been described, these embodiments are presented as examples and are not intended to limit the scope of the invention.

These novel embodiments can be implemented in various other forms, and various omissions, substitutions, and changes can be made without departing from the gist of the invention.

The conductor element (element 1, component 2/product 2 including element 1, and system 3 of elements including sensors) of the present application has the following intentions and possibilities

In the field of batteries, to provide batteries that are lighter than copper-containing batteries, eliminate resource constraints derived from metallic elements, and are safer.

In the field of motors (coils, magnets), provide motors that are lighter in weight and have fewer resource constraints derived from metallic elements.

In the field of conductors, provide motors that are lightweight and have fewer resource constraints derived from metallic elements.

in the field of sensors, the conductor element 1 of the present application may be a switch part 1 that can turn on/off the conductivity of 1 by a sensor (e.g. 3SEN and control unit). The function of said switch part may be used for batteries 3BATT including 1WIRE, 1FILM and 1FILM.

### EXPLANATION OF LETTERS OR NUMERALS

### <Transistor/Element/Device Part>

1: Element. Conductor element. (It is not limited to semiconductor devices, so it is described as a conductor element).

101: Conductor or semiconductor. A material part/portion that conducts a carrier. Conductor or semiconductor.

Can include semiconductors, which can usually be taken as insulators, such as diamonds. (101 includes conductors and semiconductors.)

102: Source electrode(S).

103: Drain electrode (D).

104: Carrier introduction layer.

(104: Channel section of field-effect transistor)

(conductivity-increasing carrier introduction layer 104).

105: Insulator layer. * It can be the insulator layer 105 of a field-effect transistor, or an insulator portion 105 that can be used to form an electric double layer such as molten salt, ionic liquid, etc.

105 can be a porous material or separator that can contain ionic liquids. The insulator layer 105 that can form an electric double layer is acceptable.

The purpose of this application is to increase the conductivity of 101 including 104 by storing the electric charge in 104 of the capacitor portion of the aforementioned field effect transistor using insulators and dielectrics, not 101 of a semiconductor, but 101 of a conductor of carbone base material, (specifically, the configuration of an electric double-layer transistor in the field-effect transistor category is used.)

105SEP: An insulator layer used in the formation of an electric double layer while physically separating it to prevent internal shorts, such as by including ionic liquid in the separator.

(Separator section capable of forming an electric double layer).

106: Gate electrode (G).

107: Protective layer.

108: Body section (B). (Body terminal section of field effect transistor and MISFET).

201: Layer stacked on 101 (may include layers, materials, and structures to achieve a certain function, such as a layer of active material in a battery, a semiconductor layer in a semiconductor device, an EAP layer, etc.).

104I: Reverse carrier introduction layer.

(Layer 104I: a carrier introduction layer of the type that reduces conductivity)

(Layer 104I: a layer that introduces carriers of the type that reduces conductivity).

2: Electronic components, conductors, sensors, and electrical and electronic applied products using the conductor element 1.

3: A system/apparatus with the function of increasing or decreasing the conductivity of a conductor element 1 in accordance with the result of an input from a sensor or input device, where the conductor element 1 or a component or product 2 using the element 1 is provided with a sensor 3SEN, a control unit 3C and a gate drive circuit 3CGATE.

### <Explanation of FIG. 11>

101P: The part of conductor 101 when 101 is a comb, pillar, rod, porous layer, membrane, or electrode.

(101P may be a porous membrane.)

For the image of the above-mentioned porous film, it is a porous film formed by sintering semiconductor particles in dye-sensitized solar cells, a fuel electrode in solid oxide fuel cells, an electrode film including a porous current collector or current collector formed by applying carbon black or other conductive particles in the conductor of electrodes in batteries including dry cells, Or nanorod and pillar structures grown or deposited on the electrode 101.

For example, the porosity/porosity of 101P may be within the range that can be taken for porous materials.

101P may be a layer or a portion where the ratio of the volume of the void space to the total volume is determined.

101P can be a conductor layer or film with many micro/nano-level voids that are not flat at the micro/nano-level, where the volume of gaps exists relative to the total volume, unlike 101, which is made of a single crystal plane of a so-called semiconductor or conductor.

It can be a porous membrane with micro- and nano-level gaps, such as a sponge.

May be a conductor layer/membrane with many micro/nano level voids.

1012: The second 101.

(It can be a conductive material 1012 formed on the surface of 101 or 101P.)

1012 can be thinner in layer thickness than 101.

When 1012 is copper or aluminum and its thickness can be reduced, 1012 can be deposited on 101, and said 101 can be formed of carbon-based materials such as carbon materials, the amount of copper or aluminum used can be reduced.

1042: Carrier introduction layer formed on 1012. A carrier introduction layer to improve conductivity.

1042I: Reverse carrier introduction layer formed on 1012.

(Layer 1042I, which introduces carriers of the type that reduces conductivity)

(Layer 1042I, which introduces carriers of the kind that reduces conductivity)

### <Wires and Conductors Related to Wires and Conductors>

1WIRE: Conducting wire using a conductor element. wire using a conductor element.

(1COVER: Coating layer of a wiring member.

2COIL: Coil made of 1WIRE.

2CORE: Magnetic core. The core of a coil.

2CORE-MGS: Magneto-strictive material of magneto-strictive element.

2MOTO: Motor (2COIL is used.)

(When the specific type of motor is not limited.)

2MOTO-BLDC: Brushless DC motor. (For example, the outer rotor and inner rotor type of brushless DC motors can fix the coil 2COIL to the stator side, and the current flowing to the stator can be controlled to rotate the rotor and drive the motor. As in the article in Non-Patent Document 2, the brushless type requires a motor drive circuit, but the element 1 or 2COIL of this application could be used in the coil of the stator).

3C: Control section or controller connected to gate control section 106 or sensor. 3SEN: Sensor or input device section.

3WIRE: A conductor system that adds a mechanism to control 106 by sensor measurements of 3SEN.

*The 1WIRE may have a 1-2TER configuration and include the 3SEN sensor and 3C control unit in the 1WIRE. 1WIRE may include the 3T temperature measurement sensor or 3A acceleration sensor as the 3SEN sensor.

### <2-Terminal and 3-Terminal Elements>

1-2TER: 2-terminal conductor element 1.

(The terminals related to gate 106 are incorporated inside of 1. 1-2TER type 1WIRE can be connected and used just as existing wires are connected and extended to form a long wire.

The 1-2TER type is a method that has the effect of eliminating the need for external circuitry and wiring for the gate electrode). U1: Control unit of the gate or the gate

U1: Control section or drive circuit of the gate.

(It may include a part to configure 3 such as 3C, 3SEN, 3CGATE, etc.)

U1: The control or driving unit for the gate/device.

1-3TER: 3-terminal conductor element 1.

(A method that allows 106 to be controlled from outside of 1.)

<Electrodes related to>

1FILM: Film or foil or sheet with conductive elements. (electrode foil and film electrode).

As shown in FIG. 3 (b), there are two types of 1FILM: a single-sided electrode type (in which one of the two sides of the 1FILM becomes the electrode) and a double-sided electrode type (in which both sides of the 1FILM become the electrode) that can be used by stacking two 201s for a single gate electrode portion, as in FIG. 3 (b).

(A) and (B) in FIG. 1 are used as a broad plane, and the single-sided electrode type (in which one of the two sides of the 1FILM becomes an electrode) can be used by stacking one 201 for one gate electrode section. As shown in FIG. 3 (b), there is a double-sided electrode type (in which both the back and front surfaces of one film become electrodes) that can be used by stacking two 201s for one gate electrode portion.

3C: Control section or controller connected to the gate control section 106 and sensors.

3SEN: Sensor or input device section.

3FILM: Electrode system, conductive film, conductive foil, or conductive sheet system with added mechanism to control 106 by 3SEN sensor measurements.

201: A layer laminated near 104 and 101.

(May include electrode layers of batteries, active materials of batteries, electrode layers and active layers of semiconductor devices, layers for charge transport, etc. 201 may be a layer that is controlled by electrodes and causes some function,) (for example, liquid crystal layer 201-LC in the case of using conductive element 1FILM as electrode of liquid crystal devices.)

201-LC: Liquid crystal layer.

### <Actuators, Transducers, and Mechanical-Electrical Conversion Devices Using Electrodes and Wires>

201EAP: 201 which is EAP.

2ACT: Actuator (including actuators using EAP; 1FILM may be used).

2ACTS: An element when 2ACT is used as a sensor for pressure sensing, a power generator that converts mechanical force of human or object movement into electrical force, or a mechanical-electrical converter.

2ACT-EXC: An external circuit for driving 2ACT. (When the gate drive and the drive circuit that drives the functional layer, such as EAP or piezo material, are separated and driven.)

2MOTT: Motor. Electric motor.

2MOTTG: Generator using an electric motor, motor type mechanical-electrical converter.

### <Photoelectric Conversion Element>

2PCE (2PV): Photoelectric conversion element.

An example of an opto-semiconductor device is a solar cell.

(or photodiode, LED, OLED).

2PV-E: Electrode.

2PV-HTM: Layer that transports holes.

2PV-AL: active layer. (In photodetectors, it can be a layer that absorbs light and separates it from the charge, and in light-emitting devices, it can be a layer that emits light.)

2PV-ETM: Layer that transports electrons.

2PV-TE: Transparent electrode.

1WIRE-(busbar wiring section): A bar, wire, plate, sheet, or thick film section with 1 conductor element and 1WIRE for current collection.

<Thermo electric conversion element>.

2TCE: In the conductor element 1 of this application, a thermoelectric conversion element that uses N-type and P-type semiconductors in the 104 portion.

104N: Carrier introduced n-type semiconductor layer,

106N: Gate electrode for 104N.

104P: p-type semiconductor layer with carriers introduced,

106P: Gate electrode for 104P.

105N, 105P: Ionic liquid insulator layer that generates an electric double layer as a carrier introduction method.

106NGRID: Power distribution network for applying voltage to 106N.

106PGRID: A power distribution network for applying voltage to 106P (a separate network from 106NGRID).

(In FIG. 11, the voltage VGN can be applied to the gate 106N of the N-type

semiconductor and the voltage VGP to the gate 106P of the P-type semiconductor. VGP is a different voltage from VGN, and the polarity of the voltage can be different for the two types of gates mentioned above.)

### <Battery>

2BATT: Battery using 1 conductor element.

104NE: Carrier introduction layer of 1 FILM of anode.

106NE: Gate electrode of 1 FILM of anode.

101NE: Conductor layer of 1 FILM of anode.

201NEC: 201 of the anode current collector.

201NE: active material layer of the anode.

104PE: Carrier introduction layer of 1FILM of positive electrode.

106PE: Gate electrode of 1FILM of cathode.

101PE: Conductor layer of 1FILM of cathode.

201PEC: 201 of the cathode current collector.

201PE: Cathode active material layer.

201EC: Electrode current collector.

202: Assumed example of a terminal section that draws charge from the cathode anode.

105, 105SEP: 1FILM insulator layer.

205: Battery separator.

205E: Electrolyte and electrolyte of the battery.

P1: Area of charge loss in the electric double layer due to a short circuit between 106 and 104.

(The area where 104 is lost or the charge of 104 decreases due to the short circuit and 101 including 104 becomes highly resistive as an electrode.)

P2: Area of reduced charge when the gate 106 is short-circuited due to dielectric breakdown Nail/Spike: Conductor nail/metal nail for battery skewering.

(An area created when a short circuit occurs between 104 and 106 inside the positive and negative electrodes inside the battery.)

(The short-circuit area may be considered as the area of the nail or spike like attack when the battery is subjected to a collision, impact, accident, etc., and the structure of the battery causes each electrode to stretch, tear, or deform, resulting in a contact between said electrodes).

### <Explanation of FIG. 10>

3BATT: A battery system that adds a mechanism to 2BATT to control 106 by sensor measurements.

3SEN: A sensor that obtains information from the surrounding environment to control the conductivity of the conductor element 1. Means of measurement.

3A: Acceleration sensor, shock sensor.

3S: Strain sensor (detects battery deformation due to external shock. In the case of a strain sensor attached to a battery, it also detects swelling of the battery or battery pack, etc.).

3K: Contact sensor (sensor for detecting contact of an object toward the battery).

3T: PTC element, temperature sensor, temperature measuring means.

3C: Controller, control unit, control means. (May include a computer or other control unit and a gate drive unit.)

3CBATT: Battery controller, of 3C. 3CGATE: Controller of gate 106. controlled by 3C.

3BC: battery enclosure, container (container containing the battery system).

3BCE: The ambient environment of the device containing the conductor element 1 (in the figure, the ambient environment of the battery 2BATT).

3COMM: 3C communication device, means of communication.

It may communicate wired or wirelessly with other communication devices.

Communicate wired or wirelessly with other communication devices.

Communicate wirelessly with other communication devices.

C2: External computer.

A terminal that can communicate with 3C using 3COMM and C2 communication devices.

(The control method, program, algorithm, and variables for controlling the gate electrode of 3C may be exchanged, changed, and updated by C1 through communication. Other, For maintenance and inspection of 3s such as 3BATT, about C2 which can access to 3C, C2 may command 3C to turn the gate electrode on or off, or C2 may command to change the voltage value or polarity.)

C1: A computer or other device that uses 3BATT.

For example, an in-vehicle computer C1 that controls an automobile, is equipped with an in-vehicle camera CAM connected to it, takes pictures of the external environment from the CAM, and detects vehicles and objects that may collide with the C1/vehicle.

C1 may also be the control computer C1 of an aircraft or other transportation machine equipped with batteries.

In the case of an aircraft, a sensor can detect a crash before the crash (or have a means of sensing and measuring the crash) and set the battery resistance to a high level to prevent the battery case from being destroyed in a crash, resulting in a short circuit between the positive and negative electrodes and causing a fire or explosion.

When the 3CBATT of C1 may be damaged, send gate electrode voltage control data and commands to 3C (3CBATT) of 3BATT to reduce the conductivity of the battery electrodes so that the electrodes are in a state of reduced conductivity.

(At a car containing C1 and 3BATT collides and 3CBATT is destroyed, causing an internal short circuit, the resistance of the electrodes of 3BATT is increased to prevent ignition and explosion due to an internal short circuit between positive and negative electrodes.)

C1SEN: Sensor of C1.

CAM: Camera as a sensor of C1.

(When a car containing C1 and 3BATT collides and 3CBATT is destroyed, resulting in an internal short circuit,

### <Supplement to FIG. 10>

In the example in FIG. 10, the battery using the conductor element 1 is equipped with a sensor and a controller, and the controller controls the gate drive circuit according to the value measured by the sensor to control the voltage applied to the gate 106, 104 or 1042 (and 104I or 1042I depending on the type of 101 or 1012) is controlled, formed or lost,

Increase or decrease the conductivity of 101 or 101P,

The configuration reduces conductivity when it is desirable to reduce conductivity,

The above configuration can be used not only in batteries, but also in 3FILM with 1FILM and 3WIRE with 1WIRE.

The 3SEN can be used not only in the form of a battery, but also in a wide range of electronic components 2/electronic electronic products using conductor elements 1, which can be controlled by sensors using 3SET, 3C and 3CGATE.

The aforementioned 3SEN may use known types of sensors.

For example, the 3SEN can be an acceleration sensor (3-axis acceleration sensor), magnetic sensor, temperature sensor, humidity sensor, air pressure sensor, pressure sensor, strain sensor, contact sensor/touch sensor, illumination/light sensor, infrared sensor, camera/scanner/imaging device, smell sensor, fire sensor/smoke sensor, sound sensor, wireless sensors (wireless receivers) may be used.

An external computer C2 may access 3C (using 3C's 3COMM communication device) via wireless or wired communication to change the programs, etc., variables, etc., of the control of the conductive elements of conductor element 1.

The voltage VGS of the gate 106 of the conductive element 1 may be controlled by an external computer C2 via wireless or wired communication through 3C's 3COMM.

<Temperature sensing type device>

For example, 3WIRE is equipped with a temperature sensor 3T and a control unit and gate drive unit, and 3WIRE detects the temperature rise due to heat made by leakage fire or due to heat generated before leakage fire at 3T, and 3WIRE detects the temperature rise and it may be conceivable to prevent fires in the form of control to increase the resistance of conductors and make it difficult for current to flow.

In the event of a building fire, 3WIRE in the power distribution network connected to the room or compartment of the fire origin could be fused to prevent the current from flowing to said room or compartment of the fire origin.

(3WIRE could be configured like a large fused element with increased resistance due to temperature rise.)

By installing acceleration sensors (or 3-axis acceleration sensors) not only in 3BATT but also in 3WIRE and 3SEN of 3FILM, and a system of conductor elements with a control section that increases or decreases the conductivity of 3WIRE or 3FILM in response to acceleration (by sensing the inclination of the wire in response to gravitational acceleration or with respect to the direction of gravitational acceleration) could be configured.

*For example, at electric wires in the city/ground/mountain made using known technology such as using power distribution networks or transmission networks are constructed using poles with horizontal or sagging electric wires as overhead wires to supply electric power. Electric wires for trains and telephones are also strung around the area.

In the above systems (where power lines are not undergrounded, are in the air, and hang down when they are cut), electric wires or power lines that were laid using poles are cut by typhoons or fallen trees or etc, and the power line/wire fall and hang down or drop down according to gravity.

Since a hanging/dropping conductor is always a conductor, and usually has a copper or aluminum section, and electricity (or electric power) can flow even in the hanging state because said metal section does not change in conductivity with hanging/dropping or tilting. Therefore, the conductor system 3WIRE could also be considered, which detects drooping by an acceleration sensor when the wire droops, and conveys the anomaly detected by the sensor to said C2 through communication between the control unit 3C of the conductor system and the external computer C2.

3WIRE, which includes accelerometer 3A in 3SEN in this application configuration, measures the acceleration change and the acceleration at the time of hanging or falling when the wire is broken or when the wire is falling or hanging, and controls the voltage VGS of the gate electrode 106 according to the measurement results.

If the acceleration sensor measures the condition of drooping or sagging (when the wire is dropping or sagging in the same direction as the direction of gravity), the gate 106 can be controlled to reduce the conductivity of 1WIRE or 3WIRE.

Or conductive 1WIRE, 3WIRE (and 1FILM, 3FILM) may be provided with a tilt sensor (using an acceleration sensor) and controlled to increase or decrease conductivity according to the tilt of the 1WIRE, 3WIRE (and 1FILM, 3FILM).

“This application claims the benefit of foreign priority to Japanese Patent Application No. JP2022-123161, filed Aug. 2, 2022, which is incorporated by reference in its entirety.”

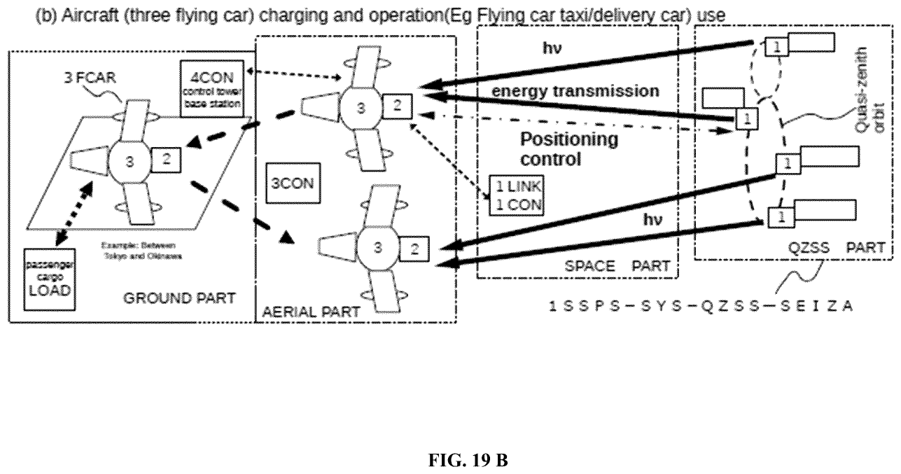

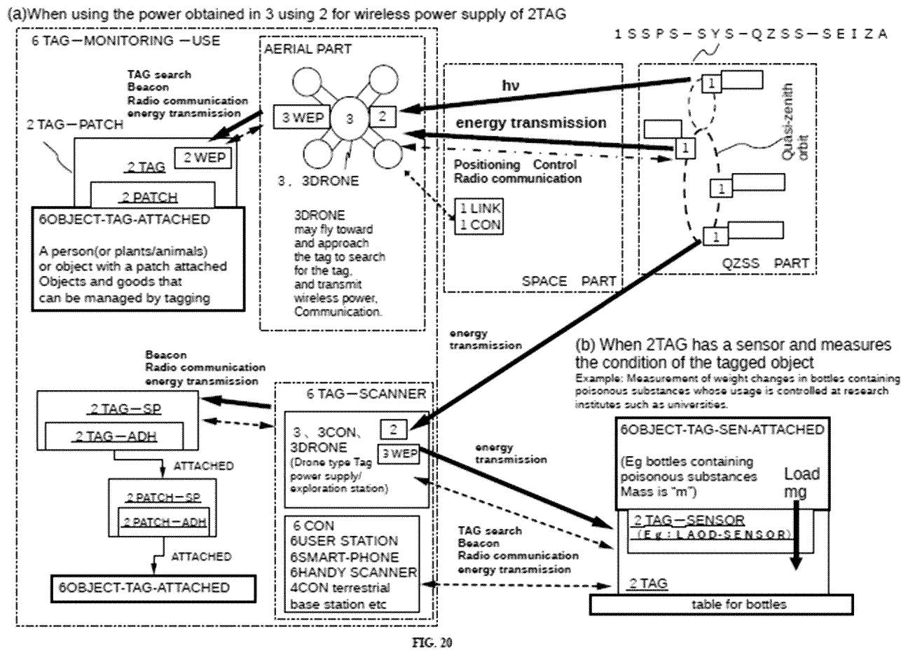

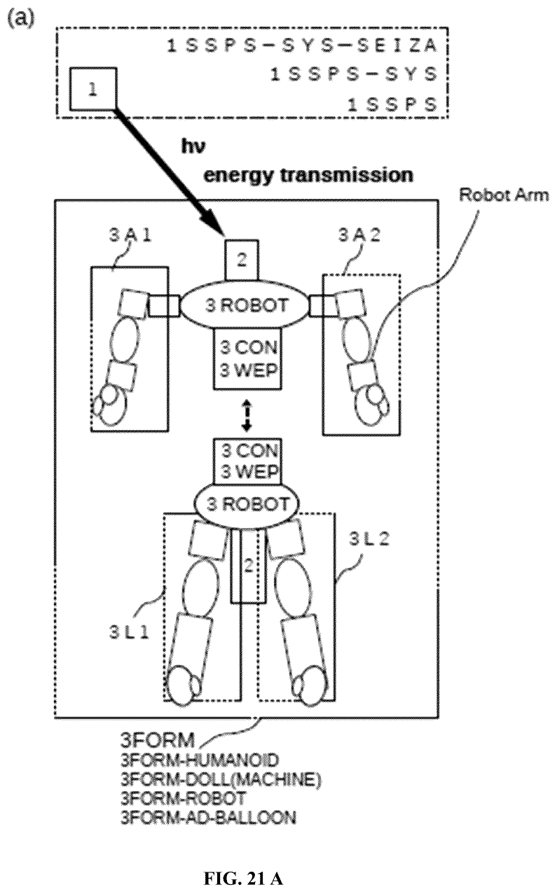

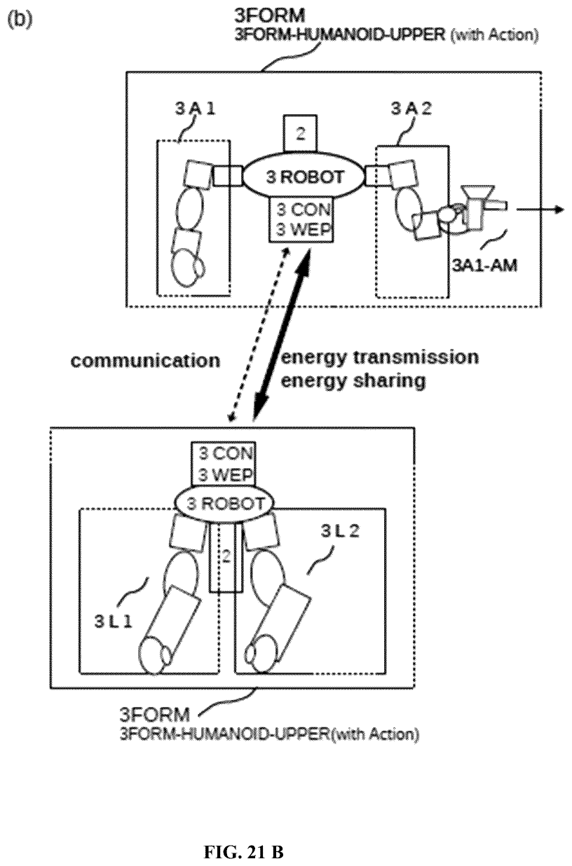

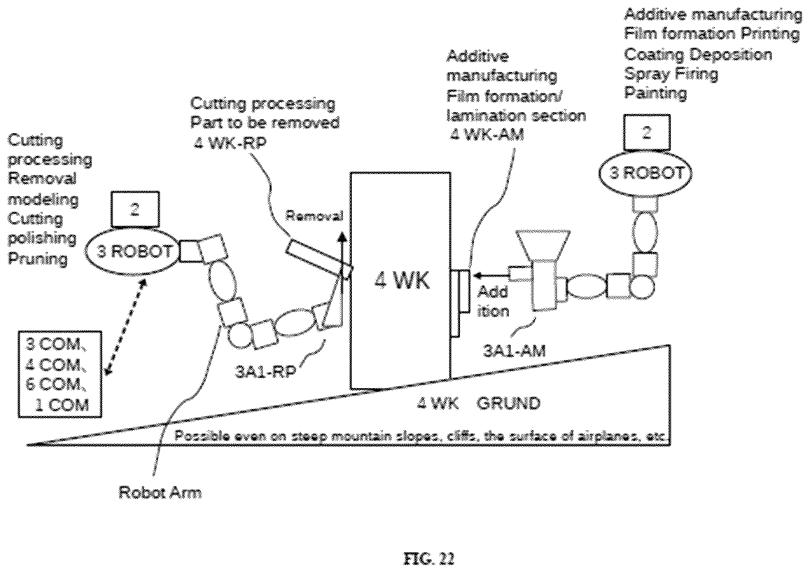

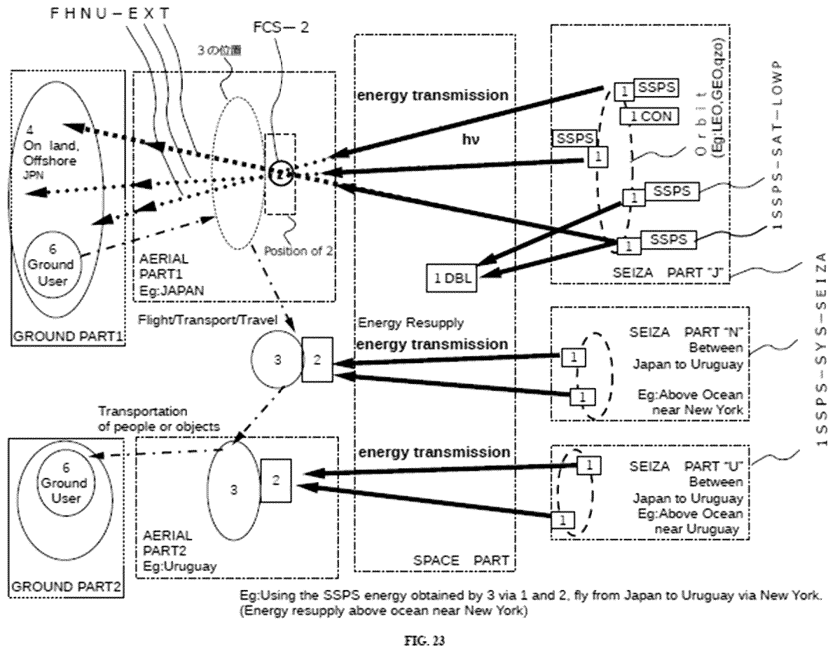

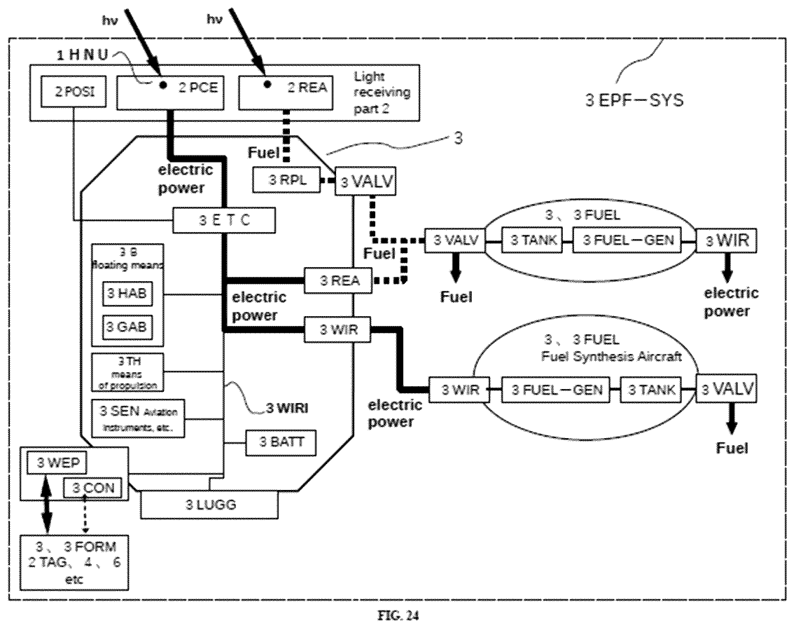

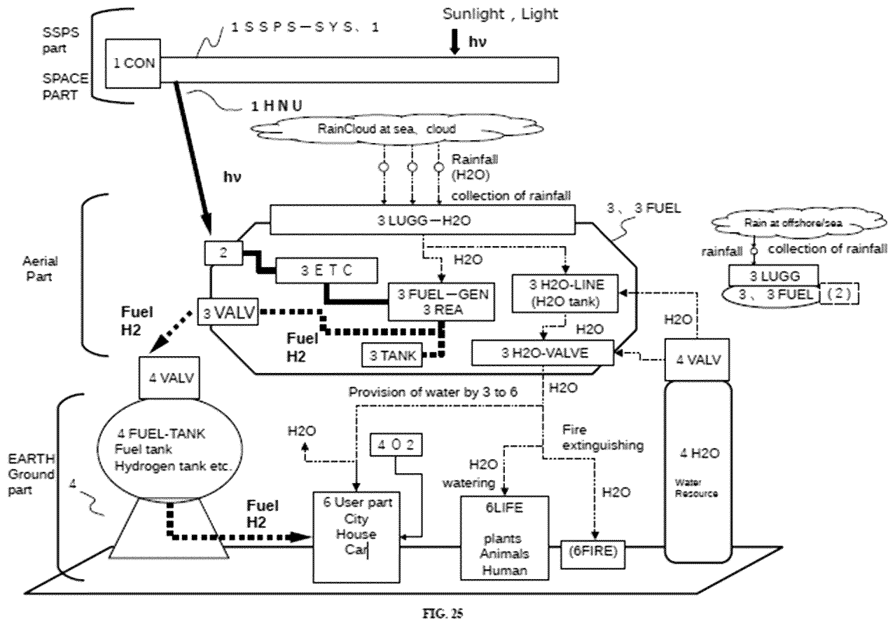

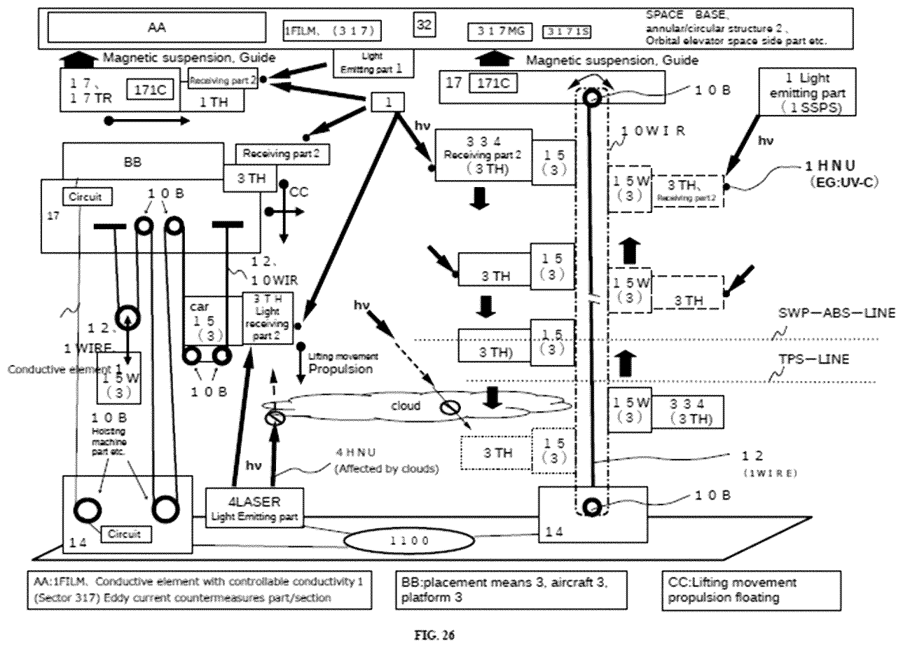

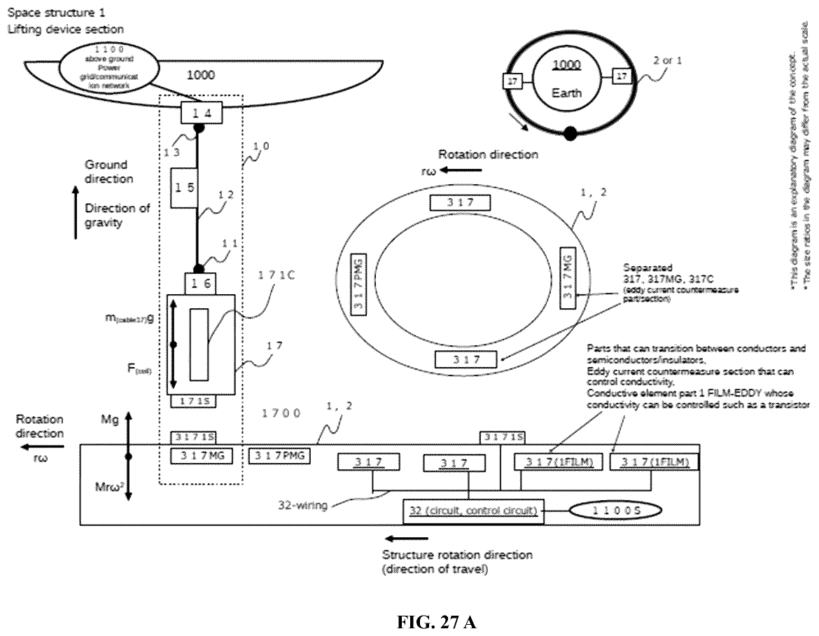

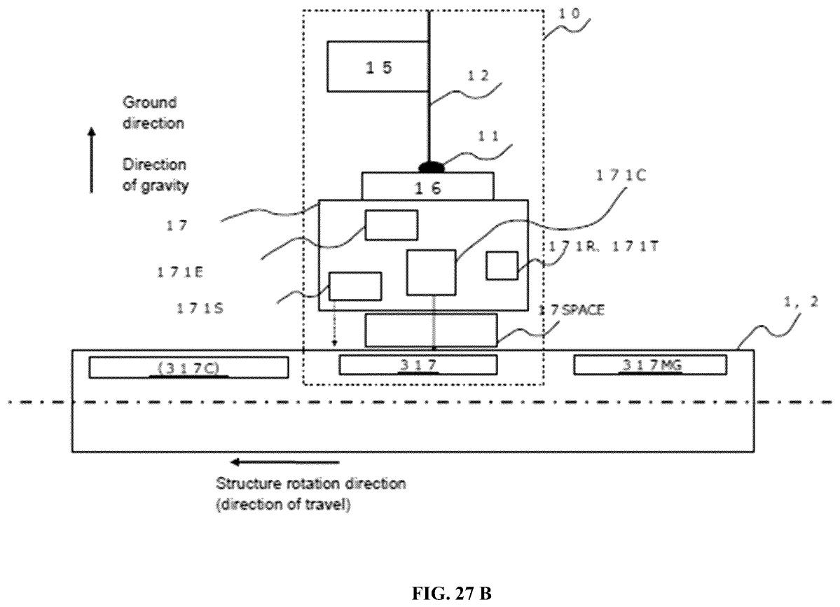

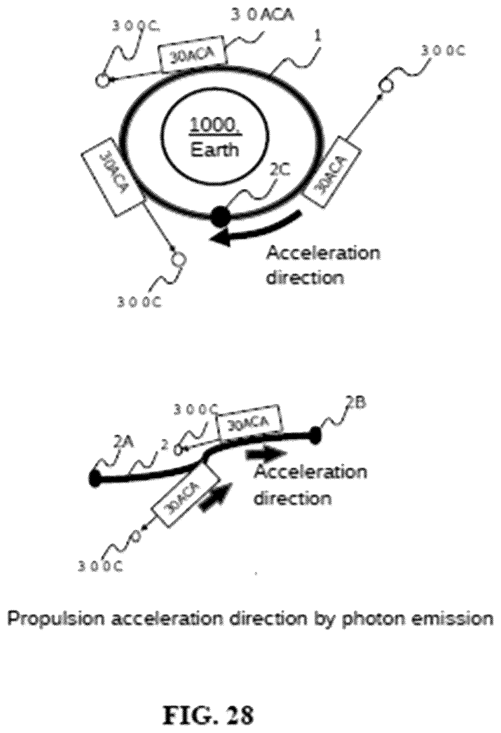

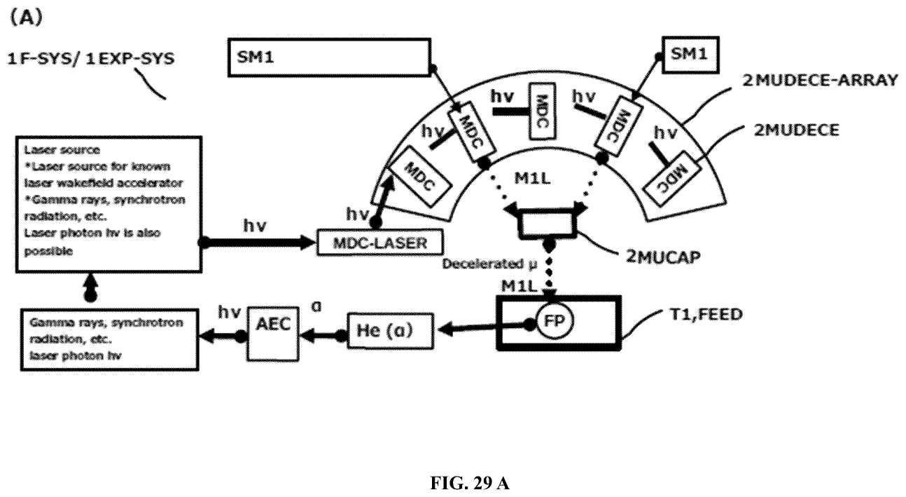

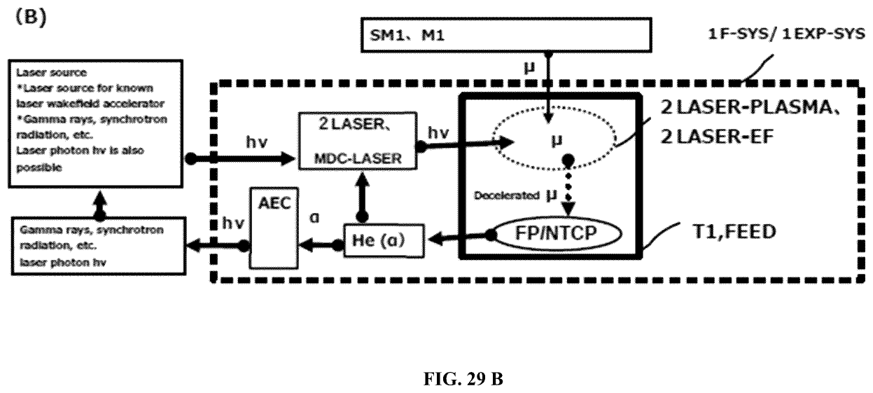

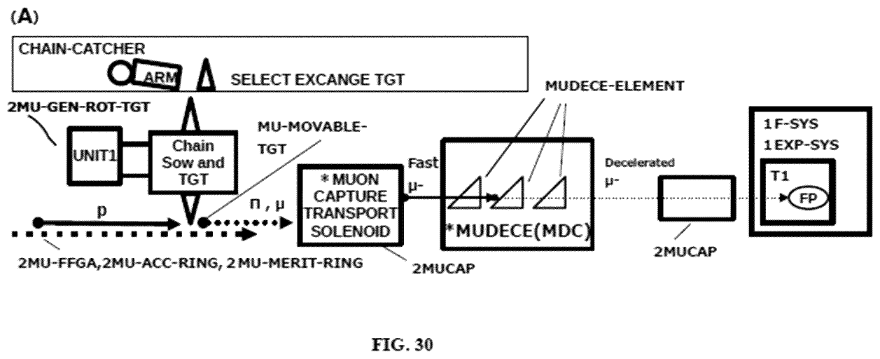

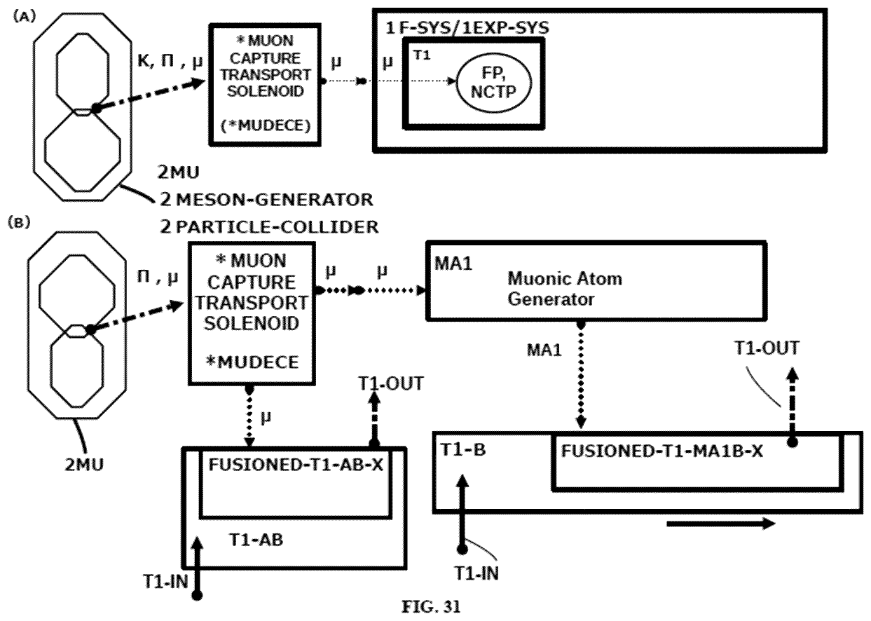

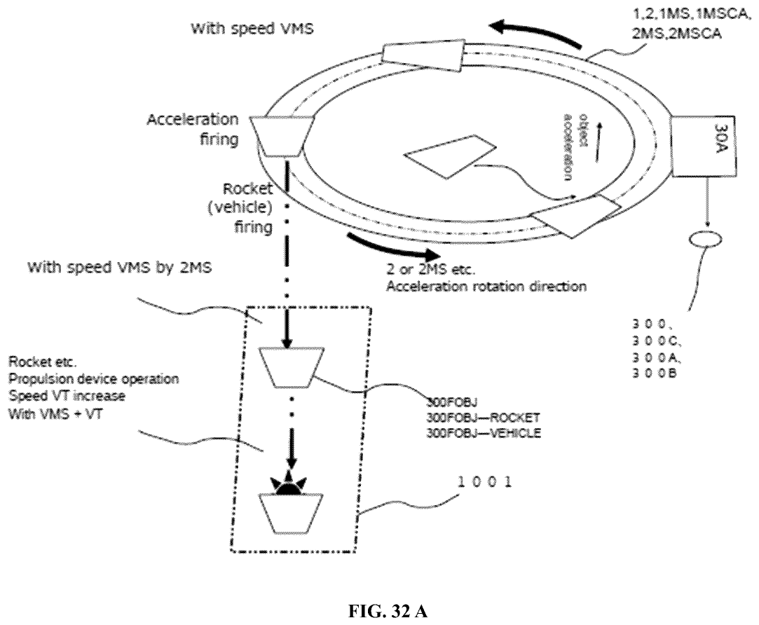

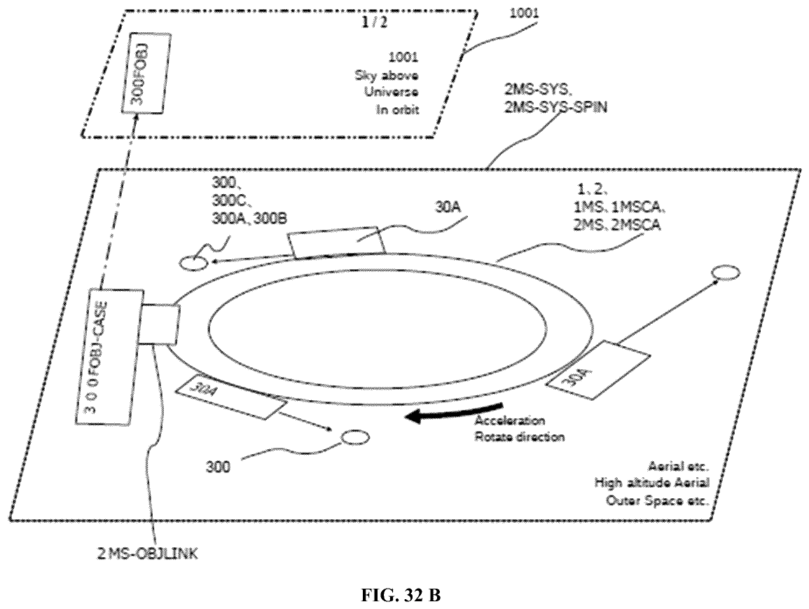

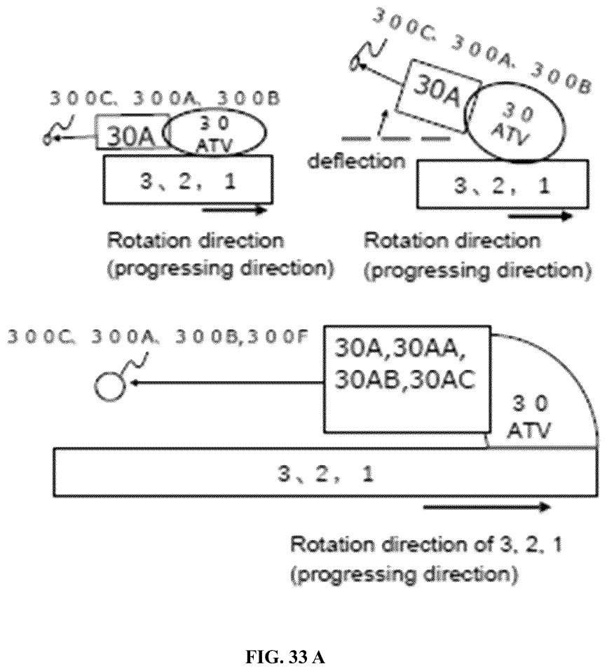

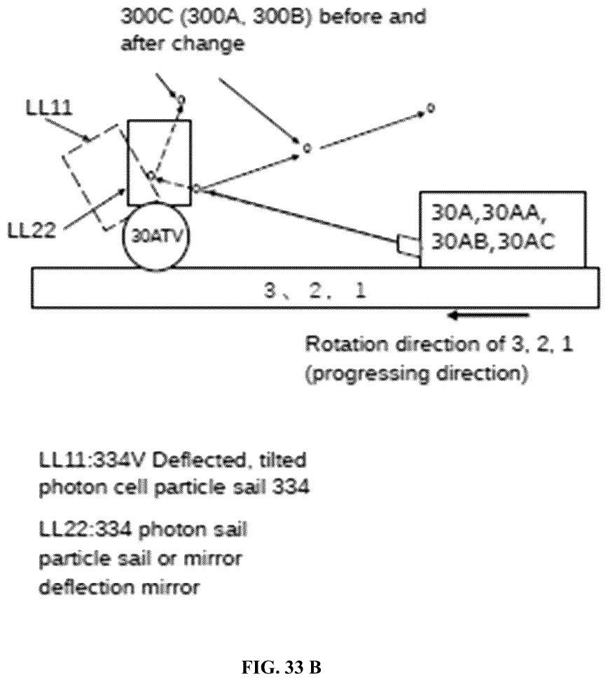

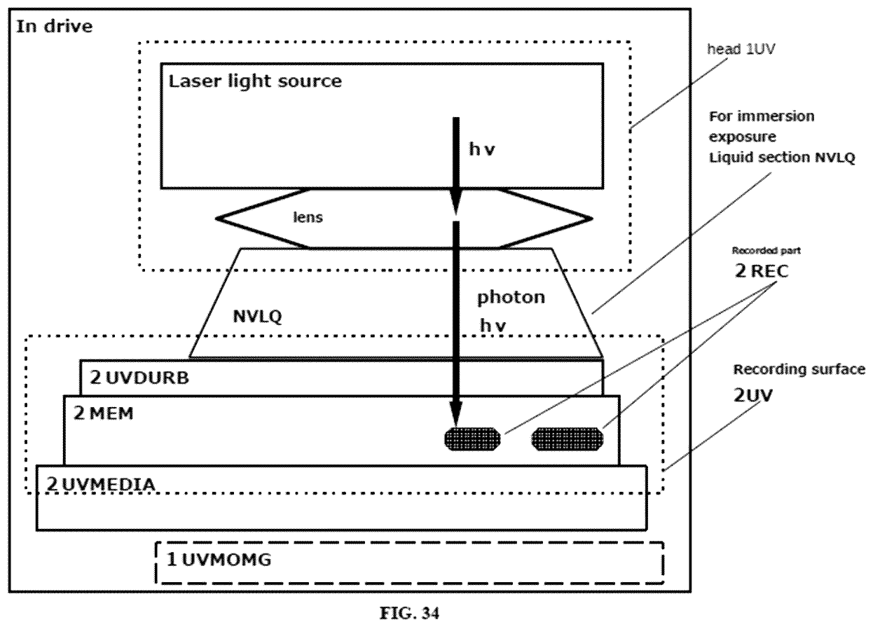

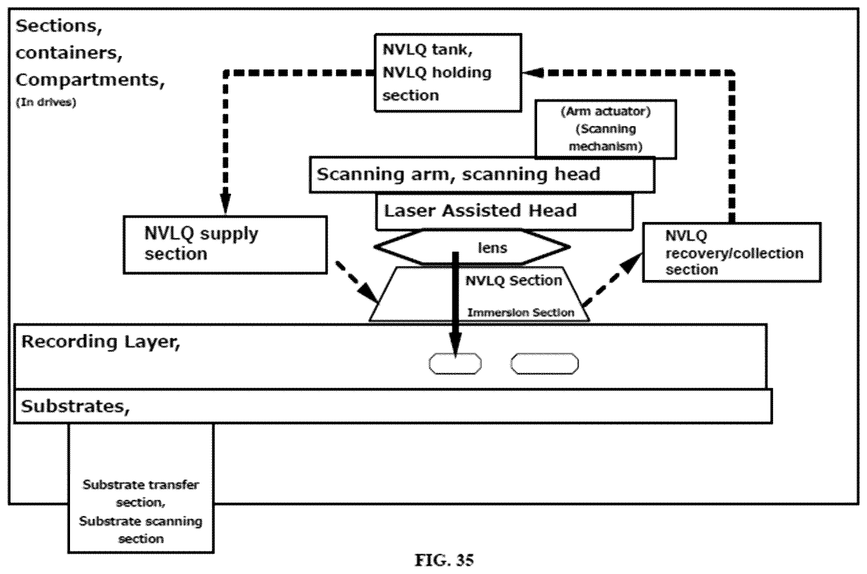

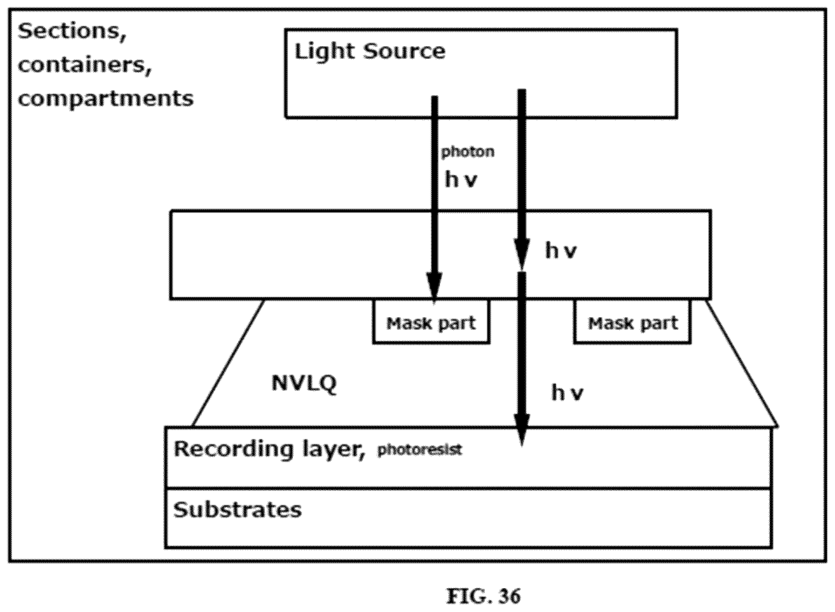

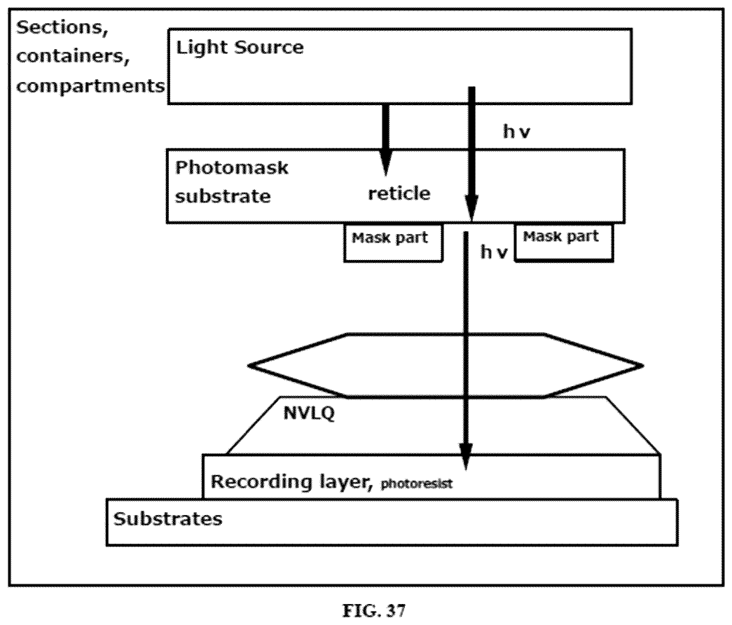

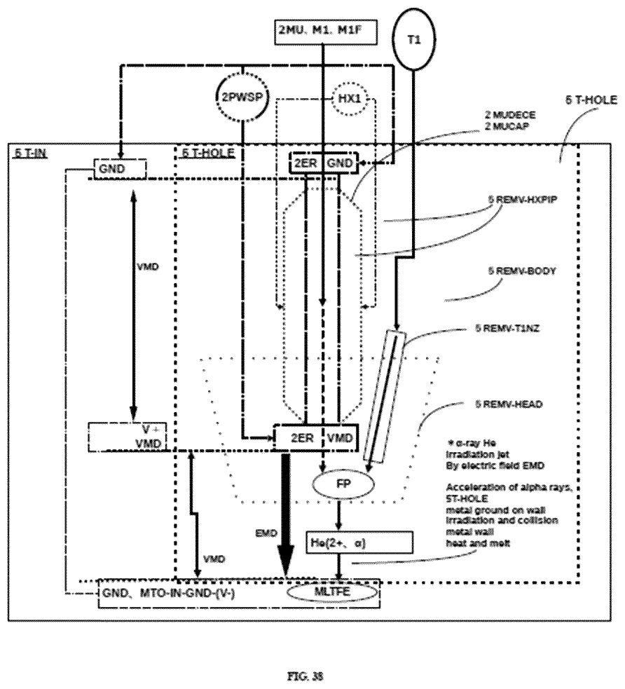

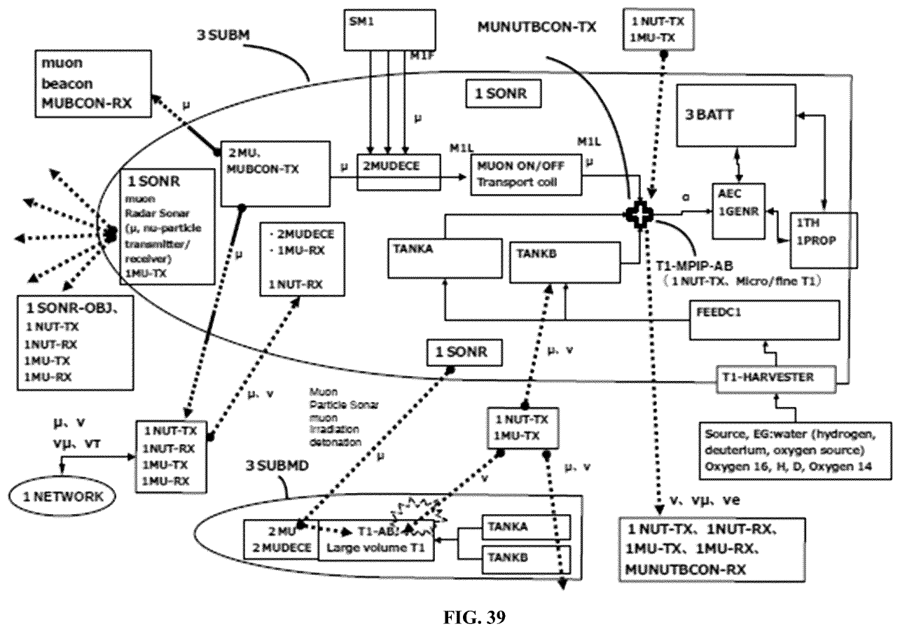

0060<Contents of the Earlier Priority Application, JP-Application No. 2023-007722> This application is cited with reference to JP-Application No. 2023-007722. The description and drawings (FIGS. 1 through 12) in paragraph 0060 of this application are the same as the description and drawings in JP-Application No. 2023-007722. FIGS. 1 to 12 described in paragraph number 0060 of this application correspond to FIGS. 14 to 25 described in paragraph number 0037 of the “Brief Description of Drawings” section of this application.

<Document Title> Description <Title of Invention> Method of transporting energy of space solar power generation system, method of transporting energy from space to earth <Technical Field> <0001> This application relates to a power transmission system and method of transporting energy between space, air and ground of space solar power generation system. It also includes a method for transporting energy from space to earth. <Background Technology> <0003> In Space Solar Power Systems (SSPS: Space Solar Power Systems), it was necessary to deliver the power and energy obtained by the solar power generation system (or solar energy collection system) placed in space to the ground and the users who have power and energy demand on the ground. The power/energy obtained from the solar power generation system (or solar energy collector) placed in space needs to be delivered to the ground/user's area with power/energy demand on the ground. <0004> <Wireless Power Transmission System> Therefore, wireless power transmission, wireless power transmission, and wireless transmission that transmits power from SSPS to the ground via outer space and the air are being considered, as shown in Patent Document 1 and Non-Patent Document 1.

Two types of wireless power transmission have been proposed and studied: those using radio waves such as microwaves, which are also photons with long wavelengths, and those using photons such as infrared rays and their laser beams, which are photons with short wavelengths. Wireless power transmission and power supply to electrical devices such as smart phones, electric vehicles, and wireless tags are also being considered. <On the other hand, there may be systems that do not use wireless power transmission or wireless power transfer, but consume power on site near the SSPS, or produce fuel materials, energy storage materials, or objects on site and transport them to the ground or other locations. It is preferable if the power generated by the SSPS can be used onsite after generating power in space, at a space base, or at a lunar base. As a case of on-site use, as shown in FIG. 3 and FIG. 4, for example, a system that produces some kind of fuel using electricity on the moon (or in space) and delivers it to a space base or on the ground may be considered. <0006>• As shown in FIG. 3, if water (an oxide of hydrogen) is sent from the ground for fuel synthesis, for example, and the water is electrolyzed on the lunar surface to obtain hydrogen and oxygen, which are then delivered to the ground again, the launch means 9 such as a rocket (or a means 9 to drop a rocket from the moon to the ground) is expensive. However, if the launch cost is reduced, this method could be used. Low-cost launch vehicle methods and non-rocket methods such as mass drivers and orbital elevators are expected to be realized. * It would also be desirable to have a low-cost launch means9 for launching parts and base materials for the construction and building of the SSPS. Since this application is not a device for launching means, the details of the launching means, such as mass drivers, are omitted. <As shown in FIG. 4, silicon dioxide (or metal oxides such as aluminum oxide, iron oxide, or oxides on the lunar surface such as water or oxidized hydrogen-containing materials) contained in lunar rocks and other resources are reduced by electric power obtained from the SSPS to obtain reduced materials such as silicon metal, which are then transported and dropped to the ground, The reduced substances such as metallic silicon may be oxidized by some method on the ground to obtain energy by redox. However, this system may reduce the mass of the Moon. <In the above proposal to transport fuel materials, materials on the Moon can be mined, reduced or stored, and shipped to the surface at the beginning of the fuel production project. However, in the long run, it is necessary to launch objects to the Moon to compensate for the amount of objects removed from the Moon, and an inexpensive launch method is needed to restore the mass of the Moon. • There may be an inexpensive method of launching objects from the ground to the moon or a mass driver9 that sends them from the lunar surface to the earth. (It is desirable to develop non-rocket launch methods in the areas mentioned in Patent Document 2, and to develop the use of reusable rockets.)<According to Patent Application 2021-181539 and Patent Table 2022-527127, functional films (semiconductor films, metal films, etc.) are formed using the vacuum of space to manufacture large-area components such as solar cells, radar, and mirror devices (telescopes, reflectors, and large-area mirror devices that reflect sunlight). The system using SSPS shown in FIG. 4 of this application can be used for (in-situ) manufacturing of solar cells and devices that collect and utilize solar energy in the vicinity of space and lunar bases by those methods. <0010>• Inorganic materials such as silicon dioxide contained in the Moon may be used to manufacture solar cells and devices that collect and utilize solar energy. Materials and resources on the Moon may be used to reduce the number of components to be launched from the ground. For example, on the lunar surface in FIG. 4, solar cells may be manufactured by reducing silicon oxide SiO2 to obtain silicon Si using lunar resources (silicon oxide and other inorganic materials), SSPS electricity, and manufacturing equipment brought from the earth, and then manufacturing silicon solar cells for use in the SSPS, or crystalline silicon Si manufactured for solar cells and silicon/polysilicon cells manufactured for solar cells that are not of solar cell grade may be used. Silicon Si produced for solar cells, non-solar cell grade silicon, polysilicon, and metallic silicon mixed with impurities (reduced material 5MC is also acceptable when described so as not to limit the scope of the invention) may be used as fuel on the Moon or dropped on the ground. The fuel production method shown in FIG. 4 may be used to reduce the number of components to be launched from the ground. <0011> Or, as described in JP 2021-181539, solar cell materials may be transported from the ground to outer space and the moon using the launch system 9, and the solar cell materials may be used to manufacture solar cells and devices (solar cells, mirrors, reflectors) to collect and utilize solar energy. <0012> The solar cell material may be used to produce solar cells, mirrors, and reflectors. <0012> When launching from the ground, resource-saving materials (examples of such materials: compound semiconductor materials, used in CIGS solar cells, etc.) may be used, which are direct-transition type and have a large light absorption coefficient and require a thin photoelectric conversion layer or functional film for photoelectric conversion. When opaque materials such as gallium and indium that can be mined on the moon are required, they can be transported from the ground. <This application discloses a method of transporting energy including wireless power transmission, wireless power transmission, wireless power transmission, wireless power transmission, wireless transmission, and fuel transportation. In this application, wireless power transmission methods may be used from SSPS to ground or air. According to Non-Patent Document 1, power transmission by microwave or laser light has been considered. However, when receiving microwaves or laser beams emitted from the SSPS, if the transmitting power is high, there is a risk of affecting or damaging the human body, organisms, environment, electrical equipment, wireless equipment, or communication equipment near the receiving or transmitting part on the ground side. As a remedy for this problem, it is assumed that the transmission power can be reduced. <0014>—In the present application, the area of the receiver 2 and receiver 2 may be made large, and even with low transmission power, the receiver 2 and receiver 2 may be configured to receive and receive light using a large area (such as a rectenna in the case of microwaves, a photodetector, photocell, solar cell, reactor, chemical reactor, chemical reactor using light or heat, etc. in the case of lasers). (For example, the energy density of sunlight is rare. (For example, the energy density of sunlight is very low, but the light emitted by the transmitter of SSPS can be received by a large-area receiver on the ground, just as sunlight is received by a large-area solar cell on the ground. The system is designed to be used with a large area for the receiving part 2 and the receiving part 2 in the case of microwaves and radio waves, which leads to high costs and the problem of securing a site. In addition, because the photons used for transmission (in the form of laser light and radio waves) have wavelengths that penetrate the atmosphere, even if the transmission output is reduced, residents near the receiver and receiver may be concerned that photons with wavelengths that penetrate the atmosphere may reach or be received. The problem may be that the SSPS satellites are oriented slightly differently, so that photons and radio waves that penetrate the atmosphere can be transmitted to and reach residential areas that are not in the receiving area, and using photon types and wavelengths that may cause people to worry in this way. • There was a challenge that delivering SSPS power to the ground in the form of photons that can penetrate the atmospheric window in this way may have a negative impact on people, organisms, and the environment living on the ground. <0016> <A method in which photons with wavelengths that are difficult to reach the ground are received by an aerial structure 3 above the earth> In the case of reception by equipment 2 on the ground, the above issue could arise by using photons that can penetrate the atmosphere.

Therefore, this application proposes to configure a wireless power transmission system (wireless power transmission system) for SSPS using photons that do not or do not easily penetrate the atmosphere, and to use it for transmitting, transmitting, transmitting, and transmitting power or energy for SSPS. <0017> In order to receive photons that do not penetrate the atmosphere (e.g., in the upper troposphere, stratosphere, or upper stratosphere) by the receiver 2 of FIG. 1, we propose to use a high-altitude communications platform (HAPS) 3 or an aircraft 3 or an electric balloon 3 located at high altitude in a low-density or rarefied atmosphere in the upper atmosphere. Aircraft 3 equipped with SSPS receivers 2 (airborne receiver/receiver 2, high-altitude receiver/receiver 2) as shown in FIG. 1, FIG. 2, etc. of this application, and SSPS and other transmitting and emitting units 1 and emitting units 1 (SSPS and SSPS relay satellite 1 LINK that links the laser light from the SSPS and SSPS) located in outer space, SSPS and The laser light with the wavelength of the photon that does not penetrate the atmosphere transmitted, emitted, irradiated, or emitted from the transmitter 1 and light emitter 1 that may be included in a group or constellation of SSPS relay satellites) is emitted, irradiated, or transmitted to the receiver 2 and light receiving unit 2 (or the laser light of light emitter 1 is hit, received, or photoelectrically converted to light by light receiving unit 2), and the laser light is then transmitted, irradiated, or emitted to the receiver 2 and light receiving unit 2. The application proposes to perform wireless power transmission and wireless energy transmission. <0018> <Comparison with Previous Reports> FIG. 1, etc. of Patent Document 1 discloses a configuration in which a receiver (1) is provided on an airship (5) in the air above the troposphere (altitude 10 to 16 km) that receives microwave and laser beams. In this application, the receiving unit 2 and the aircraft 3 may be located in the stratosphere at an altitude of 50 to 20 km. (*Aircraft have been used in high-altitude balloons to raise balloons to an altitude of 53 km. (*Aircraft experience of ballooning to an altitude of 53 km in a high-altitude balloon, viewed Jan. 19, 2023, Internet, JAXA, https://www.jaxa.jp/press/2013/09/20130920_ballon_j.html)<0019> <Atmosphere density and composition at high altitude>• In the troposphere Oxygen and ozone exist as on the ground, and the atmospheric density in the troposphere is 13% of the density on the ground (1.293 kg/cubic meter). In the higher stratosphere (above 20 km altitude where the stratospheric platform is located), the atmospheric pressure is 100 hPa at 20 km altitude and 0.013 kg/cubic meter at 32 km altitude. At an altitude of 40 km, the atmospheric pressure is 10 hPa. (Reference: Japan Meteorological Agency HP, Structure and Flow of the Atmosphere, viewed Jan. 8, 2023, Internet, https://www.jma.go.jp/jma/kishou/know/whitep/1-1-1.html) • At an altitude of 16 km, the troposphere and Above its boundary, the atmospheric density is 0.16 kg/cubic meter, and at an altitude of 32 km, it is 0.013 kg/cubic meter. (At an altitude of 68 km, the atmospheric density is 0.00011 kg/cubic meter, and the atmospheric density and oxygen density decrease in the vicinity of the stratosphere. Therefore, the upper stratosphere at an altitude of 32 km is preferable to the troposphere at an altitude of 16 km in order to receive short wavelength photons such as UV-C (short wavelength photons from ultraviolet rays to X-rays), which react with oxygen and UV light, without attenuation in the projectile line when they reach the photoreceiver. Therefore, in this application, the altitude of light receiving unit 2 and aircraft 3 should be in the stratosphere at 50 km to 20 km altitude. (However, in the case of using an aircraft 3 including the receiver 2 and a fuel composite aircraft 3FUEL in the examples in FIGS. 1 and 2, etc., 3, which is also 3FUEL, may navigate from the ground to the stratosphere and may be used without keeping the altitude of 3 constant or asking any questions). <0020>

<Air density and photon absorption in the troposphere and on the ground>—The upper troposphere is 13% of the air density on the ground, which is about one-tenth of the air density. For example, the degree of absorption of short-wavelength photons closer to the ultraviolet side, which react with oxygen and ozone, is also about one-tenth that of the ground in the upper troposphere, which is less than the degree of absorption on the ground. Even if the altitude of the photodetector 2, which receives the aforementioned short-wavelength photons, is set at the altitude of the upper troposphere (16 km altitude), even if a certain amount (X %) of photons of a certain wavelength are absorbed by the atmosphere at 16 km altitude, the remaining amount (100%-X %) may still be received by the photodetector 2, This may be practically usable in a configuration that uses photons that are less likely to penetrate the atmosphere. Therefore, it is necessary to determine the conditions for the altitude from the ground where Photodetector 2 should be located through demonstration and development. This application discloses the use of ultraviolet photons such as oxygen and ozone, or ultraviolet and some infrared photons absorbed by the atmosphere, as atmospherically attenuated photons or laser beams for SSPS energy transport in the air and on the ground, and does not consider limiting the altitude of the photosensor 2 to the stratosphere. (For example, this application discloses several cases of photons on the short wavelength side near ultraviolet light, where the energy of a single photon is large and can be absorbed by the atmosphere, oxygen, and ozone. (In addition, there are wavelengths in the infrared wavelength range that are absorbed by atmospheric molecules, and photons at these wavelengths may be used in the light receiving unit 2 of this application.) One purpose of this application is to ensure the safety of people's homes on the ground and aircraft navigating in the troposphere, and to use photons that are difficult to reach on the ground, so that photons missed by the light receiving unit 2 due to misfiring from the light emitting unit 1 do not reach the ground. The light-receiving part 2 can be placed at an altitude above the troposphere (from 16 km altitude) as described in Patent Document 1. The receiver 2 may be placed at an altitude of 20 km to 50 km from the ground, or at an altitude of 50 km or higher. <0021>• The light receiving unit 2 may be mounted on an aircraft 3, which may be equipped with a propulsion device 3 such as a motor, jet engine, rocket, photon sail or ion propulsor, in addition to a motor or jet engine, in order to control the attitude, change direction and move the aircraft such as propulsion, even at altitudes where a propeller motor or jet engine cannot operate (thin air). The aircraft 3 may be equipped with a propulsion system 3TH such as a rocket, photon sail, or ion propulsion system, in addition to a motor or jet engine. (The aircraft 3 of this application may also be an aircraft 3 that is a solar plane 3 such as the configuration of FIG. 11 of this application or FIGS. 6 and 7 of Patent Document 2.

It may also be an aircraft 3 that is a high-altitude platform HAPS.)<In an SSPS that can always transmit energy to the light receiving unit 2, the power and energy from the SSPS is transmitted from the light emitting unit 1 to the light receiving unit 2, and the energy obtained in the light receiving unit 2 attached to the aircraft 3 is used for heat to heat the gas and fluid of a hot air balloon or a roger balloon, for example, the aircraft 3 can be a hot air balloon or a roger balloon. Aircraft 3 may also be an aircraft 3 or solar plane 3 that contains elements of a balloon. <0023> <Light pollution>—In the form of this application, short wavelength photons from ultraviolet rays to X-rays are invisible to humans, so even in the middle of the night, there is the advantage of not seeing light. It may be possible to reduce effects such as light pollution at night. (When focusing on invisible photons with respect to light pollution, infrared and millimeter waves may be used in addition to ultraviolet light.) <0024> <Short-wavelength photons proposed in this application>—This application may use systems such as UV—C and UV-B, which are absorbed by chemical reactions with oxygen and ozone in the atmosphere (the atmosphere at altitudes of 20 km to 50 km from the ground or higher). This application uses the atmosphere. <The present application uses the atmosphere and troposphere, where the laser cannot penetrate the atmospheric window, and where the wavelength of the laser photons, for example, is not close to UV-C (wavelength 280-200 nm), far UV (200-10 nm), vacuum UV (or safe for use), and other UV (or safe for use). UV-B (wavelength 280-200 nm), far UV (200-10 nm), vacuum UV (200-10 nm), and short wavelength photons such as UV-B (or X-rays and gamma rays if safe and possible at the time of use) are also acceptable. <0026> UV-B and UV—C are absorbed by ozone and oxygen, atmosphere, and ozone, respectively, and have the advantage of not reaching the ground easily. It can be used in the system of this application. <Since ultraviolet rays including UV-B and UV-C have large photon energy per photon, the photovoltaic power can be increased by downsizing the reaction device that holds the energy obtained from the light receiving part 2 or by increasing the semiconductor band gap of the photoelectric conversion device (photovoltaic cell). This may lead to downsizing and higher power output of the photodetector 2. <0028>• The aforementioned ultraviolet light has higher energy per photon than visible light, infrared light, and radio waves, and is easily used to cause chemical reactions in substances, which is also beneficial in terms of fuel production. Considering photocatalysis, for example, low-energy photons such as millimeter waves and infrared rays will not cause photocatalytic reactions using titanium dioxide. Photocatalytic reactions occur with photons such as ultraviolet rays that have energy higher than the band gap of titanium dioxide. If photoreceiver 2 is a photocatalytic device/reactor, photocatalytic reactions cannot occur in photoreceiver 2 in systems using microwaves or millimeter waves, but in systems using ultraviolet rays (UV-A, UV-B, UV-C), as claimed in this application, photocatalytic reactions can occur in photoreceiver 2. <0029> <0029> This is a photocatalytic reaction. <0029>• In the case of making fuel by photocatalysis or chemical reaction of light and substance, there may be an advantage of using photons such as ultraviolet rays in the photosensor 2. <0030> <0030> Photons in the form of radio waves, such as millimeter waves and microwaves, cannot be used for chemical reactions and may have low electromotive force in the photoelectric conversion device. (*When an object is heated in receiver 2 regardless of the magnitude of photon energy, it can be heated by radio waves such as millimeter waves and microwaves. (*In case of heating an object by radio waves such as millimeter wave or microwave, it is possible to heat the object by millimeter wave or microwave. 2 or 3 used for heating by microwave radio waves may be used for heating a hot air balloon or an element for heating gas in a hot air balloon.)<0031>• Radio waves require large-area rectenna, etc., and it is difficult to concentrate the energy like laser light. On the other hand, in the form of tag 2TAG, beacon tag, and RFID tag described below, the energy is easily diffused and used for tag operation. Tag search from aircraft3, transmitting SSPS-derived energy in the form of laser light or radio waves to search for tags from aircraft (used for guarding) will be disclosed. <0032> The present application uses the wavelength of the photons used and the absorption and attenuation of the photons in the atmosphere for a fail-safe design in which the photons do not reach residential areas or houses under the atmosphere or troposphere and are attenuated. The intention of the aforementioned fail-safe design is to ensure that even if the attenuation is caused by misorientation of the transmitter 1 and the photons are irradiated in the direction of a human residence and not in the direction of the receiver 2, said photons are of short wavelengths, for example UV-B, UV-C to X-rays, which can act on atomic molecules and cause chemical reactions with atmospheric molecules and atoms. The photons are absorbed by the atmosphere and do not reach the ground (the number of photons reaching the ground can be reduced), and the fact that the photons do not reach the ground can be used to reduce the number of fixed-wing aircraft in the troposphere. (Designed to ensure safety for fixed-wing aircraft in the troposphere and for people and organisms on the ground by preventing photons from reaching the ground)<0033> <Generation and use of short-wavelength photons> An ultraviolet laser capable of emitting ultraviolet light, or a synchrotron or other particle accelerator that can generate X-rays, gamma rays, etc. from ultraviolet light (or free electron laser generator), may be used.

<0034> <0034> For example, an ultraviolet laser can emit ultraviolet rays. <0034>—For example, examples of ultraviolet lasers include known solid-state devices such as long-wavelength, mid-wavelength, and short-wavelength ultraviolet laser diodes composed of semiconductors such as aluminum gallium nitride AlGaN having a band gap equivalent in size to the energy of an ultraviolet photon, and such devices may be used. The light-emitting device using such semiconductors may be used. <0035>• Also, to enumerate without limiting the scope of the invention, a wavelength conversion device (for example, a device or element that converts wavelength from infrared light to ultraviolet light may be used; a system using a crystal that converts an infrared laser wavelength of 1064 nm using an Nd: YAG crystal to ultraviolet light of 266 nm is envisaged) Or an excimer laser device (e.g., generating UV-C photons with a wavelength of 248 nm when KrF is used), a vacuum tube device, etc. may be used. <0036> The above-mentioned short wavelength photons such as UV-B, (UV-A,) UV-C, far ultraviolet rays, vacuum ultraviolet rays, X-rays, gamma rays, etc. are generated by the light emitting unit 1 and transmitting unit 1, said short wavelength photons are fired toward the light receiving unit 2 and receiving unit 2 The photons may be irradiated or transmitted, and photoelectrically converted by the light receiving element 2PCE provided in the light receiving 2/receiving 2 to obtain electric power. Since this application is an invention/device related to the energy transport method of SSPS and its utilization, the detailed description of the device/element generating photons is omitted. <0037>• The energy of the aforementioned short wavelength photons may be irradiated to the reactor 2REA or fuel material to cause a chemical reaction to produce fuel (e.g. hydrogen from water in the receiver 2). (The energy of said short wavelength photons may also be used to produce fuel by irradiating a reactor 2REA or fuel material, e.g. to produce hydrogen from water in receiver 2, or to reduce terrestrial carbon dioxide to carbon/hydrocarbon and oxygen. The laser light is converted to photoelectricity at the receiver 2 and used as electric power to power 2, aircraft 3, transport equipment 3, aircraft formation 3 FORM, flying vehicles 3FCAR, robots 3, etc.)<As shown in FIG. 6 (a), the power converted photoelectrically by the light receiving unit 2 may be used to fly an aircraft 3 including 2 and operate the actuators and other electrical equipment of the aircraft 3. Also, as shown in (a) of FIG. 6, aircraft 3 may supply power to aircraft 3A1, 3A2, 3L1, and 3L2 in 3FORM, including aircraft 3, through wireless power transmission. Aircraft 3 may also be able to communicate with objects included in 3FORM such as 3A1, 3L1, etc. Aircraft 3 may share or exchange energy or power with objects included in 3FORM such as 3A1, 3L1, etc. by contact or non-contact means. <0039>• As shown in FIG. 6 (b), an aircraft 3 (3FCAR) containing 2 may be flown to transport passengers and cargo by using the power converted photoelectrically at the light receiving unit 2. <0040> As shown in FIG. 6 (b), an aircraft 3 may be equipped with a light receiving unit 2, and after having the aircraft 3 recharge secondary batteries such as lithium ion batteries or hydrogen fuel/fuel cell systems by receiving said photons at a suitable altitude, like a whale catching its breath, it may descend to the ground again and use 3 as transportation equipment 3 for transportation purposes. The aircraft 3 may be manned or unmanned. The unmanned aircraft 3 may be used for known operations, such as navigation to a destination, autopilot or autodrive, or dispatch of the aircraft 3 by a smartphone terminal (summoning the 3 from the air to the ground with a smartphone). It can also be used for monitoring operations, for example, to monitor the movements and threats of birds and animals in mountain villages suffering from bird and animal damage, or to provide security in towns. <0041> In the case of the unmanned aircraft 3, even if it encounters an accident, the damage can be reduced because there is no crew on board. In addition to automatic operation, the unmanned aircraft 3 can perform unmanned (programmed) formation flight 3FORM, perform tasks in agriculture, forestry, fisheries, and various industries, and can be used as a flying robot 3ROBOT, a passenger transport vehicle, or a vehicle for the passenger transport industry. The robot can be used for residential and real estate operations, such as vehicles for industrial applications, aerial hotels and aerial stations (aerial stay facilities and bases, such as space stations). <0042>• This application allows aircraft 3 (which are powered or energized from time to time by space solar power) to eliminate the refueling step as in jet engine aircraft or the recharging step as in battery-powered drones, reducing or eliminating the time the aircraft 3 has to wait back on the ground. <0043>• Even if the airport on the ground is not functioning and the aircraft cannot stay at the airport or refuel, in the system using 1, 2 and 3 of this application, 3 can recharge and refuel in the sky and can continue to fly even if the airport is not available. <0044>• In FIG. 6 (b), three 3FCARs are configured to transport passengers and cargo in a taxi-like interchangeable manner. On the other hand, when the 3FCAR flies along a route between Tokyo and Okinawa or between Tokyo and the Ogasawara Islands and Guam, for example, it would be possible to extend the cruising distance by transmitting photons from the light receiving unit 2 to the light receiving unit 1 above the route and charging and supplying energy to the 3FCAR. FIG. 10 shows an example of a flight from Japan to Guam. FIG. 10 shows an illustration of a concept in which 3.3FCAR flies from Japan to Uruguay near the other side of Japan, for example, over the Pacific and Atlantic Oceans and over the ocean near New York, etc., while receiving energy supply from 1 and 2 of this application and transporting passengers. (Without having to descend to the ground to charge and refuel, the 3FCAR can be charged and refueled at any time in the sky using 1 and 2 and the photon described above, thereby increasing the cruising range of the 3FCAR)<0045>• In the configuration shown in FIG. 6 (a), an ad balloon 3FORM-AD-BALLOON or 3FORM-AD-BALLOON is placed in the air using 3FORM. In the configuration shown in FIG. 6 (a), a device (3FORM-ACTING) that performs shows, performances, competitions (e.g., races, racing competitions, survival games by robot-type 3FORM), and missions by using 3FORM-BALLOON and formation mechanism of 3FORM, or a human-type human with limbs and torso by formation mechanism, can be used. A configuration that can be a humanoid robot 3FORM-HUMANOID by formation 3FORM to use a humanoid robot with limbs and torso for a show, some labor, watch over work, transportation work, entertainment, or robot competition is disclosed. <0046>—The 3form-humanoid is a flying machine, and may consist of a rather huge humanoid robot, a human, animal (tiger, rabbit, zodiac animals, lion, dog, cat, etc.), plant, imaginary creature (dragon, etc.), doll or papier-mâché in the shape of a character, etc. The object may consist of a doll or a papier-mâché object in the shape of a character. In this case, the use of SSPS and 1 and 2 may also enable constant missions in the air without the need for recharging and energy replenishment on the ground. <0047> Compared to microwaves, photons in the ultraviolet to X-rays range have a higher energy per photon (which can be absorbed and attenuated by reactions with atmospheric molecules, chemical reactions, etc.), and their shorter wavelengths allow the size of the receiver 2 to be reduced. (For photons in the microwave region, the receiver 2 is an antenna/rectenna, whereas for photons with wavelengths shorter than UV, a photocell or a reactor that chemically converts water or other substances into hydrogen or other fuel substances can be used.)<0048> <High-altitude receiver 2 for receiving photons that decay in the atmosphere> Since this application uses photons that decay, it is necessary to install receiver 2 in a section of the atmosphere that is rarefied at a high altitude from the ground. <0049> <Generation and use of photons that do not penetrate the atmosphere> Photons in the UV-C region (photons absorbed in the atmosphere by causing chemical reactions of oxygen and ozone) are shown above as an example. Atmospheric absorption is high for UV light in the wavelength range of 1 nm to 280 nm. (Absorption is especially large from 1 nm to 200 nm.) In a system using photons from 1 nm to 280 nm, light does not penetrate to the ground, and safety on the ground may be maintained. In addition to ultraviolet light, photons in the infrared region from 1 to 10 micrometers in wavelength and laser light using these photons may also be considered as photons that do not penetrate the atmosphere or are blocked by atmospheric windows. Non-patent document 3 describes millimeter waves in the patent document 1. Millimeter waves can also be absorbed in the atmosphere. In this application, photons on the shorter wavelength side than ultraviolet light, which is absorbed by molecules in the atmosphere, and photons on the longer wavelength side than infrared light, millimeter waves, and other photons may be used. In the actual demonstration, it is necessary to select the wavelength of the photons. This application discloses a system of photons that are absorbed by the atmosphere (e.g., oxygen and ozone), but the wavelength of the photons is not limited. <0050> <Means of transporting energy obtained by aircraft 3 including light receiving unit 2 in the air to the ground> Patent document 1 discloses transporting the energy of SSPS from space to the ground using a system consisting of radio waves or lasers (photon only system). Non-patent document 4 discloses the use of a laser with a wavelength of around 1070 nm (near infrared) to transmit energy to the ground. <0051> In this application, as shown in FIG. 1, we have considered having the aircraft 3 including the light-receiving part 2 be equipped with a cable 12 to the ground (for example, the cable 12 connecting the aerial structure 2 and the ground in the previous application and the cable 12 of the orbital elevator section connecting the space structure 1 and the aerial structure 2 to the ground are cited and referenced) and wireless power transmission means 3WEP. However, considering the fact that radio waves tend to diffuse in wireless transmission and that it is unclear whether a lightweight, low-resistance transmission line can be obtained to the stratosphere with cables, a method of delivering electric energy by converting it into chemical energy and fuel is disclosed in FIG. 2. FIGS. 3, 4, and 5 are also disclosed as systems that use fuel. Other forms and illustrations are disclosed in the drawings of this application. <0052> Patent document 2 discloses descriptions of non-rocket launch methods such as orbital elevators, orbital ring systems, orbital rings, and mass drivers. In the field of space development, including the construction of SSPS, low-cost launch methods (including rocket and non-rocket methods) are highly desirable. <0053>• For example, in FIG. 1A and FIG. 1 of Patent Document 2, the cable 12 that serves as the orbital elevator section may be an orbital ring, and the annular structure is held at an altitude in air or space by centrifugal force generated by a large rotating and moving annular structure (1 or 2), and the cable is suspended from the annular structure in the form of a cable that is balanced and held in mid-air. The cable is held in the air or space by the centrifugal force generated by the ring structure (1) and (2), etc., and the weight of the cable is balanced and held in the air. The orbital ring and orbital elevator enable the construction of the SSPS and the energy obtained from the SSPS to transport construction materials between space and ground, as well as to transport power and fuel using the aforementioned structures, wires, and cables. The system does not have such a large-scale ring structure and does not have a large force to fish the 12 cables except for the buoyancy of the aircraft 3 and other aeronautical means, and high-altitude balloons, etc. may be used, or hot air balloons heated by the energy derived from SSPS, and the gas to fill said balloons for levitation and flotation is The gas used to fill the balloon for levitation/flotation can be hydrogen gas, helium, methane, or any other gas capable of levitating in the air, and the system can be buoyant only. The present application is an idea to deliver energy from SSPS to the ground using an aircraft3, which may be a compact and small-scale balloon compared to the so-called orbital ring and orbital elevator of Patent Document 2, for example. <Prior art document> <Patent document> <0054> <Patent document 1>2004-266929<Patent document 2>2023-001372<Patent document 3>2022-058853<Patent document 4>2022-105726 No.22-105726<Non-patent document> <0055> Study of Space Solar Power System (SSPS) [JAXA, viewed Jan. 6, 2023, Internet, https:/www.kenkai.jaxa.jp/research/ssps/ssps-ssps.html] <Non-Patent Document 2> The Atmospheric Window [National Oceanic and Atmospheric Administration NOAA, viewed Jan. 8, 2023, https://www.noaa.gov/jetstream/satellites/absorb]. <Non-Patent Document 3> Window on the Atmosphere [Japan Meteorological Satellite Center, JMA, viewed Jan. 8, 2023, Internet, https://www.data.jma.go.jp/mscweb/en/prod/band_window.html]<Non-Patent Document 4> Laser wireless energy transmission technology Research on laser wireless energy transmission technology [JAXA, viewed Jan. 21, 2023, Internet, https:/www.kenkai.jaxa.jp/research/ssps/ssps-lssps.html]<Outline of Invention> <Problems to be solved> <0056> Next, the problems and solutions in this application are described. The following is a description of the issues and solutions in this application. <1> In the method of transmission in the form of radio waves, such as laser light or microwaves, which can penetrate the atmospheric window toward the ground due to the misorientation of the light emitting part 1 and transmitting part 1, photons or wireless transmission and power transmission energy is transmitted to the ground. Even if the transmission power can be reduced in that form, there is a possibility of harm to people living on the ground, and a method was needed to eliminate people's fears that photons in the form of radio waves or lasers would penetrate the atmosphere and reach the ground. <0057>• It was necessary to devise a system for wireless power transmission by SSPS while ensuring the safety of people on the ground by limiting the photons transmitted by the transmitter unit 1 to those with wavelengths that are easily absorbed by the earth's atmosphere. <0058>• In this application, by using photons that are not transmitted to the ground due to absorption in the atmosphere, etc., we propose a configuration in which energy can reach the upper troposphere, stratosphere and other airborne areas, but not the ground. <0059>• In particular, as an example, as photons that are not transmitted by the atmospheric window, we propose using photon wavelengths that are absorbed by the oxygen, ozone, etc. in the atmosphere through chemical reactions, etc., and whose transmittance to the atmosphere is close to zero. <0060> <Second Problem> When transmitting energy from an aircraft to a ground-based rectenna by microwave diffusion, it is assumed that the energy is diffused and cannot be transmitted efficiently. For example, if radio waves are used in the section from 3WEP in FIGS. 1 to 2LAND, 2TAG, and 2WEP on the ground, the radio waves reach the above-mentioned section while diffusing. The high energy density of the radio waves may cause uneasiness among residents on the ground. <0062>—Therefore, the applicant considered that the problem is to devise a system to transport energy between the aircraft 3 in the air and the ground part 4 without limiting to electromagnetic methods such as wireless power transmission or power transmission by wires and cables. (The applicant considered three methods of energy transmission: wired, wireless, and fuel transport.)<0063>—As a result, a system using the fuel described in FIGS. 2 to 4 is disclosed. <0063> <0063> As a result, a system using the fuels described in FIGS. 2 through 4 is disclosed. When operating SSPS on the Moon and transmitting energy as fuel, a form of reducing materials (silicon oxide, aluminum oxide, iron oxide, water, etc.) compounded with oxygen out of lunar resources and dropping them to the Earth is also disclosed, as shown in FIG. 4. <0064> <The third issue, the issue in the example> <Hitting the photons of the light emitting part 1 to the light receiving part 2 and positioning>• The light receiving part 2 should be small in size. In the case of a small size, it is necessary to direct and hit the laser beam from 1 to 2 (with high accuracy). <0065> As shown in FIG. 10, this application is designed to attenuate the laser beam due to oxygen, ozone, and atmosphere even if it does not hit the target and misfires when the ultraviolet laser beam is irradiated from multiple 1s (multiple 1s in a constellation of multiple 1SSPS-SATs) to 2s, for example, but the misfires result in energy loss. However, since the laser energy is lost in the event of a misfire, a method to hit the target without misfiring was necessary. <0066>• Noting the use of quasi-zenith orbit, which is also used for QZSS positioning satellites in Document 1, FIG. 5 illustrates the use of multiple light emitters1 (or SSPS-SAT with SSPS equipped with multiple issuers1) that operate and move along the quasi-zenith orbit or are placed in quasi-zenith orbit. FIG. 5: A satellite constellation 1SSPS-SYS-QZSS-SEIZA may be placed in a quasi-zenith orbit or a satellite constellation 1SSPS-SYS-QZSS-SEIZA. <By operating in a quasi-zenith orbit, the 1SSPS-SYS-QZSS-SEIZA always passes over Japan and can constantly irradiate photons by replacing the 2 receivers on the ground and in the air. While configuring the system, positioning signals transmitted from 1SSPS-SYS-QZSS-SEIZA, as in the Global Navigation Satellite System GNSS and the positioning system by QZSS, can be used for positioning by the positioning section 2POSI, which is additionally placed in the light receiving section 2. The positioning system can be configured to enable positioning using the QZSS positioning system by using the positioning unit 2POSI additionally placed in the light receiving unit 2. <0068>• In order to check the position of the light receiving unit 2, the distance relationship between the light receiving unit 2 and 1SSPS-SAT or 1SSPS-SYS-QZSS-SEIZA, and the coordinate information in 3-dimensional space, 2 or 2POSI and 1SSPS-SAT or 1SSPS-SYS-QZSS-SEIZA may be used in combination with 1SSPS-SAT or 1SSPS-SYS-QZSS-SEIZA. SAT or 1SSPS-SYS-QZSS-SEIZA may communicate with 2 or 2POSI and 1SSPS-SAT or 1SSPS-SYS-QZSS-SEIZA by laser or radio wave. SYS-QZSS-SEIZA may be equipped with 2 or 2POSI and 1SSPS-SAT or 1SSPS-QZSS-SEIZA. <0069> To assist in positioning 2 or 2POSI, 2POSI or the aircraft 3 containing it may be equipped with a clock, altimeter, sensors and instruments, such as an atomic clock, and an altimeter. The altimeter may be used to measure the altitude component of the information in the three-dimensional space in which 2 or 2POSI is located, which may be combined with the results of positioning by the global positioning satellite system GNSS or the positioning system by QZSS for positioning and use (use of photons fired from 1 to 2 to hit 2). The above positioning results may be used to irradiate photons from 1 to 2 with 2POSI. <The SSPS can be placed above the sea in Japan, for example, where there are no settlements on the ground at that latitude and longitude. From 4STAT, fuel can be transported or pumped by pipeline to ground users6 or residential areas6. 4STAT can be transported or pumped by pipeline from 4STAT to ground user 6 or habitat 6. <In the case of FIG. 5, there is no transmission loss when connecting the light receiving unit 2 to the power grid by a wire. In addition, there is no need for an aircraft 3 to lift the 12 electric cables. Aircraft 3 does not need to lift the wires. (For example, aircraft 3's ability to levitate can be limited to its own aircraft.)<Aircraft 3 can receive energy from the SSPS and use it to levitate day and night, allowing it to fly through the troposphere and stratosphere. In this case, if the aircraft 3 retains the power to hold the wires and float, buoyancy, and maintain altitude through flight, and if the aircraft 3 can hold the cables 12, which can be up to 20 km in length, for example, a fuel-mediated process such as 3FUEL may not be necessary. The electrical wiring components such as wires and electrodes (or motors and coils if a propeller is required) of the aircraft 3 used in this application should be lightweight. <0073>• Also, in the case of FIG. 5, it is possible to respond to demand that does not want to place user sections 6 and 4, which are also living quarters, directly under or near the light-receiving section 2. <0074>• Even in that case, the configuration of FIG. 5 (a) in the present application can separate the SSPS light emitting section 1—light receiving section 2 and the light receiving section 2—ground level section 4 by sandwiching the energy conversion process to fuel and chemicals, which may have the advantage of relieving the people in residential area 4. This may have the benefit of reassuring the people in residence 4. <0075>—However, conversion losses (losses in the conversion from optical and electrical energy to chemical energy) occur when photon and electrical energy in the SSPS light emitting section 1—light receiving section 2 is converted to chemical energy for use in the light receiving section 2—ground level 4 section. This is called a conversion loss. Therefore, as shown in FIG. 6, if energy can be consumed as electrical energy, thermal energy, etc. in the aircraft 3 section (before being converted to chemical energy) and used for transportation equipment, passenger transportation, robotic work, shows, formation flights, ad balloons, advertisements, and entertainment, the above chemical energy conversion loss can be eliminated. FIG. 6, FIG. 7, FIG. 8, FIG. 9, FIG. 10, and FIG. 12 disclose examples of the use of aircraft 3. <0076> <Case where the power and energy of SSPS is transported to aircraft 3 including 2 and then used for airborne applications instead of ground use>> Aircraft need energy for flight and movement. Fuel-driven jet-engine aircraft3, drones3DRONE, or aircraft formation3FORM have limited flight time due to battery and fuel limitations, and require fueling and recharging steps when operating the aircraft. <0077> Also, solar plane aircraft3 equipped with solar cells and batteries on Earth, which can extend operating hours, have also been limited in their performance due to daytime charge limitations. <0078> Thereupon, a system is disclosed in which the energy obtained from the light-receiving part 2 is not sent to the ground but is used to drive the aircraft 3. FIGS. 6 and 8 show a humanoid doll device or humanoid robot 3form-humanoid, 3form-doll (machine), or a humanoid robot 3form-humanoid, 3form-doll (machine), or a humanoid robot 3form-doll (machine) that is composed of a formation flight group 3form or formation flight of aircraft that can operate under constant electric power supply using aircraft 3. 3FORM-HUMANOID, 3FORM-DOLL (MACHINE) or 3FORM-ACTING, 3ROBOT or 3FORM-AD-BALLOON which are used for advertisement or exhibition. FIG. 9 describes an example of removal processing (which may use a robot arm) and additional manufacturing by 3ROBOT on a work object 4WK. <0079> <In the case where SSPS power is transported to 2 and then used for wireless power transmission>> FIG. 7 shows an example of the use of wireless power transmission. Beacons and tags are known to be used for watching over people, managing goods, or searching for people in distress when climbing a mountain or encountering an avalanche. Watchdog devices for children and dementia patients and wearable devices for watchdog 2TAGs are also known. However, there may be a challenge in how to provide power to the tag to run the tag or to charge the tag. Therefore, FIG. 7 of this application discloses 2TAG and 2TAG-PATCH, which are capable of wireless communication, sensor operation, and beacon operation by supplying power wirelessly from an aircraft3. <0080> <Means for Solving the Problem> <0080> <First Means for Solving the Problem>• The system using light receiving part 2, aircraft 3 and fuel as described in FIG. 2, FIG. 3, FIG. 4, FIG. 5, FIG. 10 and FIG. 11 is disclosed. The system is configured to enable wireless transmission and power transmission using short-wavelength photons absorbed by molecules in the atmosphere, such as UV—C and UV-B to X-rays, between the light emitting unit 1, transmitting unit 1, and the light receiving unit 2, receiving unit 2, and then the light receiving unit 2 is placed in the air at a high altitude and at an altitude where said short-wavelength photons are not easily absorbed. The light-receiving part 2 is attached to a means of transportation 3, transportation equipment 3, or deployment means 3, such as an aircraft 3 or airship 3 placed at an altitude that is difficult to absorb said short-wavelength photons, and the light-receiving part 2 is configured to be able to receive said photons from the light-emitting part 1. The light emitting unit 1 and transmitting unit 1 may use an ultraviolet laser or a synchrotron radiation generator (generated using a particle accelerator and undulator, etc.), and its operating power and energy may be obtained from the power and solar energy generated by solar cells and SSPS solar power generation. In addition, as shown in FIG. 4, when fuel is produced on the Moon and used on the Moon or on the ground while reducing the number of launches to the Moon, a form is disclosed in which materials (silicon oxide, aluminum oxide, iron oxide, water, etc.) compounded with oxygen from lunar resources are reduced using power and solar energy from solar power generation by SSPS and dropped to the Earth. <0086> FIG. 10 illustrates the laser beam line, the focus of the laser energy, and the laser attenuation due to the atmosphere when irradiating the laser to the multiple light emitting sections 1 to 2 of the quasi-zenith orbit group in this application. Also included is an illustration of the 3FCARs and 3 that receive energy replenishment by the SSPS method of transporting energy in this application on the way to remote locations. <0081> As shown in FIG. 2 and FIG. 5, we propose a system that uses fuel instead of electricity or light when transporting energy from the light receiving part 2 in the air to the ground part 4 and the user side 6. Specifically, we envision the use of hydrogen obtained by reducing water, carbon and hydrocarbons obtained by reducing water and carbon dioxide, and metals obtained by reducing metal oxides. After receiving the energy from the SSPS at the light receiving unit 2, an aircraft 3 including the light receiving unit 2 or an aircraft 3FUEL for fuel synthesis that can be connected to the 3 using a connecting wire or connection 3WIR to share/fuse power/energy between the 3 and 3FUEL or to transfer energy from the 3 to the 3FUEL, and then the light receiving unit 2 and Fuel is synthesized from the energy held by the aircraft 3 and 3FUEL and the raw materials of fuel in the reactor or electrolysis unit 3FUEL-GEN, and the fuel is transported and stored in the aircraft 3 and 3FUEL's flow path, pipeline, and tank 3TANK, and then stored in the tank 4FUEL-TANK in the ground section 4.—The fuel is transported to tank 4FUEL-TANK in ground section 4 by connecting TANK and 3TANK using 3VALV/4VALV and connecting pipes, nozzles, etc. In this way, SSPS-derived energy is transported from 1SSPS to ground 4 via light receiving unit 2 and aircraft 3 for storage, and then used at the user side 6, thus delivering energy to the user without using wireless power transmission between ground and air. <0082> <3rd Problem Solving Method> Examples of applications for wireless power transmission are shown in FIGS. 6 to 9, etc. In FIG. 6, an aircraft 3 is used to deliver energy to the user at all times. In FIG. 6, a humanoid doll device or humanoid robot 3FORM-HUMANOID, 3FORM-DOLL (MACHINE), or a humanoid robot 3FORM-HUMANOID, 3FORM-DOLL (MACHINE), or a robot 3FORM-DOLL (MACHINE), which is composed of a formation flight group 3FORM or formation flight of aircraft 3 that can operate under constant power supply by using aircraft 3, or a robot 3FORM-ACTING that moves with them, and also 3FORM-AD-BALLOON that uses them for advertisement or exhibition. <0083> FIGS. 8 (a) and 8 (b) are examples of a humanoid doll device or humanoid robot 3 FORM-HUMANOID composed of a formation flight group 3 FORM and aircraft group 3 FORM or formation flight of aircraft 3. Aircraft 3 with a robot arm attached, in which the upper body 3FORM-HUMANOID-UPPER and lower body 3FORM-HUMANOID-LOWER of the humanoid robot fly in formation The illustration shows a humanoid robot 3FORM-HUMANOID painting with a robot arm equipped with an additive manufacturing nozzle 3A1-AM for painting while flying in formation (firing paint bullets from the paint nozzle).) illustration is described. FIG. 8 (b) illustrates the 3FORM-HUMANOID, consisting of the upper and lower body, performing the action of spraying the hand-held paint device to the right side. *There may be a competition/exhibition/show configuration in which paint bullets are sprayed as shown in FIG. 8 in a robot competition. In FIG. 8, a humanoid robot is disclosed as an example after considering the robot arm to be able to perform the same tasks as a human, such as painting. However, this application is not limited to humanoid robots, but can also emulate real animals and plants, such as dogs, cats, birds, fish, whales, trees, flowers and plants, or fictional creatures and characters, such as dragons. The 3FORM may also be used as a stage set-up to reproduce or express a scene in a play or other performance. It may be used for advertisements, dynamic objects, billboards, displays, and ad balloons placed in the air. For example, each of the 3 aircraft equipped with a light emitting device 31 may be used to perform a formation flight 3FORM to create patterns in the sky (such as the display of spheres and pictograms by light emitting drones in the night sky at the Tokyo 2020 Olympic Games). FIG. 8 may use manned or unmanned aircraft 3. <0084> FIG. 9 describes an aircraft 3 with a robotic arm that has or is equipped with an additive manufacturing device or a removal processing device. FIG. 9 includes a description of the cutting of a branch by the removal processing device of 3, for example, when pruning a tree branch. <0087>• In addition, when an aircraft 3 is equipped with a balloon section for levitation/floating, the use of rare gases such as helium may result in resource constraints. Therefore, the system using SSPS disclosed in FIG. 11 of this application may use the energy received by 3 through 2 from SSPS to heat the hot air balloons and use the hot air balloons to float the aircraft 3. (The propulsion system 3TH (which operates using SSPS) may generate the force to levitate, move, fly, and propel against gravity, and may be used to levitate, float, propel, fly, and move the aircraft 3.) <0085> FIG. 7 discloses the tag 2TAG and 2TAG-PATCH, which are capable of wireless communication, sensor operation and beacon operation by supplying power from the aircraft 3 by wireless power transmission. <Effects of the Invention <0088> <0088>—While making the light-receiving and receiving parts 2 and 2 compact, the photons of the light-emitting and transmitting parts 1 and 1 are photons of wavelengths that easily attenuate in the atmosphere, making it difficult for them to reach the ground and protecting the safety of people and objects on the ground.

(The energy transport from the light-receiving part 2 to the ground is a system that uses chemical energy and fuel to eliminate concerns about the weight of electric wires, the large area of the receiving part on the user side for wireless transmission, and the transmission of radio waves, thereby overcoming the challenges of wireless transmission and power transmission using electric wires and cables. This system may be able to overcome the problems of wireless power transmission and power transmission by wires and cables, and deliver the energy produced by SSPS to the user. (FIG. 1, FIG. 2, FIG. 5, FIG. 10, FIG. 11, etc.)

Aircraft 3 and formation flight 3FORM and aircraft group 3FORM equipped with light receiving unit 2 may be able to operate with energy supply from SSPS, reducing steps for refueling and charging on the ground and extending operating time. And 3 could be used for transportation, watch and patrol, work, entertainment, etc. (FIG. 6, FIG. 7, FIG. 8, FIG. 9, FIG. 10, FIG. 11, FIG. 12, etc.)—Powering and recharging the 2TAG tag by aircraft 3 could be used to drive, search, sense, and communicate with 2TAG. 2TAG that may be able to communicate with 3 could be reagent bins, cargo holds, containers, trays, and merchandise shelves with weight measurement capabilities, as well as automobiles, aircraft 2TAG may be used for the management of vehicles, aircraft, transportation equipment, keys, ID cards, objects, and living organisms. <Brief Description of the Drawings> <0089> <FIG. 1> FIG. 1 is an illustration of the method of energy transportation from outer space to the earth describing the configuration of the present application including the light emitting part 1, transmitting part 1 and light receiving part 2, receiving part 2, and the aircraft 3, ground part 4, user 6, clouds and tropospheric and stratospheric regions (Example 1)<FIG. 2 is an illustration of transporting energy from the light-receiving and receiving sections 2 and aircraft 3 to the energy demand area on the earth. (Example 1)<FIG. 3> FIG. 3 is an illustration of launching the raw materials of fuel to the SSPS by means of launching means, producing fuel with the electricity obtained by the SSPS, and dropping said fuel to the ground for use. (Example 2)<FIG. 4> FIG. 4 illustrates a system in which lunar resources and lunar metal oxides are reduced by the power or energy of the SSPS near the Moon to obtain 5M metal and 5MC reduced material, and said 5M metal and 5MC are transported to the ground. (Example 3)<FIG. 5> The upper part of FIG. 5 shows a constellation of SSPS satellites and spacecraft (1SSPS-SAT) deployed in a quasi-zenith orbit (QZO) (1SSPS-SYS-QZSS The figure illustrates the energy transport to the ground from the SSPS satellite and spacecraft (1SSPS-SYS-QZSS-SEIZA). (Example 4)<FIG. 6> The upper part of FIG. 6 is an illustration of a humanoid puppet device or humanoid robot composed of a formation flight group 3FORM or formation flight of aircraft that can be powered and operated (constantly) by using aircraft 3. Illustration of a cab or cargo transport application. (Example 5)<FIG. 7> Illustration of a case in which power and energy are delivered to a tag 2TAG by wireless power transmission from an aircraft 3 or an unmanned 3DRONE to manage the tag and the object attached to the tag. (Example 6)<FIG. 8> An illustration of a robot/exhibit that imitates a living creature formed by 3FORM. (Example 7)<FIG. 9>

An illustration of an unmanned flying robot 3 equipped with a robot arm and tools (e.g., a saw). (Example 8)<FIG. 10> An illustration of a laser beam line, laser energy focus, and laser energy scattering after passing through the focus when irradiating a laser from a plurality of light emitters 1 to light receivers 2 in a quasi-zenith orbit group in this application. (Illustration of the claim in this application that it is difficult for the energy to reach human houses on the ground during laser irradiation)<FIG. 11> Illustration of the system of aircraft 3 that can output the energy obtained from light receiving unit 2 as electric power, light, fuel, chemicals, and various other energy to the outside world. (<FIG. 11> Illustration of an aircraft 3 equipped with a hot air balloon 3HAB and a propulsion system 3TH, which can be operated by the energy of the battery, fuel or SSPS of the aircraft 3.)

<FIG. 12> Illustration of a water supply system 3 and a method of using water, in which water obtained by collecting rainfall/rainwater/snowfall or water supplied from 4H2O on the ground is fed into 3, which may be equipped with a light receiving unit 2, and delivered to places where water is in demand, places where fire should be extinguished, etc. (Example 9)<Form for carrying out the invention> <0090> FIGS. 1 to 7 show examples. (Example of configuration). <Example 1> <0091>SSPS-derived energy transport system using short wavelengths> FIGS. 1, 2, and 5 show Examples 1 and 4 of the invention. It is recommended to be able to temporarily turn off the laser when a communication satellite, its constellation, a constellation of satellites, or a spacecraft (e.g., a constellation of communication satellites, etc.) reaches the laser beam line. It is preferable to be able to turn on/off microwaves as well as lasers. As shown in the illustration of the L-SSPS pilot laser, beacon laser, and main laser beam in Non-Patent Document 4, it is also possible to exchange photons, lasers, and radio waves for guiding and communication between the light emitter 1 and receiver 2. For example, communication by communication laser for guiding to control the orientation of the light emitting part 1 to the light receiving part 2 may be possible between 1 and 2. <0092> <System for transporting SSPS-derived energy by fuel from light receiving unit 2 to ground level 4><System using water and hydrogen> <0092> FIG. 11 illustrates the internal elements of light receiving unit 2 and aircraft 3. In the system of light receiving unit 2, receiving unit 2 and fuel synthesizing aircraft 3FUEL described in FIG. 2, water is delivered from the ground to light receiving unit 2 (reactor 2REA) and 3 (reactor 3REA) including 2 by aircraft, water is electrolyzed and decomposed by 3 and 3FUEL receiving power and energy from light receiving units 2 and 2 to generate hydrogen and oxygen. The hydrogen may be stored in a tank in the aircraft, transported to the ground, and stored in a tank 4 on the ground for use. When used, the hydrogen may be transported to drive a hydrogen engine, drive a fuel cell, run a hydrogen-utilizing thermal power generation system, or transmit the hydrogen to an electric power system. <<In the system of light receiving unit 2 and fuel synthesizable aircraft 3FUEL described in FIG. 2, a metal oxide may be used in addition to water, for example, iron oxide may be used. The iron oxide may be delivered from the ground to the receiver 2 by the aircraft, and the iron oxide may be reduced by the 3FUEL receiving power and energy from the receiver 2 or 2.

<0093> <System using iron and water, system using metal and water>> The system of the receiver 2 and the fuel synthesizable aircraft 3FUEL described in FIG. 2 may use two oxidized substances. For example, water and iron oxide may be delivered from the ground to the photosensor 2 at the aircraft 3FUEL to perform hydrogen iron making (hydrogen reduced iron making) in the system of photosensor 2, aircraft 3 that can be connected to photosensor 2 and 2, and aircraft 3FUEL. In the system of light receiving unit 2 and aircraft 3 or aircraft 3FUEL in the air, the energy of photons from light emitting unit 1 may be used as energy for water reduction to produce hydrogen, and then the hydrogen may be used to reduce iron oxide to produce iron. In the system where hydrogen and iron are produced by 3, iron oxide and iron are not as large in volume as hydrogen, and there is no need for hydrogen cylinders, etc. to be pressurized and loaded with gaseous hydrogen when loading 3. Iron oxide and iron have the advantage that they can be handled at ambient pressure without the need for pressurization like hydrogen cylinders when transported by 3, for example. For hydrogen steelmaking, hydrogen is produced from water, iron oxide is reduced with hydrogen, iron is obtained, and returned to water, and a certain amount of water is maintained at 2, 3, or 3 FUEL. On the ground, iron can also be used to generate electricity and heat from chemical energy, as in iron-air batteries and iron powder in pocket furnaces that oxidize iron. The advantages of the abundance of water, hydrogen, and iron resources are also significant. (In addition to the reduction of iron, zinc, metallic lithium, metallic sodium, metallic magnesium, metallic calcium, aluminum, etc. can also be used to reduce metal oxides.)<0094> <Systems using hydrogen, water, carbon dioxide, and hydrocarbons>>Carbon dioxide and carbon sources may be fed into a water and hydrogen system to reduce carbon dioxide and produce a hydrocarbon-based synthetic fuel. Carbon-based materials may be produced from carbon dioxide. The carbon dioxide stored on the ground may be transported by a 3FUEL or other means to the system of Receiver 2 and Aircraft 3, where it is reduced and separated into carbon dioxide and oxygen using energy that may be derived from SSPS, thereby reducing the amount of carbon dioxide on earth. Carbon dioxide can also be recovered from the atmosphere by separating carbon dioxide from the air in a 2,3 or 3FUEL system and separating the carbon and carbon content from the carbon dioxide. For separation, known methods such as absorption of carbon dioxide by monoethanolamine, membrane separation of gases, or separation by cooling the atmosphere may be used. <Separation of Atmospheric Components from the Air>• Energy from SSPS may be used in systems 2 and 3 or 3FUEL to drive equipment (e.g., pumps, machines, and reactors for air component separation) at all times to recover carbon dioxide and other substances from the air, and the same energy, which may be derived from SSPS, may be used to recover helium, neon, and other gases.

Similarly, energy that may be derived from SSPS may be used to separate and recover rare gases such as helium and neon, oxygen, nitrogen, argon, and other components of the atmosphere. The separated and recovered noble gases may be loaded into the 3GAB. For separation, gases may be compressed by a compressor, liquefied, and separated (deep cold separation). The components of the atmosphere may be separated from the air using known methods such as membrane separation of the gas or cooling the atmosphere and diverting it. <0095> For example, ammonia NH3 may be produced for gas applications, chemical applications, and fertilizer applications where 3 is floated using 3FUEL, which transports nitrogen from the air and 1, 2, and 3 of this application, and water and hydrogen. <0095>3 may be a gas balloon system. In FIG. 11, 1HNU may be photoelectrically converted by 2PCE at 2 to obtain electric power to drive the propulsion system 3TH, or 1HNU received from 1 may be absorbed by a photon absorber at 2 to heat the photon absorber to heat the propellant that drives the 3TH, which in turn heats and injects the propellant to drive the 3TH. The 3TH including the photon absorber 2 and the transport device 3 may be configured to float, levitate, or propel by the energy obtained from 2. <0096> <Floating and propulsion of 3>3 may be propelled by rockets, propellant jets, photons or charged particles, such as the aircraft 3 disclosed in Patent Document 2, Patent Document 3 and Patent Document 4, which is propelled by the recoil of photons fired and reflected from rockets, jets, ion propulsion devices and photon sails, for example. Aircraft 3 can be used. The 3 of the present application may be positioned or suspended in the air by the recoil of the aforementioned photons or charged particles that are shot or reflected toward the ground. A rocket or propellant jet or photon or charged particle may be used to generate thrust in the direction opposite to that of gravity. (The aircraft 3 that is supplied with energy by the SSPS of the present application may use the propulsion system 3TH to hover, fly, or fly in the air (similar to the case where a balloon provides buoyancy, so that the drone 3 that is constantly charged by the SSPS can generate thrust with the propulsion system 3TH to balance its gravity and dead weight in the sky and continue hovering). The aircraft 3, which is supplied with energy by the SSPS of this application, may hover, fly, move, control its attitude, and perform aircraft movement by the propulsion system 3TH. <0097> The FSM, pilot laser beam and its receiver, main laser beam and beacon laser beam described in the L-SSPS schematic diagram in Non-Patent Document 4 may be used in the system of this application. When performing the configuration of non-patent document 4 in the present application, for example, a pilot laser beam light emitting unit 2POSI-PL is provided in a light receiving unit 2 (or 2POSI unit) provided in an aircraft 3 such as FIG. 1 and FIG. 2 of the present application, and a pilot laser beam light emitting unit 2POSI-PL is provided from said light emitting unit 2POSI-PL to the space side, and a pilot laser beam light emitting unit 1 on the SSPS side to the space side. A pilot laser beam may be emitted from the pilot laser beam emitting section 1 on the SSPS side to the pilot laser receiving section 1POSI-PL of the light emitting section 1 on the SSPS side. The laser emitting part 1 may fire the main laser and the pilot laser to the light receiving part 2 or 2POSI of the aircraft 3. The main laser and beacon laser of the laser emitter 1 may be controlled to emit photons from 1 to 2 and hit 2. <0098><Positioning and Communications>> FIG. 5 shows an example of energy transport in quasi-zenith orbit and from geostationary orbit and the Moon. When configuring the system in the quasi-zenith orbit shown in the upper part of FIG. 5, the SSPS can combine the functions of known satellites such as positioning satellites, communication satellites, and ground observation satellites. The SSPS may be used for positioning of photon irradiation from the light emitting part 1 to the light receiving part 2 and for ensuring the accuracy of the launch of the photon between 2 and

The communication between 2 and 1 may include positioning information and launch instructions for launching said photons from 1 to 2 to hit the target. 3, 2 and 1 may be connected to the Internet/communication network from another system, e.g., satellite 1 LINK located in space, or via communication devices with the terminal/computer of ground station 4 or user station 6, or through 4 or 3. (The position of 2 may be located by 1SSPS-SYS-QZSS-SEIZA.) <0108> The 2POSI of the receiver 2 and the 1SSPS-SYS-QZSS-SEIZA, which is also a positioning device QZSS, may be used to determine the location of each 1 and 2POSI of the receiver 2 and 2POSI. The 2POSI of the light receiving part 2 and the 1 may perform wireless and laser communications, and may transmit and receive position information and other necessary data between the 2 and the 1. (Sharing of position and time information and operation information of satellites passing between 1 and 2, if any, and on/off control of laser direction and firing)<0099> <Posture direction control, photon irradiation control>• 1 may be able to control the direction and on/off control of photon irradiation of 1 to 2. 1 may send, emit and transmit photons from 1 in the direction of firing. 1 may be equipped with means to change the direction of 1's emission of photons (1's attitude control and direction control device, 1's deflector), 1 may be equipped with means to suppress or control shaking (e.g., 1 on a stabilizer, gimbal, or head), and said control may be performed from 1, 1SSPS, 1CON, or an external network or the Internet. • 1 may be able to turn on/off the light emission of 1. For example, 1 may check the operation status, operation schedule, orbital information, date and time of other satellites and spacecraft via the external Internet from 1CON, 1LINK, etc., and control to turn off the photon irradiation if a spacecraft or other object comes in the line of fire when irradiating photons from 1 to 2. For example, 1 turns on and off the laser by controlling 1CON. <0100><Supplemental: Laser irradiation of debris> The configuration of this application (laser irradiation from 1 to 2) may be used to change the orbit of space debris 1DBL. For example, when placing 1 in a certain orbit and irradiating the laser toward 2 in the stratosphere/air, as in FIG. 10 for the 1DBL, if the spacecraft is in the line of fire from 1 to 2, the laser is turned off, and if space debris is passing through, it is left on so that the debris is exposed to the laser (and if possible, heats the debris to be heated or to change the orbit of the debris). The light emitting part 1 of this application may be used to irradiate the debris with the laser. <Example 2<0101> <Energy transport system for SSPS by fuel transport> FIG. 3 shows an example of launching fuel material into space, producing fuel with 1, and transporting it to the ground. <FIG. 4 shows an example in which metal oxides and oxides on the lunar surface are reduced to metallic silicon, metallic aluminum iron, etc. 5M (or reduced powdered metallic fuel) at 1, or their related compounds 5MC The figure illustrates the case where metal oxides and oxides on the lunar surface are reduced to metal silicon, metal aluminum iron, etc. 5M (or reduced powdered metal fuel) or their related compounds 5MC and transported to the surface. (If the aforementioned oxides, such as water, as well as the aforementioned metal oxides, are present on the lunar surface, the oxides, such as water, may be reduced to produce and use hydrogen or other reduced substances as fuel.) Although the example in FIG. 4 has the disadvantage of consuming lunar metals and terrestrial oxygen because the metallic elements are removed from the Moon and compounded with terrestrial oxygen, it can deliver power from space solar power generation to the ground while developing the Moon, and may be useful for using SSPS energy on the ground in the early stages of lunar development. (In addition, the oxygen 5O2 produced by oxide reduction on the Moon may be used on the Moon or at space bases or bases, or 5O2 may be fed to the Earth and used as oxygen 402 on the ground).

<0103> As a variant of FIG. 4, silicon oxide is reduced to obtain a reduced substance 5MC or silicon compound 5MC, and the silicon compound 5MC is transferred between regions on the Moon (e.g., from 1FUEL-GEN-1CHEM1 to chemical plants in other regions on the Moon through pipeline 5PIP). The silicon compound 5MC may be transported from 1FUEL-GEN 1CHEM1 to 1CHEM2 or 1CHEM3 near the drop means 9 via pipeline 5PIP.

(The metallic silicon and crude silicon may be produced by known methods using carbon and metallic magnesium. Metallic magnesium may also be produced from magnesium-containing raw materials obtained on the moon and SSPS electricity). Bases 1CHEM1 and 1CHEM3 may be connected by pipeline 5PIP of silane (gas), silicon tetrachloride, or trichlorosilane (raw material and liquid for crystalline silicon), which is a fluid silicon compound 5MC. A pump or similar device can be used to send the 5MC fluid under pressure through the 5PIP. <0104> For example, after the 5MC is transported as fluid 5MC in the pipeline 5PIP, it may be converted to metallic silicon 5M in the conversion sections 1CHEM1, 1CHEM2, and 1CHEM3 by chemical reaction. For example, it may be transported as 5MC of fluid from 5PIP to 1CHEM3 and converted to silicon metal from 1CHEM3 to 5TANKM in the launch/drop unit 9 or on the ground. (Also, if it is acceptable to transport 5MC instead of 5M to the ground, for example, 5TANKM may be equipped with 5MC instead of 5M such as metallic silicon.)<Example 4> <0105> The upper part of FIG. 5 illustrates energy transport to the ground from a system (1SSPS-SYS-QZSS-SEIZA) deployed in quasi-zenith orbit and forming a constellation of SSPS satellites. The lower part of FIG. 5 shows the SSPS satellite constellation 1SSPS-SYS-ORBIT formed in space orbit, or the geostationary orbit constellation 1SSPS-SYS-ORBIT formed in space orbit, or the geostationary orbit constellation 1SSPS-SYS-ORBIT formed in geostationary orbit. GEOS, or the constellation 1SSPS-SYS-MOON or the group 1SSPS-SYS-MOON in lunar or near lunar orbit, and the illustration of energy transport to the ground from the SSPS 1LINK may be used when sending (exchanging) lasers for energy and power, lasers for signals, etc. from 1 connected to SSPS to 2 in the air. 1LINK may relay radio waves as well as lasers (in consideration of the case of relaying radio signals). <0106> 1LINK may include relay means for relaying photons such as lasers. For example, it may include a mirror device 1MRR that changes the projection line and trajectory of laser beams by reflecting light, and an optical component part 1OPT (or optical system 1OPT) such as a lens. It can also be a relay satellite 1LINK, in which 1LINK is equipped with a light-receiving part 2, a light-emitting part 1, and means to operate them. The 1LINK or 1OPT may be a 1LINK or 1OPT that corrects the laser flux that reaches the 1LINK or 1OPT (spread (blurred) by passing over the distance between 1 and 1LINK) with the optical system 1OTP (lens, etc.), converges the flux at the 1OPT, and/or directs the flux to the 1LINK, 2, etc. at the 1MRR. It may be reflected and delivered to the next relay satellite 1LINK or to the receiver 2 in the air. * 1MRR is not limited to use at 1LINK. For example, 1MRR may be a means of delivering sunlight to the sunlight-gathering portion of the SSPS solar cell or sunlight-gathering portion of the SSPS, or it may be a mirror device 1MRR that reflects sunlight to said sunlight-gathering portion, which may be a large-area mirror device. <0107> FIG. 5 shows a diagram of laser irradiation from multiple 1SSPS-SATs on a quasi-zenith orbit to a receiver 2. FIG. 5 is one of the illustrations of the concept, and the constellation 1SSPS-SYS-SEIZA in FIG. 5. SEIZA is not limited to the description of a group of spacecrafts orbiting in a quasi-zenith orbit as shown in FIG. 5. • Also, as shown in FIG. 10, not only one but several Constellation 1SSPS-SYS-SEIZA may be used to supply and feed SSPS-derived energy to 3 including 2. SSPS-derived energy may be supplied to 2 and 3 from multiple 1 SSPS-SYS-SEIZA constellations in different orbits and emission locations (e.g., LEO constellations and geostationary orbit GEO/QZO constellations, lunar surface, etc.). For example, in FIG. 10, three (or more) SSPS-SYS-SEIZA constellations are used to supply energy to aircraft 3 during long-distance transportation or passenger transport. The concept of energy replenishment to aircraft 3 at intermediate sections (e.g., over the ocean) is described. In an asymmetric figure-8 quasi-zenith orbit, a satellite can stay over Japan for about 7 hours.

FIG. 5, for example, can be configured so that the receiver 2 receives laser beams sequentially from each one of the multiple 1SSPS-SAT satellites approaching over Japan (in the small ring over Japan in the asymmetric figure-8 orbit). The light receiving part 2 may be configured to look up at the light emitting part 1 of the QZO satellites in the small circle on the Japanese side of the asymmetric FIG. 8 of 1SSPS-SYS-QZSS-SEIZA at a quasi-zenith angle, and receive laser beams from the light emitting part 1 to the light receiving part 2 in the form of a line of satellites in the QZO. The configuration of the QZO is also acceptable.

<The QZSS and QZSS positioning system may use the 1SSPS-SYS-QZSS-SEIZA, which is also the QZSS. The QZSS and the QZSS-QZSS-SEIZA may be used to determine the positional relationship between each 1 and 2 POSI of the 2 POSI of the 2 receivers and the 1SSPS-SYS-QZSS-SEIZA, which is also a positioning device QZSS. The 2POSI of light receiving part 2, 1SSPS-SYS-QZSS-SEIZA and 1 may communicate with each other by radio or laser communication, and may transmit and receive the position information of 2 etc.

and 1 etc. and other data necessary for energy transport and transportation of this application by radio or laser communication. The position and time information and the data between 1 and 2 may be transmitted and received by radio and laser communications. The position and time information, as well as the operation information of satellites passing between 1 and 2, if any, may be shared to control, for example, the direction of the laser and the on/off control of the photon emission. Laser communication between light emitter 1 and receiver 2 is possible by controlling the on/off of photon emission. Laser/radio communication may be performed between the light-receiving part 2 and the light-emitting part 1 (and even the relay satellite ILINL). <0109> The present application may provide the light-receiving unit 2 with a positioning means to facilitate laser irradiation and hit by the laser from the light-emitting unit 1, or may use the laser relay means 1LINK to direct the laser from 1 to 2 (said positioning means may be 2POS). (The aforementioned positioning means can be 2POSI and space-side positioning systems such as GNSS, GPS, QZSS, etc., or 1SSPS-SYS-QZSS-SEIZA can be equipped with a positioning system such as QZSS, etc.).

Other known means of positioning may be used.)<0110> Not limited to quasi-zenith orbit, a constellation of multiple 1SSPS-SATs orbiting in low earth orbit (LEO), 1SSPS-SYS-ORBIT, can also be used for laser irradiation from 1 to 2 (each 1SSPS-SYS-ORBIT can be used as a 1SSPS-SYS-ORBIT). SATs, as well as communication and positioning between the two light-receiving units) can be performed in the same way as in the case of 1SSPS-SYS-QZSS-SEIZA.)<Example 5> <0111> FIGS. 6 and 10 illustrate cab, cargo, and passenger transportation by aircraft 3FORM, formation flight group 3FORM, or aircraft 3 or flying car 3FCAR, which can be powered and operated (at all times) using aircraft 3. The 3 FORM can be connected to a communication terminal 4CON on the ground, a communication terminal 3CON in the air, or a user terminal 6CON, and can be connected to the Internet using a communication network with the communication part of the aforementioned terminal or 3. For example, in FIG. 6, a user portable terminal 6 may be provided. The user of the user portable terminal 6 may remotely control the humanoid 3FORM, the airplane 3FCAR, or the 3ROBOT (forestry machine, forestry machine, or 3ROBOT which may be a tree pruning machine) shown in FIG. 9 from a remote point from 3 via a communication channel such as the Internet. <Example 6> <0112> When a person or object to be watched over by a beacon or a wearable device 2TAG, wireless terminal 2TAG or electronic tag 2TAG with an active wireless communication unit, it was necessary to mount batteries or replace batteries. Therefore, in (a) of FIG. 7 of this application, wireless energy is irradiated to the 2TAG by the 3DRONE and wireless transmission while the 2TAG is searched by the 3DRONE and 3, the 2TAG is charged, beacon operation and wireless communication operation are performed, and the attached object 6OBJECT (6OBJECT—The 3DRONE is used as a scanner 6TAG-SCANNER of the tag, and the transport device 3 searches for the 2TAG, and when the 3 approaches the 2TAG, the 2TAG is wirelessly powered and wireless communication and beacon operation are performed to identify the tag.

When the 3-TAG approaches the 2-TAG, the 2-TAG is wirelessly charged to perform wireless communication and beacon operation to identify the tag. The charging energy can be SSPS-derived energy using 1, 2, and 3 of this application. (3 or 3DRONE is a transportation device 3, but also a tag scanner 6TAG-SCANNER. When described so as not to limit the scope of the invention of this application, transportation equipment 3 includes not only aircraft 3, but also vehicles such as cars 3, bicycles 3, etc., self-propelled robots, flying drones 3, etc.). <0113> Also disclosed in FIG. 7 (b) is a configuration in which the aforementioned 2TAG is equipped with a sensor. For example, a 2TAG attached to or equipped with a person includes an acceleration sensor and a load sensor, and wireless transmission is performed by 3, 3DRONE, or scanner 6TAG-SCANNER to supply power to the 2TAG with sensors, and the sensors are operated while the power is being supplied or charged by the power supply to collect acceleration, load and environmental data. FIG. 7 (b) shows an example of a 2TAG equipped with a load sensor as a sensor (2TAG-SENSOR) attached to the bottom of a reagent bottle for a toxic substance whose weight should be controlled (2TAG-SENSOR). When the 2TAG is charged by 3 or 3DRONE wireless transmission, the 2TAG acts as a load sensor/weighing device, the 2TAG acquires the load sensor readings, and the 2TAG transmits the bin load sensor readings to the 6TAG-SCANNER tag scanner. The 2TAG can communicate the measurement values of the bin's load sensor to the 6TAG-SCANNER by means of communication. In addition to the weight of the tagged object, the 2TAG can be used in combination with a load sensor and a tilt sensor/accelerometer to check the tilt (e.g., if a reagent bottle or drum tagged on the ground is lying on its side). For example, when 3DRONE or robot car 4CAR is patrolling in a building where reagents are stored while charging 2TAG with a load sensor installed in reagent bottles or shelves as a tag scanner, the charged 2TAG acts as a sensor and transmits the measured values by the load sensor to 4CAR or 3DRONE as described above. The weight information of tagged reagent bottles and other items in the building may be conveyed to the tag scanner or viewed externally from the tag scanner via the communication network. The tag scanner can be used to manage goods and reagents. <<The wireless tag for insole-type monitoring (or related applications such as attaching or attaching 2TAG to socks, footwear, and footwear) described in JP-A2016-073366 may also use the wireless power transmission method and device configuration shown in (b) of FIG. 7. The configuration of the wireless power transmission method and device in FIG. 7 (b) may also be used. The configuration of the method and apparatus for wireless power transmission in (b) of FIG. 7 may be used for attaching or attaching the 2TAG to insoles, shoes, socks, footwear, underwear, clothing, glasses, HMDs, headgear, helmets, gloves, watches, bangles, rings, jewelry, ornaments, portable terminals, etc. as items to be worn. • For the wireless communicator (1b, 1a) described in No. 2016-073366, a mid-range wireless communicator with wireless communication and positioning functions that can charge said wireless communicator (1b, 1a) by a system of 1, 2 and 3 from the SSPS (without the function of charging by walking).

The system may be configured as follows. The sensor section, wireless communication section and beacon of the 2TAG may be operated by charging the battery by wireless transmission method using 3DRONE or 3DRONE driven by SSPS. When 2TAG is used for a pedestrian insole, as described in JP-A2016-073366, the wireless communicator may measure the weight of the person riding on the insole when standing up, the pressure, load, and weight caused by stepping on the insole by walking, and the motion and acceleration of the toes as the acceleration of the insole. Measurement may be made. Measurement of pressure distribution on the sole during walking and gait analysis may be performed. May measure body weight and observe and measure gait. The 2TAG may be used to collect information that can be used for personal biometric characteristics and health management. The 2TAG may be equipped with GPS, GNSS, QZSS, or other positioning means by receiving signals from satellites or radio stations or by communication, and the 2TAG may be used to measure its position. <0114> 2TAG-SENSOR may be a device that measures and senses position by sensing radio communications and signals from satellites or by satellite positioning devices such as GPS and GNSS. As shown in FIG. 7 of this application, a tag scanner 6TAG-SCANNER (which can be a drone 3 or a user's smartphone 6CON) is used to search for tags, charging and feeding power to the tag 2TAG during the search and storing it in the 2TAG's storage device, and using the power stored by the 2TAG (GPS, GNSS, QZSS or other The 2TAG can then receive signals from radio stations (GPS, GNSS, QZSS, or any other satellite, aircraft, or ground base station), obtain the position and time of the 2TAG, perform positioning by radio stations or satellites, and transmit the positioning results from the 2TAG to the 6TAG-SCANNER, which then transmits the 2TAG's positional information.

<0115> When 1, 2 and 3 of this application are added to the system of 2TAG and 6TAG-SCANNER as shown in FIG. 6 and FIG. 10 above, the energy of SSPS can be used to move around remote areas without refueling or charging on the ground, and 6TAG-SCANNER is also a communication platform in the air that can stay above the ground. If 3 is an unmanned aircraft, it can be used as a patrol device for 2TAGs. <0116>• FIGS. 8 and 6 show a group of aircraft 3 FORM that can fly in formation or cooperate with other aircraft, which can share energy by means of a wireless transmission device 3WEP or other energy sharing means. In FIG. 7, a group of aircraft that can share energy among aircraft can also be used, although in FIG. 7, a single 3FORM is described to watch over the area. For example, a 3FORM equipped with a 2FORM may be placed above the stratosphere, and a 3FORM equipped with a 6TAG-SCANNER, which is also a 3FUEL that can fly in the troposphere or on the ground, may be connected to the 3FORM periodically to share and refuel energy by recharging and refueling. <Example 7> <0117> FIG. 8 shows an illustration of the humanoid robot 3FORM-HUMANOID with robotic arm that can fly in formation and coordinate with an upper body aircraft 3 and a lower body aircraft 3 equipped with tools and various devices, at rest and in operation (during flight and robotic arm operation). The control configuration of the device in FIG. 8 is as shown in FIG. 8. The device shown in FIG. 8 can be manned or unmanned. In the unmanned case, 3CON may be equipped with communication devices with external radio stations or communication networks, and computer-related devices such as computer processing, storage, and input/output devices. The aircraft 3 may be equipped with batteries and fuel. Aircraft 3 may use said batteries or fuel to power a robotic arm or motor/actuator/propulsion system. <Example 8> <0118> FIG. 9 shows an aircraft 3 or a robot arm of an aircraft 3 (3ROBOT) equipped with tools, tools, various devices or additive manufacturing devices 3A1-AM, removal processing devices 3A1-RP to perform additive manufacturing on a work object 4WK The figure illustrates the configuration of performing additive manufacturing on the 4WK-AM and removal processing on the 4WK-RP. FIG. 9 also shows an unmanned aircraft 3 or flying robot 3ROBOT that performs branching to cut and remove tree branches as one of the removal processes by remote control from a base station (3CON, 4CON, 6CON), and is equipped with a robot arm and 3A1-RP that may be a saw, cutting section, or grinding wheel The figure below illustrates the flying robot 3ROBOT. The 3ROBOT is powered and operated by the energy of the SSPS, and can be accessed by the 3ROBOT even when the 4WK is located on the side of an airplane 3 or on a slope, cliff, or other location that is difficult for humans or land-moving machines to work on.

(It can also be accessed by the 3ROBOT, a high altitude work equipment. (It may be used for monitoring and working on steel towers and utility pole wires.)—Although FIG. 4 describes a configuration in which 3ROBOT accesses 4WK, 3FORM, consisting of 3ROBOT with tools attached in FIG. 3, can be driven by SSPS energy to work on 4WK. 3FORM The machine with reduced energy can be replaced with a recharged machine in turn, and work can be performed at all times. <Example 9> <0119> FIG. 12 is disclosed as a reference figure. FIG. 12 illustrates a method of producing hydrogen fuel by injecting water obtained by collecting rainfall/rainwater on the pelagic ocean or water supplied from 4H2O on the ground into a 3FUEL, which may be equipped with a light receiving unit2. (and an illustration of the method of using water by collecting rainfall/rainwater by 3FUEL driven by SSPS and delivering it to people, animals, plants, users6 on the ground, and places where demand exists (places where fire should be extinguished)) <0120> The embodiments of the invention have been described, but they are presented as examples only and are not intended to limit the scope of the invention. It is not intended to limit the scope of the invention. These new embodiments can be implemented in various other forms, and various omissions, substitutions, and changes can be made without departing from the gist of the invention. (*This application is based on a conception. (*This application is based on an idea, which has not been demonstrated at the time of application.)<Industrial applicability> <0121> The system may be used for power transmission and energy transportation from light emitting part 1, which is also a space solar power plant, to airplane 3 or high altitude platform 3 including light receiving part 2, and to the ground. Not limited to space solar power applications, it could be used for transmitting power generated in space or on the moon to the earth's ground, which has an atmosphere. <0122> If airplanes, electric airplanes, and hot air balloons could be powered by SSPS-derived energy, this could eliminate the need for refueling and recharging steps on the ground, increase cruising time, and make long-distance travel possible for aircraft, planes, airships, and passenger aircraft (or facilities such as airborne hotels). <code description> <0123> <Energy transport from SSPS to ground by short wavelength photons> <emission section 1, SSPS section>1: Emission section, transmission section (laser transmitting section, laser firing section, photon emitting section. May also include radio wave transmitting section). 1PP: Power plant, power plant. (In addition to photovoltaic power plants, this may be thermal or chemical energy-utilizing power plants, large-scale batteries, or nuclear power-related power plants.) 1PV: Solar cells (*1PV may be 1PV launched from the ground or 1PV produced from raw materials from resources on the moon or other celestial bodies and manufactured in the vicinity of the site of use using the in-situ vacuum of outer space). 1PCL: A means of energy conversion and solar energy collection unit other than a solar cell). 1LASER-GEN: A device unit that converts sunlight into laser light from the power and energy obtained from 1PV and 1PCL (a means of laser generation such as an ultraviolet laser or synchrotron or other particle accelerator-based synchrotron radiation generator, which can be used to generate light and transmit energy), 1CON: A communication part of 1. 1FUEL-GEN: FUEL-GEN is the part that synthesizes fuel materials using the energy obtained by SSPS. 1SSPS: SSPS, space solar power station.

1SSPS-ETC: 1 1SSPS-SYS: A series of systems and components related to SSPS. 1SSPS-SYS: A series of systems for space solar power plants. (1SSPS-SYS-QZSS: SSPS that is also QZSS (QZSS: Quasi-Geostationary Orbit Satellite System). 1SSPS-SYS-GEOS: Geostationary Orbit (GEO) space solar power system. 1SSPS-SYS-MOON: Space Solar Power System in Geostationary Orbit (GEO).1SSPS-SYS-MOON: SSPS in lunar or near lunar space operating in geostationary orbit (or space solar power system on a moon-like satellite or other planet). 1SSPS-SYS-QZSS-SEIZA: a constellation of satellites in the 1SSPS-SYS satellite constellation. 1SSPS-SYS-QZSS-SEIZA: a constellation of satellites operating in the QZSS.1 1SSPS-SYS-QZSS satellite constellation.)<1 or 1SSPS-SYS may be placed in a QZSS quasi-zenith orbit (such as an asymmetric figure-8 orbit when placed over Japan) and used as shown in FIG. 5. FIG. 5. <Constellation in Low Earth Orbit LEO, etc.> In a Low Earth Orbit (LEO) satellite constellation (such as those provided by SpaceX and OneWeb, for example), the satellites comprising said Low Earth Orbit (LEO) satellite constellation are the SSPS satellites 1SSPS-SAT, The constellation 1SSPS-SYS-SEIZA may be operated by organizing a formation of satellites so that the satellite 1SSPS-SAT is always near 2 as seen from a certain point/receiver 2 on the ground side, and by letting a group of satellites flow into orbit. The configuration of 1SSPS-SYS-SEIZA (1SSPS-SYS-LEO-SEIZA) in LEO is such that SSPS satellites and light emitters can be placed in low earth orbit closer to the ground than in quasi-zenith or geostationary orbit. 1 can be placed on the low orbit side, closer to the ground than in quasi-zenith or geostationary orbit, reducing the length of distance (in space) when launching photons from 1 to 2 to hit the target. The case of a constellation of satellites moving at speed in low or medium orbit can be applied to the SSPS constellation, for example, by organizing a swarm of SSPS satellites (tens to tens of thousands) in low orbit at an altitude of 300 to 500 km or 1100 km, and then launching the SSPS satellites from 1 to 2 at a certain point on the ground side and at the light receiver. The SSPS satellites can be used as a relay satellite (1LINK) or as a SSPS-SYS-SEIZA (1SSPS-SYS-SEIZA) to transmit the energy of the SSPS light emitting part 1 to the light receiving part 2. The 1SSPS-SYS-SEIZA is a SSPS-SYS-SEIZA. 1SSPS-SYS-SEIZA is a solar power generation satellite and an energy transmission satellite, but it can also provide satellite communication network and communication service by satellite constellation, or provide communication service between ground and satellite. (Communication, laser communication, and energy transmission may be performed between SSPS satellites and between the light emitter 1 and receiver 2 of the SSPS.) 1LINK: relay satellite, relay aircraft, or relay means of energy/signal from SSPS to light receiving unit 2. 1LINK may be equipped with mirrors for photon reflection, relay, and transmission, for example, UV reflectors made of aluminum are assumed. 1HNU: photons irradiated, fired, oscillated, or transmitted from 1, emitting unit 1 to light receiving unit 1HNU: A photon or a group of photons arriving from 1 to 2, dropping or passing through the air with lower air density or oxygen/nitrogen density than on the ground, such as in the stratosphere or troposphere (1HNU may be able to turn on/off its generation at 1, so that communication and optical communication by laser may be performed in parts 1 to 2 by turning on/off generation and emission of 1HNU at 1. (The 1HNU-EXT may also be used to generate and fire 1HNUs.) 1HNU-EXT: Photons that do not reach the ground or are attenuated. Photons with characteristics and wavelengths that are absorbed by the atmosphere. LEO: Low Earth Orbit; GEO: Geostationary Orbit; QZO: Quasi-Zenith Orbit; and 1HNU-EXT: Photons with characteristics and wavelengths that are absorbed by the atmosphere. <In this configuration, the laser is attenuated by the atmosphere, and the laser can be emitted from n (or more) 1SSPS-SATs or 1SSPSs per 2 photoreceivers. The use of multiple SSPS-SATs reduces and distributes the output of n 1SSPS-SATs to the 2 receivers from X watts in the case of 1 SSPS-SAT to X/n watts, reducing the energy of the laser fired by each 1SSPS-SAT, reducing the output of energy irradiated to the ground, and protecting the safety of people on the ground. Protect the safety of people on the ground. (The laser energy per SSPS-SAT can be reduced by flying a constellation of multiple SSPS-SATs equipped with the light emitting part 1 instead of the light emitting part 1 of a single SSPS-SAT, and distributing the light emitting part 1 to multiple satellites while irradiating the laser to the light receiving part 2). For example, there is a 1SSPS-SAT-LOWP with an output of X watts, which has a low laser output that can be generated (specifically, a low amount of UV photons), and n of these are placed in quasi-zenith orbit or LEO to form 1SSPS-SYS-SEIZA is formed, and energy is irradiated from n 1SSPS-SAT-LOWPs to the receiver 2, if the lasers of all the units are received at 2 or FCS-2, the point of FCS-2 can receive n×X watts (nX watts) at the FCS-2. On the other hand, at the point outside the focal point FCS-2, the laser energy travels straight along the trajectory FHNU-EXT and is attenuated and diverged by the atmosphere. The output power of the laser photon in the trajectory FHNU-EXT is less than X watts, which is lower than nX watts at the focal point FCS-2. Thus, energy density reduction is possible outside of the focal point FCS-2. (Also, at focal point FCS-2 in the stratosphere and troposphere, photons are not absorbed because the air density is low and there is little atmosphere, oxygen, and ozone, and a photon convergence point can be formed at focal point FCS-2, but at a location with high air density near the ground, focal point FCS (If we set the focus FCS-2 at a location with high air density near the ground and irradiate photons from FCS-1, we expect that they will be attenuated by the atmosphere before arriving at the focus FCS-2)—As a result, there is a factor that the laser will be attenuated by the atmosphere at the ground level outside the focus FCS-2. and the factor that one laser output can be reduced and distributed to the aforementioned 1/n of the constellation's total laser output X. The above two factors are used to try to ensure safety on the ground. (The two elements are used to ensure safety on the ground. (In this application, in addition to attenuation to the atmosphere, the constellation is combined to reduce the laser output toward the ground by dispersing the laser output to 1 each.) When the satellite approaches the receiver 2, the laser emitted from the light-emitting part 1 of the multiple n satellites in close proximity is emitted from the light-emitting part 1 to the receiver 2 and received by the receiver 2, thereby obtaining nY watts of power. Even if some photons are not caught and head toward the ground, their output power is limited to Y watts, which may be useful for reducing the power of photons that head toward the ground due to poor hits and for ensuring safety on the ground. If n satellites equipped with a low-power (X-watt) light emitting unit 2 are prepared, the amount of energy that goes to the ground without hitting 2 may be lower and safer than when aiming at 2 with a single nX-watt high-power laser. In the case of an SSPS satellite or a lunar base equipped with an SSPS, the higher the output power of a single light-emitting part 1 laser (output power of a single laser), the more uneasy people on the ground may feel. Considering the above, the device of this application may be configured to use multiple light emitters and direct the laser beam toward a light receiving part 2 in the sky above. FIG. 10 discloses the trajectory of the laser when fired off from the position of the receiver 2 or when there is no receiver 2. FIG. 10 shows the consideration of making it difficult for the laser energy to reach the ground FCS-2: A point to be aimed at by one light emitter or the focus of a laser photon to be aimed at by multiple light emitters. FCS-2: The point or focus of the laser/photon to be aimed at by the multiple light emitters. FHNU-EXT: The trajectory of a laser beam that deviates from FCS-2 and travels through the stratospheric troposphere toward the ground. Trajectory. <Receiving section 2, airborne section>2: Receiving section, light-receiving section (laser receiver, laser receiving section, which is mounted on means of deployment in the air 3, aircraft 3, airship or platform 3. 2 is configured to receive the laser of 1, taking into account the orientation of the light-receiving surface and other factors. It may include devices to control the attitude or change the orientation of the light-receiving part, and may include gimbals, deflectors, stabilizers, etc.) 2REA: Reactor, chemical reactor, photochemical reactor, thermal reactor, furnace, chemical mechanical device for 2 (a reactor that causes chemical reactions by photons with photon energy that can excite semiconductors with a wide band gap, such as photocatalysts, capable of causing chemical reactions by heat or UV light, etc.) 2WEP: wireless power receiver for 2PV: photoelectric conversion element. 2RANT: part that converts radio waves and electromagnetic waves into electric power (the part of wireless power transmission methods such as electromagnetic induction, magnetic field resonance, electric field coupling, and radio wave reception methods, among others. Including antennas, rectifier circuits, and rectenna) 2LAND: Receiving part located on the ground (mainly the part that receives power from 3WEP)<Aircraft 3, airborne section, FIG. 2 or FIG. 11, etc.>3: Aircraft, etc., airships, etc. (Receiving part 2 can be UV—C and B with less attenuation of UV laser. 3EPF-SYS: Aircraft system/system that receives the SSPS-derived energy of this application at the receiver 3 and uses it as electricity/power or chemical energy/fuel. 3GAB: Gas balloon of 3.

3HAB: Hot air balloon of 3. 3 GHAB: gas hot air balloons and roger balloons of 3. 3TH: propellant and related equipment of 3 (in addition to aircraft propeller motors, motors, actuators, and jet engines, including spacecraft rocket propulsion, electric propulsion, ion propulsion, photon sails, and propulsion by recoil from photon launch and reflection. (May include propellant for propulsion systems.) 3BATT: Batteries of 3 (or batteries or fuel to power 3, 3ETC, 3TH, etc.) 3ETC: Control systems, computer systems, communication systems, power systems, electrical wiring systems, sensors, instruments, positioning devices, 3HAB control devices, hot air balloon heating devices, gas balloon 3GAB control devices, 3CON: control and communication part of 3 (including external devices and communication devices with external 3 and 3FORM); 3SEN: aeronautical instruments, sensors, etc.; 3WEP: means of wireless power transmission to external 3 and 3FORM and to the ground from 3's perspective; 3 WIR: A device or wire, power cable, or optical repeater connecting 3 and 3FUEL, including the receiver 2, or a path for transmitting power or energy. 3WIRI: A wire, cable, or bus such as an electrical wireway, power wireway, signal wireway, or optical fiber.

3REA: A reactor in 3. (3REA is a device that performs chemical reactions. For example, reactions using heat, electricity, and light may be performed. It can be a device that performs chemical reactions using light, electrochemical reactors/electrolysis, or heat. (For example, electrolysis equipment, photocatalytic or light reaction equipment, reactors by heat, ammonia synthesis equipment, equipment for various types of chemistry, kilns for firing materials such as ceramics, cement and lime, reactors and furnaces for steel making. 3RPL: Means of transporting pre- and post-reaction substances (such as fuel) in the reactor 2REA, chemical 3VALV: Fuel outlet/valve to the fuel tank inside the 3FUEL. 3FUEL: An aircraft that uses the power or energy obtained in 2 to produce fuel and/or transport the produced fuel. The fuel can be, for example, hydrogen, metals such as lithium metal, sodium metal, magnesium metal, calcium metal, aluminum metal, silicon metal, iron, zinc, etc., or carbon, hydrocarbon, or organic material. 3FUEL-GEN: The fuel production section of the 3FUEL. For example, a device that electrolyzes water using electricity obtained from SSPS through 1 and 2 to produce hydrogen and oxygen as fuels. Conversely, it can also be a fuel cell or battery that generates electricity using water and oxygen as fuel. * Further expressions that do not limit the scope of the invention are the parts that convert the energy (electrical energy, thermal energy, mechanical energy, and heat engine energy) obtained by 2 and 3 from 1 through 2 by SSPS into chemical energy and fuel, and the chemical energy and fuel into electrical energy and fuel. energy, thermal energy, mechanical energy, and heat-engine energy (reverse conversion). 3TANK: cargo compartment, tank, fuel tank [3FUEL-TANK: fuel tank for 3FUEL (can also be a hydrogen gas fuel tank or a balloon. Oxidized metals may also be reduced and used as fuel. For example, hydrogen, metal lithium, metal sodium, metal magnesium, metal calcium, metal aluminum, metal silicon, iron, zinc, or other metals, carbon, hydrocarbons, or organic materials may be used.] 3LUGG: A cargo space for 3. It may be loaded with batteries or fuel to run 3. It may be loaded with humans to run 3 and maneuvering devices such as 3, 3FORM, etc. It may be loaded with equipment and maneuvering devices to run 3, 3FORM, etc. unmanned. 3LUGG-H2O: A water cargo space, rainwater collection equipment and water may be used in the cargo compartment of the vehicle. * Propulsion system 3TH may use air, atmosphere, gas, or ionized gas taken from outside as propellant.3TH may use air, atmosphere, gas, water, or fluid as propellant, giving the energy of said photons obtained by light receiving unit 2 to said propellant, jet propulsion, rocket propulsion, propulsion by heating jet of propellant, 3TH may use air, water, hydrogen, liquid hydrogen or solid propellant (propulsion by laser ablation). 3TH may use water, air or air as propellant. 3TH may be used for propulsion by heating water/air with a laser (either the laser built into the 3TH or a photon/laser emitted from the light emitter 1 and received by the light receiver 2) and injecting it from the aircraft 3/3TH. Water may be obtained in the form of precipitation, snowfall, hail, rainwater, or atmospheric water vapor that is moved and received by the aircraft 3 as shown in FIG. 12 (FIG. 25 of this application). Water may be obtained from a ground source 4H2O. Water may be used for propellant, hydrogen fuel, and synthesis of hydrogen-containing compounds. SWP-ABS-LINE: The upper altitude at which photons absorbed and attenuated by the atmosphere reach. (TPS-LINE: Troposphere. AIR: Atmosphere. <4: Ground-side energy supply system, ground section; 4VALV: connection/valve that connects to 3VALV; 4FUEL-TANK: fuel tank that stores fuel transported from 3FUEL-TANK via 4VALV and 3VALV; 4FUEL-TANK: fuel tank that stores fuel transported from 3FUEL-TANK via 4VALV and 3VALV; 4FUEL-TANK: fuel tank that stores fuel transported from 3FUEL-TANK via 3VALV. A tank for storing SSPS-derived energy received by the receiver 2 after it is transported to the ground using 3 or other means of transportation. It can be a pipeline. Fuel storage and flow paths, and flow paths to users. <User section>6: User section. A user section that consumes energy by consuming fuel transported and delivered from the 4FUEL-TANK to 6. (or the user section that consumes energy derived from SSPS.)<Other>12: Cables (may include power cables. May be a cable/pathway that directs power in the form of light.) (May include 1 conductor element, 1 WIRE.) 14: Cable foundation, may be connected to 1100. 17: Connection with 3 (may be the connection 17 described in the patent document 2). 1100: Power grid. <FIG. 3, Fuel production of hydrogen and metal by launching> 1VALV: connection for connecting the tank 5TANK, which is loaded with water or hydrogen when hydrogen is made from water by the electricity obtained from 1. 1FUEL-GEN: fuel production and chemical reaction section of 1. 5VALV: connection for 5 tanks. 5 TANK: tanks (tanks loaded with water, hydrogen, oxidized and reduced metals, fuel feedstock and produced fuel).5TANK1: tanks loaded with fuel feedstock (e.g. water, metal oxides, carbon dioxide.) 5TANK2: Tanks connected to 1VALV and producing fuel from SSPS electricity or energy and loading (e.g., hydrogen and oxygen from water, metal oxides from metal and oxygen from metal oxides). Metal and oxygen production from metal oxides. 5TANK3: A tank that is loaded with fuel and dropped from the SSPS to the ground (e.g., hydrogen/hydrogen and oxygen loaded tank, metal/metal and oxygen loaded tank, carbon and hydrocarbon/carbon and hydrocarbon and oxygen loaded tank). 9: A launch vehicle. (9: Means of launch, or means of dropping a launch from the Moon to the Earth, a planet, a satellite, a celestial body, or outer space.

<The configuration shown in FIG. 4 is not a permanent cycle because the process of removing metal elements from the Moon and compounding them with Earth's oxygen destroys the Moon's material balance, but in the short term (in the course of space exploration), the process will not emit CO2 and will not require launching water and oxides on the ground. However, it is disclosed because it is a method that enables the use of space solar power generation near the Moon on Earth (using materials as fuel) without emitting carbon dioxide in the short term (during the course of space development) and without the need to launch water and oxides on the ground, and allows resources on the Moon to be dropped directly onto the ground (while using less materials launched to the Moon). (5O2 below can be used for oxygen for residence, migration, and stay on the Moon and for terraforming. 5 MM: Mines, mining sources, and extraction sources of lunar resources such as metal oxides. The series of means from resources to fuel 5M production, including extraction, sorting, separation, purification, transportation, etc., may be included. 5MOX: Raw materials of fuel (metal oxides such as silicon oxide or aluminum oxide) that can be made into fuel by energy from SSPS, such as metal oxides mined and extracted on the Moon. A material, object, or device that can be procured locally in space (moon, satellite, asteroid belt, small bodies such as meteorites, comets, and other small bodies and celestial bodies floating in space) that can store SSPS energy when described so as not to limit the scope of the invention. 1FUEL-GEN: The fuel production section or chemical reaction section of 1.

5MOX and 1. SSPS power or energy may be used to produce fuel or chemical energy stored substances. 1CHEM: 1 chemical reaction section. 1 chemical plant. 1CHEM1, 1CHEM2, 1CHEM3 (including devices and reaction sections capable of chemical reactions and electrolysis using thermal energy. For example, in addition to the production of 5M, it can be a part where substances are chemically reacted by chemical or thermal energy to make products during the production of earth and stone products such as cement at the lunar base). 5O2: Storage sites, pipelines, etc., for oxygen resulting from the reduction of metal oxides.

5M: A metal produced by 1FUEL-GEN and 1 SSPS power and 5MOX (a metal derived from lunar resources that can be oxidized by oxygen to produce redox energy). 5M can be, for example, powdered metallic silicon, metallic aluminum, or iron powder. 5MC: A substance that can be compounded with lunar resources and oxygen obtained by SSPS (e.g., silane, which is a fluid). (e.g. fluid silane or trichlorosilane. 5MC: a substance that requires more care in handling compared to metallic silicon, but because it is a fluid, it has the potential to be transported by pipeline). 5TANKM: Earth- and ground-bound transport containers loaded with 5M or 5MC. Drop container/fuel drop pod. 402, 602: Oxygen source on the ground or user side. Used to oxidize 5M at user 6. For example, if metal oxides are obtained on the Moon, and oxygen is stored on the Moon among the produced metal and oxygen, and the metal is dropped to the Earth and reacted with oxygen, the amount of oxygen on the Earth will decrease as it compounds with the metal. Therefore, it may be preferable to drop both oxygen and metal synthesized on the Moon to the ground. 6: A user who consumes fuel and oxygen and utilizes energy. <FIG. 5, Examples in SSPS in quasi-zenith orbit, on the Moon, and in geostationary orbit >1SSPS-SAT: Satellite for SSPS containing 1. 1SSPS-SYS: System for SSPS containing 1. (1SSPS-SYS: SSPS system. 1SSPS-SEIZA: 1SSPS group, a constellation of satellites organized and composed of satellites for SSPS including 1SSPS.-QZSS-SEIZA: 1 SSPS constellation in quasi-zenith orbit.-ORBIT: 1 SSPS constellation in orbit.-GEOS: 1 SSPS constellation in geostationary orbit.-MOON: 1SSPS group in orbit near the Moon or on the lunar surface.) 1LINK: A relay satellite that relays between the 1SSPS emitter and receiver. A satellite or device that relays photons attempting to pass between the emitting and receiving sections of 1SSPS. * For example, a satellite equipped with a mirror 1MRR that reflects laser/photons and an attitude control device that changes the direction of said mirror. When sending photons from 1 to 2 by laser from a geostationary orbit or from a distant place such as the moon to the earth, it prevents lack of precision and diffusion of laser light generated from 1. 1OPT may be equipped with an optical component such as a lens to focus the light, and if the laser beam diverges before reaching the relay satellite 1LINK from 1 of 1SSPS, the diverged laser may be optically corrected (or adjusted) to a converged laser again by the lens of the 1OPT of 1LINK, etc. * For example, 1LINK including laser receiver 2 and light emitter 1. The laser light flux/beam diffusion that occurs due to the increase in the distance the laser travels is recovered as laser light energy at the photoelectric converter/receiver 2 of the relay satellite 1LINK to obtain power, and said power is used to again emit photons to the 3 receiver 2 in the air or The light flux that arrives diffused using 2 and 1 of the 1LINK is converted to electric power and reemitted as a non-diffused laser beam. 1MMR: A mirror or reflective device that can reflect photons (e.g., sunlight reflector, concentrator). (e.g., mirrors for reflecting and focusing sunlight, aluminum mirrors for reflecting ultraviolet laser light) It may be mounted on a 1LINK. 1OPT: Optics, optical component, means of correcting light, may be mounted on 1LINK. * For example, if a photon irradiated from 1 spreads (or diffuses and blurs) its light flux/beam as it passes over a long distance, the optical system is used to converge the light flux again. 2: light receiving part. 3: aircraft. 3FUEL: fuel synthesis aircraft/fuel carrying aircraft. 4: ground part. 6: user part. <FIG. 6, Examples of using energy from 2 to 3 to drive 3 or for services by 3. 3FCAR: Airplane, flying car. 3ROBOT: Flying Robot. It may have a robot arm with tools attached and may be in the form of a humanoid robot. 3FCAR and 3FORM robots may be used to perform tasks. For example, forestry work may be performed by a 3 or 3FCAR or 3 FORM robot. 3FCAR or 3 FORM robots may be equipped with devices and means for pruning (devices for cutting branches, attitude control and propulsion devices for changing the attitude and position of the aircraft in relation to the tree and each branch, pruning devices and means) to prune trees in forests. (3) The ROBOT may be equipped with devices and means for pruning (devices for cutting branches, attitude control and propulsion devices for changing the aircraft's attitude and position in relation to the tree and each branch, and pruning devices and means) so that it can prune branches. (3ROBOT may be allowed to perform various tasks in agriculture, forestry, fisheries, etc. that can be performed by the aircraft system of this application.) Aircraft 3 and 3FCAR may be used for object delivery or recovery applications. (e.g., mail, fuel delivery, object delivery, mail order EC, resource recovery, water delivery, fire extinguishing agent delivery/drop) *Aircraft 3 or 3FCAR may be a transportation device, or an aircraft or residential section that also serves as a hotel or residential use (or aircraft type camper 3FCAR, residential type aircraft). <FIG. 7, example of energy from 2 to 3 used for 2TAG> 2: Receiver. 2WEP: Wireless power receiver or communication device about 2. 2RANT: A part that converts radio and electromagnetic waves into electric power. 2WEP: A part that may be included in 2WEP (electromagnetic 2RANT: The part that converts radio waves or electromagnetic waves into electric power, which can be included in 2WEP (electromagnetic). 2TAG: A tag equipped with a receiver2. It is mainly used to watch over objects, packages, children, and the elderly, and is equipped with a part that receives power from 3WEP. It obtains power through wireless power transmission from 3WEP to perform wireless communication, beacon operation, sensing, and positioning. 2TAG: A wireless tag and beacon device that receives power and operates by wireless power transmission. 2TAG may be equipped with computer functions and may have processing, storage, input/output, and communication devices. 2TAG-CAP: The part of 2TAG that stores power from the wireless power supply. 2TAG-SENSOR: A sensor attached to the 2TAG (accelerometer for measuring the acceleration of the 2TAG attached with the 2TAG, load sensor for measuring weight/load, temperature sensor for measuring temperature, altimeter for measuring altitude, magnetometer for measuring magnetism sensor when measuring magnetism, and those dedicated firefighting sensors when detecting smoke or fire. When aircraft 3 approaches close to 2TAG-TAG, wireless power transmission becomes possible, and 2TAG-CAP is charged, the sensors are driven by the charged power. (Positioning and time acquisition of 2TAG may be performed by radio signals from aircraft 3, a positioning system such as MICHIBIKI, or 1SSPS-SYS-QZSS-SEIZA.) 2TAG-IN: Input device for 2TAG. 2TAG-OUT: Output device of 2TAG. For example, when searching for a 2TAG attached to an object, the 2TAG may be equipped with a sound device as 2TAG-OUT, and the 2TAG may play a sound in response to the result of communication by a communication device or a request by a processing unit controlled by a program in a processing unit or memory device. For example, if the 2TAG is charged by the tag scanner, the sound device may sound to notify the tag scanner or the person accompanying the tag scanner of the presence of the tag. 2PATCH: A patch, which may be a paste or medicine. It can be a cloth, bandage, or film that can also be a tag. It can be a patch that can be affixed to clothing, underwear, etc., or a patch that can be sewn on. Patches that can be used as a treatment for dementia, smoking cessation patches, poultice patches or tapes, plasters or bandages for children, or patches that can be affixed to clothing, underwear, or small articles of clothing. Insect repellent patches can be applied to clothing to prevent malaria and other diseases caused by mosquito bites, etc., and have the function of releasing ingredients that insects do not like or that kill insects. 2TAG-PATCH: 2TAG with 2PATCH or 2TAG that can be attached to or detached from 2PATCH. 2TAG, 2PATCH, and 2TAG-PATCH are equipped with a portion or layer that functions as a tag, a patch, or a cloth or film/tape for application. For example, 2TAG has a support 2TAG-SP and an adhesive layer 2TAG-ADH. 2PATCH, for example, can have an adhesive for sticking to an object and a drug-containing adhesive layer (plaster) applied and laminated to a support such as film or tape. (Examples of 2PATCH are rivastigmine tape and poultices in the form of a pap or tape.) 2PATCH can also be an adhesive bandage or plaster. *For example, 2PATCH can be a patch that does not contain a drug or medicine, or it can be a tape, film, or patch containing an adhesive layer 2PATCH-ADH and a support 2PATCH-SP. (In the case of 2TAG-PATCH, a pharmaceutical patch-type tag, there is the advantage that the tag can be checked for application, reapplied, or replaced with a new tag when the drug is applied.) 6OBJECT-TAG-ATTACHED: An object to which 2TAG or 2TAG-PATCH is attached or worn. A person, animal, plant, or object to which a patch is affixed. Object or goods controlled by a tag. * Examples of objects: swords, firearms firearms, and weapons requiring item control; alcohol, pharmaceuticals, medical supplies, and medicines, including deleterious poisons; cargo, luggage, bags, ID cards, keys and keys, car keys, car and transport equipment, buildings and furniture, important documents, antiques, treasures, precious metals, jewelry, ornaments, computers, watches, devices, 6TAG-SCANNER: A part of a tag that wirelessly transmits power to a 2TAG or 2TAG-PATCH or receives a wireless communication signal or beacon from a 2TAG or 2TAG-PATCH and alerts the user to the presence of the tag. 2TAG, 2TAG-PATCH, or receive radio communication signals or beacons emitted by 2TAG, 2TAG-PATCH and notify the user that a tag is present. Tag scanner. 6TAG-SCANNER can be used, for example, in an aircraft equipped with a tag scanner3, 3CON, 3DRONE drone, 4CON ground base station, 6CON, 6user station, 6SMART-PHONE, 6HANDY-TAG-3, 3DRONE: may be a tag scanner, unmanned tag search, wireless power transmission and charging on the ground or in the air at the search location while in flight, and if there is a charged tag in the air during the search A drone or aircraft/transportation equipment/vehicle that may receive a tag beacon, communication, or other response and search for the tag. The 3DRONE may transmit wireless power from the 3WEP to the tag while flying/approaching the tag as it searches for the tag. 6TAG-MONITORING-USE: This section describes the use of the tag for monitoring. FIG. 7 (a). 6OBJECT-TAG-SEN-ATTACHED: An object to which 2 TAGs with sensors or 2 TAG-PATCHs are attached or attached. (Also, a description of the use of the tag as a measurement sensor for the tagged object.) For example, 2TAG and 2TAG-PATCH with sensor are attached to the bottom of a storage bottle of a toxic substance that needs to be monitored in a laboratory, and when the bottle is placed on it, the force (bottle mass m×gravitational acceleration g) of the bottle pushing the bottle weight over the load sensor of the tag is detected as the bottle weight. A system that detects the bottle weight as weight, and manages the reagent as the amount of toxic reagent used in the reagent change in the bottle weight. The power to drive the tag is by wireless power transmission. FIG. 7 (b). <FIG. 8, Example of 3FORM> *FIG. 8 is an example of using the 3FORM configuration for entertainment and work purposes. FIG. 8 (a) and (b) are examples of two planes with robot arms, robot arms, robot legs, human or animal torso, limbs, head, spine, and tail cooperating and flying in formation, and said robot arms are used as 3A1-RP and 3A1-AM in FIG. 9. The robot arm may manipulate, hold, or hold a device, tool, or tool that performs removal processing or additive manufacturing with a robot hand, or it may be equipped with the aforementioned tool or tool, etc. A group of airplanes (3A1, 3A2, 3L1, 3L2 in FIG. 8) may be equipped with robotic hands. FIG. 8 (b) is an example of using an aircraft such as US Patent Publication No. 20140231590 for the show. In FIG. 8, the aircraft may fly in formation like a humanoid robot (an operating puppet device). 3If FORM is in the stratosphere and cannot be propelled by jet engines or propellers, electric propulsion using photons, particles or charged particles such as photon sails and ion propulsion devices, or rocket propulsion devices are necessary. <FIG. 9> FIG. 9 illustrates a robot arm 3A1 attached to 3, which may be charged by photon receiver 2 or driven by fuel produced by 2, to perform removal processing or additive manufacturing, such as 3A1-RP or 3A1-AM, with a robot arm removal processing or 3A1-RP: removal processing device/robot arm; 3A1-AM: additive manufacturing device/robot arm; 4WK: work target, part, product, object; 4WK-AM: additive manufacturing of 4WK, target part of deposition/stacking; 4WK-AM: additive manufacturing of 4WK, target part of deposition/stacking 4WK-AM: 4WK additive manufacturing, film deposition, lamination object, lamination part. 4WK-RP: 4WK cutting, removal, cutting, and polishing object. 4WK-AM: chemical solutions such as pine weevil repellents, paints, seeds, etc. that are added to the workpiece. 4WK-RP: branches to be removed from the workpiece such as branches of trees to be pruned. 4WK-RP is an object to be removed from the work object, such as branches of a tree for pruning. <FCS-2: Focal point at which one or more 1s are to be aimed; FCS-2 may coincide with the point at which light is to be received by the receiver 2. FHNU-EXT: A trajectory that deviates from FCS-2 and attempts to pass through the stratospheric troposphere toward the ground. FHNU-EXT: A trajectory that leaves FCS-2 and attempts to head toward the ground through the stratosphere. * FIG. 10 shows, as an example, an illustration of an aircraft 3 traveling from Japan to Uruguay (the other side of the earth from Japan, half way around the world) without landing on the ground due to the energy received from SSPS emitter 1 using light receiver 2. (In FIG. 10, it is possible to travel from Japan to Uruguay using 3, and 3 may be energized by receiving photons from the light emitter 1 to the receiver 2 over the high seas on the route between Japan and Uruguay, or over the distant ocean in New York.) 1DBL: (without an atmosphere or other object to attenuate the photons) space 1DBL: Space debris that travels around in space (without an atmosphere or other object to attenuate photons). 1DBL: Space debris that travels in space (with no atmosphere or other objects to attenuate the photons). 1DBL can be used as a focal point in space to focus the laser without attenuation. (It is possible to irradiate the laser to 1DBL in FCS-2 which makes multiple 1s.)<FIG. 11, Illustration of Aircraft 3>2: Photodetector. 2POSI: The part of the positioning and locating device to irradiate and hit the photons and laser from 1 to 2. <2PCE: Photoelectric conversion device. 3ETC: Electricity, power, computer, various circuits, and communication parts necessary for the operation of 3. 3WIR: Parts that exchange electric power and photons with the outside. 3REA: Reactor of 3 (It can be a device that operates an electric furnace or electrolysis operation by feeding electric power). 3WIRI: circuitry, wiring. 3BATT: batteries. 3LUGG: cargo bay. 3SEN: sensors. Measuring devices. 3TH: propulsion device, means of propulsion. 3B: balloon, levitation device, means of levitation, levitating device, means of levitation. 3HAB: hot air balloon. 3HAB: hot air balloon. 3HAB's hot air balloon gas may be heated by the energy from the light-receiving part 2. 3GAB: gas balloon. 3WEP: wireless transmission means to the outside. 3CON: communication and control part to the outside. <2REA: A device that causes a reaction to take place by photons. (3RPL: Pipelines, pipes, and tanks for fuel-related materials. 3VALV: Fuel connection valve to the outside. 3REA: Reactor of 3. 3EPF-SYS: Aircraft system that receives the energy derived from the SSPS of this application at the light receiving section 3 and uses it as electricity, power, chemical energy, or fuel. Aircraft system that uses it as electricity/power or chemical energy/fuel. * FIG. 11 illustrates an aircraft 3 that may have a form of aircraft with a propulsion system, motor, actuator, propeller, fixed wing, rotary wing, hot air balloon 3HAB and gas balloon 3GAB driven by SSPS. * The SSPS-derived energy can be delivered to aircraft 3 including 2 day and night, and the energy may be transferred from 3 including 2 to other aircraft 3 or 3FUEL or 3FORM, or shared with them. <Reference Figure, FIG. 12>3LUGG-H2O: A cargo compartment for water. It can catch rainfall and collect it for use as water. (Consideration of environmental impact.) 3H2O-LINE 3H2O-LINE: Pipelines, tanks, and channels for water. 3H2O-VALV: Valves and nozzles for taking water outside. 4H2O: Ground water supply (main assumed water supply sources: including rivers, dams, and reservoirs). 6LIFE: Watering and water supply required Organisms (delivering water to people, plants, animals, creatures, deserts, etc.) 6: User part. People's homes, factories, towns, etc. that need water. 6FIRE: Fire source. (Fire is extinguished by water injection) *FIG. 12 discloses that water is supplied from outside of 3 to inside of 3 and from inside of 3 to the consumer through the valve mentioned above, considering the possibility that 3 can operate as an aircraft with constant water supply due to energy from SSPS. The 3 may be an emergency water supply equipment 3/transportation equipment 3 for water supply. The aircraft 3/transportation equipment 3 may obtain said water from rainwater or ground water resources 4H2O. Said water may be used as propellant to be sprayed from the propulsion system 3TH of the transport machinery 3 (aircraft 3, deployment means 3, cage section 15 of orbital elevator, space fountain, hauler, aerial structure 2, launching device, launch vehicle, vehicle 3 launched from the ground into space, etc.). The water may undergo heating, chemical reaction, filtration, sterilization, and other processes using the energy obtained from the light-receiving unit 2, and may be used for propellant injection propulsion operation, fuel generation, cooling of airframe equipment and light-receiving unit 2, generation of drinking water, etc. (4H2O includes water tanks, ponds, rivers, etc.) Rainwater, in particular, does not contain salt that needs to be separated by membrane separation, etc. like seawater (as water that has already been separated from salt in the natural cycle) and falls on the ground and at sea, and rainwater/snow that is not salt water falls from rain clouds above the sea to the sea surface. The SSPS is a water supply system. Therefore, this application discloses that rainwater/rainfall/snowfall over the sky, which may be over distant oceans, is obtained by aircraft 3 equipped with 2 with a longer operating time due to the energy of SSPS, stored in 3, and supplied to the demand area 6. * FIG. 12 shows a configuration of 3 and water flow path 3H2O-LINE equipped with a filtration membrane/filtration tank, means of sterilization by ozone or chemicals, and means of removing harmful substances, which may be used as a water purifier/water purification unit and used as a water supply plane 3. * FIG. 12 relates to the use of a 3FUEL that collects rainwater and a 3FUEL equipped with water. As a method to collect rainfall and snowfall to obtain water, and to decompose the water with SSPS energy to obtain hydrogen, for example, an aircraft 3 and 3FUEL with 3LUGG to collect rainfall and rainfall from clouds and rainfall from clouds are illustrated on the lower right side of FIG. 11. <0124><O2, O, Oxygen Atoms> The use of terrestrial atmosphere, oxygen and oxygen atoms is disclosed in the sub-concept of the claims of this application. For example, the use of photons attenuated by oxygen and ozone in the atmosphere is disclosed, as well as the synthesis of fuel with oxygen atoms removed by reducing lunar oxides in a system using oxygen as an oxidant, the production of hydrogen and oxygen in the airborne receiver 2 and aircraft 3FUEL, and the use of said fuel and said oxygen atoms in the user 6. <0125> <Method of transporting energy from outer space to the earth> The upper concepts of the claims of this application do not have to be limited to the use of space solar power. For example, a power plant using elementary particles or nuclear energy (radioisotope, fission, fusion, antimatter/annihilation, or other power plant using elementary particles or nuclei) could be provided on the Moon, and the power from said power plant 1 PP could be sent to light emitter 1, energy from light emitter 1 to light receiver 2 in the form of photons, and from light receiver 2 to operate aircraft 3, (2) The power can also be used to synthesize fuel by oxidizing and reducing substances on the ground. (A relay satellite such as 1LINK may be used to send the photons from 1 to 2.) <0126> <Space Nuclear Power, Space Physical Battery Power, and Space Power Plant> Where sunlight is not available, power from nuclear power plants or physical batteries using elementary particles or nuclear power can be transmitted to the ground using 1, 2, or 3 of this application. The raw materials for nuclear fuel such as uranium before enrichment (mixture of uranium 235 and uranium 238) can be launched on the ground, enriched to obtain nuclear fuel (uranium 235) at a lunar base or other location, used for nuclear power generation at a lunar nuclear power plant, and the power generated by the aforementioned power generation can be delivered to the ground via 1 through 2. Waste management is required after power generation.

<0127> As for the tag for watching over the elderly, refer to and cite the contents of paragraph 0127 of Patent Application No. 2023-007722<Problem> We would like to provide a wearable tag or beacon for watching over the elderly or for finding them when they are missing. As for the aforementioned tag 2TAG, it was unclear whether the elderly person would necessarily wear a shoe/insoles, belt, or wearable device with a built-in watch-type tag, depending on his/her preference, difference in condition, and interest. We thought it would be a good idea to have a tag that can be worn by relatives watching over the elderly as part of the medication administration process. <Means of Solution> A wireless tag is attached to the medicine, charged by wireless power supply and operated by a beacon, etc., to search for the tag and the elderly person to whom the tag is attached. The tag and the elderly person to whom the tag is attached are searched for. Tag power supply and beacon radio wave detection may be performed by a drone during the search. We also propose a configuration in which the tag is powered by a spacecraft such as an SSPS, and information useful for time information, positioning, and tag processing control is transmitted between the satellite and the tag, as well as beacon detection. <The most important feature of the tag 2TAG and tag scanner is that it is a patch-type wireless tag that combines a patch for medication for dementia patients and a wireless tag, so that the tag 2TAG can be attached and maintained attached to patients with dementia. 2TAG patrols and searches for tags. It may be charged by wireless transmission means of aircraft 3 and operate beacon and wireless communication. <This application includes an idea for a passive RFID tag that stores power by wireless power supply and generates a wireless signal (beacon signal) from the stored power to search for said wireless IC tag and the object to which said tag is attached. According to the known technology, a 10-meter class power supply technology (spatial transmission type wireless power transmission system) using the 2.4 GHz band, which can supply power up to 10 meters away, has been proposed. The 10-meter class power transmission technology is mounted on a drone and a paste medicine equipped with UHF tag functionality to make a patch type wireless tag 2TAG, and after the 2TAG is powered by the wireless power transmission system, the power obtained by the power supply is used to generate a beacon signal for the 2TAG to search for objects or persons whose location is unknown. The power supply is then used to generate beacon signals for the 2 TAGS, which are used to search for objects or persons whose location is unknown. Example 1: For example, an elderly person (or a person who wants to watch over or search for a child, etc.) who has wandered into the mountains can, in advance, apply an adhesive or patch containing or equipped with the 2TAG to a location on the person's back where the patch 1P is difficult to peel off, so that a drone equipped with the 10m-class power transmission technology can be flown around the mountain in the event of distress. If a drone equipped with said 10-meter power feed technology is flown around a mountain and the 2TAG is within the power feed range of the wireless power feed, the 2TAG can operate a communication device or beacon (or a signal transmitter or communication device that contains information useful for searching for objects) by supplying power, and said drone or said 2TAG can receive signals sent by said 2TAG's communication device to activate said 2TAG's communication device. The intent is to detect the presence of said 2TAG by receiving the signal and to assist in said search. (or wirelessly detect said 2TAG and use it to detect, search, watch over, guard and control the object THG to which said 2TAG is supposed to be affixed, during distribution or transportation.) Aircraft such as drones or spacecraft such as satellites can be used as power supply and reading devices (tag scanners) to search for the 2TAGs. Also, automobiles, electrically power assisted bicycles, and other transportation equipment that have a power source and travel through the city can be equipped with the aforementioned tag scanner. For example, a drone 3DRONE can be used as a tag scanner. (The drone tag scanner is just an example; existing RFID tag handheld scanners and handheld tag scanners can also be used to search for tags.) In the case of an elderly person, for example, we expect that it would be difficult to remove the medicine from his/her back, but this is just an example. For example, in the case of a child, there is a risk that a person who wishes to kidnap or otherwise harm the child may transmit a radio wave to a location where the 2TAG is likely to be located to power the 2TAG, charge it, activate it, and use it to find the child by operating a beacon, etc. To prevent this, the 2TAG can communicate when power is supplied to prevent the child from being found by a person who is qualified to power said 2TAG The 2TAG can be activated by a beacon, etc., depending on the conditions under which the 2TAG is operated and the environment in which the 2TAG is placed. Specifically, the 2TAG may be equipped with authentication methods. For example, authentication means using passwords or PINs, setting of locking means by buttons or inputs on the tag side, means to control on/off and access to beacon functions, etc., and one-time password authentication means provided in the tag 1. <Actual tag 1> For example, the use of a tag 2TAG for 2PATCH paste for the elderly, which is a 2TAG with a password printed on it, with the aforementioned printed password PWD recorded and stored in the control unit or IC of the 2TAG, as an encryption key for encrypted communication based on that password, Only the tag scanner with the PWD entered and stored may communicate with the 2TAG, beacon the 2TAG, or feed power to the 2TAG. 2TAG may be overlaid on the aforementioned paste 2PATCH. The 2TAG may be equipped with a means of affixing, fixing, or gluing, or a means of attachment and removal such as a hook and loop fastener between the 2TAG and the 2PATCH. <The 2TAG may also be a medical device used for watching over the patient, for example, a wristwatch-type device to measure the heart rate. <From the perspective of a device worn on the human body, 2TAG can be a wearable such as insoles, shoes, eyeglasses, contact lenses, contact lens-type output devices, vision-corrective devices or equipment, hearing aids, earphones/headphones, and wireless earphones. They may also be applied to the skin, as in the case of decorative stickers (bindis) in India. 2TAG can also be used for decorative stickers, patches, and patches on clothing. For example, wireless earphones are small and can be easily lost, but having a part of the tag acting as the tag 1 of the present application or attaching it to the tag 1 may help in locating said wireless earphones lost in the street or in a house. If the person looking for the 2TAG contained in the lost object uses sight or hearing, the 2TAG may be equipped with a wireless beacon or a sounding, emitting, or vibrating beacon, as is known. <Patch for the 2TAG> The patch 2PATCH can be a drug such as rivastigmine, rivastigmine tape, etc. For example, it can be a medication that widens bronchial tubes, widens blood vessels in the heart, or aids in smoking cessation. As an example, it can be a smoking cessation drug 1P or nicotine patch 1P containing nicotine for smoking cessation. The patch 1P may be a transdermal formulation (patch 1P). The patch 1P may be a pharmaceutical product such as a poultice 1P or analgesic anti-inflammatory drug 1P. The patch 1P may be an application cloth, adhesive plaster 1P, bandage 1P, eye patch, etc. 1P. Drug Administration Applications: 2PATCH may contain drugs. 2PATCH may be applied to equipment that handles drugs. Use for medicines and objects requiring management: The method of searching, managing, and guarding lost items using a beacon, etc. as claimed by 2TAG may be used for medicines requiring prescription for medical use, or for containers of poisonous substances locked and controlled in laboratories at universities and other institutions. <This application includes devices for locating items and persons. For example, this application includes a method of transmitting information and signals wirelessly from a satellite or constellation of satellites deployed in space to the aforementioned tags on the ground, as well as wireless power supply (power transmission system in space solar power generation). In addition to satellites, airborne aircraft can also be used. <Background to the use of the patch> From the example of a close relative, the inventor recognized that elderly people do not always wear wearable items such as shoes or bracelets, and that the degree of concentration on what the elderly person wears may vary depending on the progression of symptoms and other factors. The elderly person could not manage his/her clothing, and even if the guardian prepared clothing, wristwatches, or footwear with tags for watching over the elderly person or for distress measures, the elderly person himself/herself could not, would not, or could not maintain wearing such items. <Based on the above, we have focused on the Rivastimin patch for patch medication as an item that we observed the old people wearing all the time in their daily lives, and we propose the patch-type wireless 2TAG. <Application of patch, patch, or tape to other than skin> Although the patch is applied to the skin of the person to whom it is administered, there is a possibility that it may come off the skin. (For example, the patch may come off due to perspiration in the summer.) The application may be applied to the skin of an elderly person, to the fabric of underwear, or to underwear or innerwear (which is closer to the skin and difficult to take off outdoors). The patch may be attached with tape or a hook and loop fastener between the underwear and the patch/tag. <If the patch is attached to the back, it may be difficult for an elderly person to reach up to remove the patch, and it may be difficult for the patch to be removed. <The main problem to be solved is to provide a tag that can be worn to watch over the elderly or to find them when they are missing. <The problem to be solved is that even if a device is prepared as a wearable device, each elderly person has his/her own individuality and it is not always clear whether he/she will wear a certain item such as footwear or a wristwatch. The goal was to find items that would continue to be worn, and to devise RFID tag functions, tag driving methods, and search methods that would be appropriate for those items. The challenge may have been to devise a tag method that allows relatives watching over the elderly to wear the tag as part of their medication. The tag was not necessarily a wearable device with a built-in shoe, belt, or watch-type tag, depending on the preference, condition, or interest of the elderly person. <The detection range of the tag scanner with the UHF method (e.g., 900 MHZ band affixed tag) was about 2 to 5 meters. It is desirable to have a wide detection range when an elderly person is in distress in the city or in the mountains, and the configuration of the power supply system and power storage (capacitor type, primary battery type, or secondary battery type) should be considered and disclosed so that the range can be longer than 5 meters, for example. The challenge was to provide RFID tag functionality from a distance (the drive configuration could include passive, semi-active, and active types), and to enable the tag scanner to transmit tag presence and identification information to the tag scanner using electric power. <When a person with a TAG is in distress, the searcher may search with a handheld tag scanner or with an unmanned or drone-based tag scanner. The searcher may search with a handheld tag scanner or with an unmanned or drone-type tag scanner. For example, to search for a person in distress in the mountains, multiple UAVs are released into the mountains where the person is thought to be in distress, and the UAVs transmit power wirelessly to the search location and radiate energy wirelessly so that the 2TAG is charged. The unmanned vehicle can be positioned by GPS or other signals and automatically operated while it searches for the 2TAG. If radio transmission power and antenna sensitivity permit, satellites, satellite constellations, spacecraft, and space structures may be used to search for 2TAGs instead of drones and aircraft. For example, cabs, motorcycles, delivery vehicles, or public vehicles (postal vehicles, police vehicles, fire/medical vehicles, and street sweepers) could be equipped with tag scanners in advance to check for wandering 2TAG wearers in the streets. 2TAG may be attached to the keys of buildings and equipment vehicles, and the aforementioned tag scanner may be used to search for 2TAG to manage the keys and search for keys. <In case a tag scanner is mounted on a portable terminal> A tag scanner may be mounted on a portable terminal such as a smart phone. The smartphone may be equipped with a tag scanner or be retrofitted with a tag scanner to search for a 2TAG attached to a person or an important item. <Means to solve the problem> The most important feature of the 2TAG and the tag scanner 6TAG-SCANNER is that it is a patch-type wireless tag that combines a patch for medication for dementia patients and a wireless tag, so that the tag can be attached and maintained attached to and attached to the medication for dementia patients. The tag can be driven after it has been applied. Furthermore, the conditions under which the tag is driven after being affixed are also disclosed. <Effect of the Invention> The tag2TAG and tag scanner of the present invention has the advantage of being a patch-type wireless tag that combines a patch and a wireless tag for administering medication to dementia patients, and of being able to apply and maintain the state of application of the tag to the dementia patient. <FIG. 7 illustrates the concept of the invention. The main part of the invention is to incorporate the procedure of attaching and managing the attachment of the wireless tag 2TAG into the therapeutic procedure of administering the medication to the elderly dementia patient by the elderly patient's relatives, nurses and caregivers, so that the two procedures can be performed in a single procedure. The 2-TAG search is performed by sending a beacon signal to the tag scanner over a distance that exceeds the range of the wireless power supply, and by using a wireless power supply from an aircraft such as a drone or satellite or spacecraft to store power in the 2-TAG and release it as a beacon signal power. The method is to search for the 2 TAGS that are expected to be attached to the old man. The details of the basic computer, electronic components and elements, communications, power supply, drone, aircraft, spacecraft, time synchronization technology, and positioning technology can be explained from known methods and previously published patent documents. For example, in FIGS. 7 and 2TAG, wireless LAN (IEEE 802.11 series), tethering or wireless PAN (IEEE 802.15 series), and wireless power supply are used, but these technologies are obvious from the publicly known literature, so the explanation is omitted.

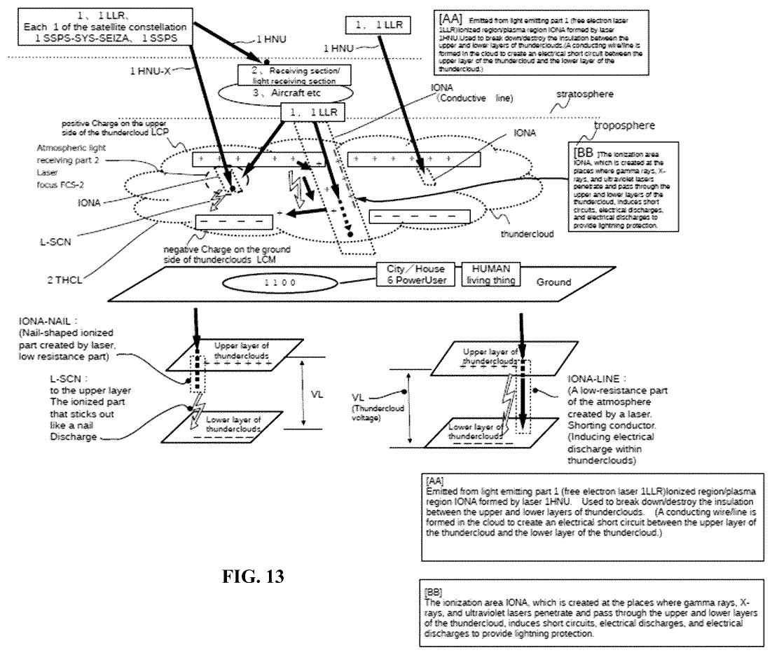

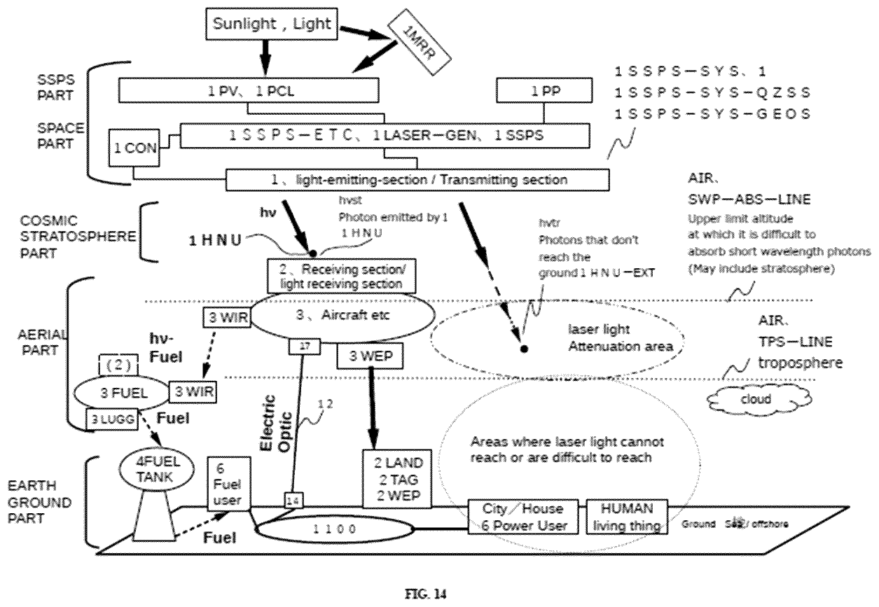

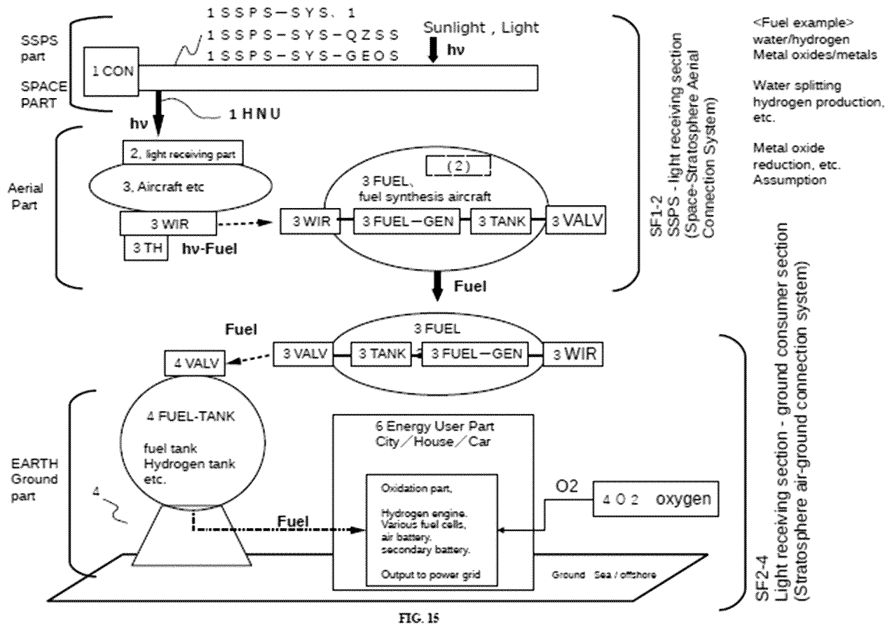

As an example of the use of said energy transport method disclosed in paragraph number, a lightning protection method using said method of transporting energy from light emitting part 1 to light receiving part 2 using a laser is disclosed. (The lightning protection method of this application is an idea.)<0001> This application is cited with reference to the earlier applications of this application, JP-Application No. 2022-123161, JP-Application No. 2022-086263 and JP-Application No. 2023-007722. This application includes ideas for lightning protection against lightning strikes caused by thunderclouds. <Background Technology> <0002> Lightning strikes affect and sometimes damage power equipment, power grids, and information and communication equipment. Therefore, measures have been taken to equip buildings with lightning rods to prevent lightning strikes. According to Patent Literature 1 and 2, a method is devised to intentionally change the direction of lightning charge flow and lightning strike by using conductive wires (Patent Literature 1, FIG. 1) or areas plasmaized by laser (Patent Literature 1, FIG. 2), which are insulated between the thundercloud and the ground and serve as capacitors, to lower resistance or short-circuit the area. This method intentionally changes the direction in which the lightning charge flows and the direction in which the lightning strikes. In Patent Document 2, it is disclosed that free electron laser or synchrotron radiation produced by a particle accelerator and undulator is ionizing radiation (Patent Document 2, FIG. 1), and a lightning protection method by laser is still being researched and developed. According to the previous patent application No. 2023-007722, a configuration for irradiating ultraviolet rays, X-rays, and gamma ray photons from outer space to the air containing oxygen molecules, ozone, and oxygen atoms, or nitrogen molecules, nitrogen atoms, and other molecular atoms in the atmosphere, which may include clouds, rain clouds, and thunderclouds, is disclosed. The configuration of irradiating X-rays and gamma ray photons as well as ultraviolet rays to the air containing oxygen molecules, ozone, oxygen atoms, nitrogen molecules, nitrogen atoms, and other molecular atoms in the atmosphere is disclosed. <Prior Art Document> <0003> <Patent Document 1> Patent Publication No. 03-222295<Patent Document 2> Patent Publication No. 05-180954<Outline of the Invention><0004> (1) When using conductive wires from the ground In the case of short-circuiting the above, the wire should be lightweight (to reduce the weight of lifting and suspending). (2) When a laser is fired from the ground into the sky during rainfall, snow, raindrops, and hail from thunderclouds may blow toward the ground and scatter the laser if hail is present in the laser beam line. When inventors were devising a method of transporting SSPS energy from space, they were considering a configuration in which ultraviolet and X-rays are received by a receiver 2 in the air from a light emitter 1 on the space side. In this application, photons and lasers of ionizing radiation such as X-rays are irradiated from the upper layer of thunderclouds (space side, stratosphere side) to the lower layer of thunderclouds (ground side) from multiple light emitting units 1 on the 1SSPS or 1SSPS satellite constellation in space, not on the ground. to promote short-circuiting of the capacitor section consisting of the charged layers of the upper and lower layers of the thundercloud (the capacitor section consisting of the LCP and LCM regions in FIG. 13). The ionization region with conductivity that becomes a breakthrough (IONA-NAIL in FIG. 13, the nail-shaped part, or the ionized, plasmaized, and low-resistance part of the atmosphere by the laser focus FCS-2) that weakens the insulation of the capacitors in the thunder cloud that store positive and negative charges of the thunder cloud. The ionized area is a conductive ionized area that is ionized, plasmaized, or low-resistive area of the atmosphere due to the laser focus FCS-2). In this application, we consider that laser irradiation from ground waves to thunderclouds may be scattered by hail, etc., and examine a method of lightning protection by X-rays and other lasers from space to thunderclouds in the air. This application discloses a lightning protection method with the intention of facilitating the short-circuiting of electric charges inside the thundercloud. As shown in FIG. 13, (considering that the laser may not work well in the troposphere due to rain, hail, snow, and other objects that interfere with the laser's straight path and reflect diffusely, and that the laser may affect aircraft and other objects in the sky when it is fired from the ground to the sky), the method is not affected by rain and other weather conditions in the troposphere and does not affect people, houses, and objects in the troposphere. In order not to affect human houses and objects below, photons absorbed by the atmosphere, oxygen nitrogen, and atomic molecules may be irradiated from outer space or the stratosphere to thunderclouds in the troposphere toward the thunderclouds to promote a short circuit within the thunderclouds or between the lower layers of thunderclouds and the ground. Charge may be induced to flow more easily in the upper layer of the thundercloud and the part of the sky above the thundercloud. Photons: preferably ionizing, output-controlled X-rays and gamma rays. (Broadly, ultraviolet rays such as UV-B and UV-C. (In addition, it is possible to use lasers or radio waves that are absorbed by the atmosphere, such as some infrared rays, if they induce ionization, low-resistance of a part of the thundercloud, or breakdown of insulation.)< (1) Lightning protection by a conductor: The conductor element 1 described in FIG. 1 of JP-Application 2022-123161 may be used to cross the thundercloud or to help discharge and short-circuit inside the thundercloud. Also, the cable section 12, which may have conductivity of the track elevator section 10 described in JP-A2022-086263, may be arranged to cross the thundercloud vertically and vertically. <0006>< (2) Lightning protection by ionization> A light emitting part 1 (synchrotron radiation generator, free electron laser) placed in space or in the air (e.g. a group of satellites or an aircraft or airborne platform) is used to irradiate and emit (ultraviolet or) X-rays or gamma rays to the light receiving part 2THCL which is a thunder cloud/rain cloud in the air. Said laser may have a laser trajectory that crosses, passes through, or penetrates the thundercloud 2THCL from the space side to the ground side. The ionizing radiation laser such as X-rays and gamma rays ionizes oxygen molecules/ozone/oxygen atoms or nitrogen molecules/nitrogen atoms and other atmospheric molecular atoms in the path of said laser, forming ionized, highly conductive and plasmaized regions of the thunder cloud. The intention is to short-circuit or reduce the insulation between the positively charged region/layer and the negatively charged region/layer to neutralize the charge, short-circuit, and control lightning or lightning strike. In addition to short-circuiting positive and negative charges inside the thundercloud, the aforementioned laser may also be used to induce, discharge, or release the charge of the thundercloud to a layer or portion of the thundercloud other than the thundercloud. For example, the laser may pass through the stratosphere, mesosphere, thermosphere, or ionosphere above the thundercloud, creating ionized or low-resistance portions in those portions, allowing the charge of the thundercloud to flow or escape in said portions. The laser may be irradiated to form low-resistance portions so that electricity can flow upward from thunderclouds such as sprites. In the case of photons with shorter wavelengths than UV-B, the aforementioned laser is expected to be absorbed and attenuated by the atmosphere due to photo-reactions, chemical reactions, and ionization of atomic molecules, making it difficult for the photons to reach the ground. <0007> According to this method, the laser is not scattered by rain and hail in the troposphere and can form an ionized and low-resistance conductive path IONA from space to the thundercloud, which can break down the insulation of the thundercloud, discharge electricity, and attempt lightning protection. Compared to the case where a laser emitting 4LASER is placed on the ground and irradiated in the air, it is possible to attempt lightning protection by irradiating a laser at a location where there is a demand for lightning protection using a group of artificial satellites. <Brief Description of the Drawings> <0008> <FIG. 13> Illustration of lightning protection method that irradiates photons with shorter wavelengths than UV-B, such as X-rays and gamma rays, from light emitting unit 1 in the sky to thunder cloud 2THCL (light receiving unit 2 in the air) (In FIG. 1, when irradiating, light emitting unit 1 used for laser SSPS in outer space and light receiving unit 2 in the air) (In FIG. 1, the light emitting part 1 used for the laser SSPS in space or the light emitting part 1 of a stratospheric platform, aircraft, etc. 3 may be used for irradiation.)< (FIG. 12) Illustration of lightning protection by short-circuiting the thundercloud 2THCL with the conductive cable 1WIRE-12. * (a) Illustration of an orbital elevator 10 with a cage 15/3KAGO connected to a ground section 14 and a space structure by a cable 12. (b) Illustration of a system in which the ground section 14 is connected to an aircraft 3, an aerial platform, etc. by a cable 12. The 3KAGO may be guided up and down (space/ground direction) by 12. <The following is an illustration of the method of implementation of the invention. <Example 1> <0010>—Ionizing radiation photons 1HNU-X such as X-rays, or photons 1HNU such as ultraviolet rays are irradiated from light emitting unit 1 placed in space or in the air or stratosphere toward the ground side so that they pass through thunder cloud 2THCL from the upper stratosphere side of the thunder cloud to the lower troposphere side and ground side. (1HNU is a lightning protection substance. (1HNU is used in ultraviolet, visible, and infrared light for lightning protection. Photons with wavelengths that react chemically or optically with oxygen molecules, nitrogen molecules, or atomic molecules in the atmosphere and are absorbed are preferred.) At this time, the low-resistance conductive pathway IONA formed through the layer of positive charge LCP in the upper part of the thundercloud destroys (is expected to destroy) the insulation between the layer of positive charge LCP in the upper part of the thundercloud and the layer of negative charge LCM in the upper part of the thundercloud. (When there is an insulation gap between LCP and LCM in the thundercloud, laser irradiation forms a low-resistance part in the aforementioned insulation gap, forming a wire-like part that weakens the insulating force in the thundercloud, with the intention of inducing insulation breakdown and electrical discharge). In the right side of the lower part of FIG. 13, the laser penetrates the thundercloud 2THCL, forming the conductive path IONA, IONA-LINE in the figure, discharging the charge of the capacitor consisting of LCP and LCM, short-circuiting it, and lightning protection is performed. (In the concept of insulating between thunderclouds with conductive wires, it is sufficient if the conductive wires in FIG. 1 of the patent document can be used to discharge or short-circuit the charge of the thunderclouds, and the thunderclouds can be used as conductors 12 and orbit elevator section 10). On the left in the lower part of FIG. 13, a laser to punch through the positively charged layer LCP in the upper part of the thundercloud The laser beam proceeds to punch through the positively charged layer LCP at the top of the thundercloud, ionizing the laser trajectory and forming a nail-shaped (or laser-dampened) low-resistance conductive path IIONA-NAIL, and a conductive path IIONA-NAIL is (suddenly) formed at the gap/distance between the LCP and LCM, which had been insulated. NAIL is formed, the distance of insulation is shortened only at the part of the conductive path IIONA-NAIL, and lightning protection is performed by discharging L-SCN from there. The laser may be turned off when there is an object to avoid laser irradiation in order to reduce the impact on airborne organisms, aircraft, etc. The output power of the laser can be controlled so that the laser output power is not too high outside the focal point FCS-2. If radiation or X-rays cannot be used to avoid biological effects, an ultraviolet laser may be used to ionize the atmosphere by controlling its output. <The left figure in FIG. 12 illustrates a case in which a power plant, space solar power plant, or space structure 1 on the space side is electrically connected to the ground 14, and the power from the power plant on the space side is transmitted to the ground 14 via a cable 12. The right figure in FIG. 12 shows a system in which a shortened cable is used to reach the aerial arrangement means 3 instead of the long cable of the orbital elevator, which has the advantage of shortening the cable), and the section from the light emitting part 1 on the space side to the light receiving part 2 in the air is used for power transmission or energy transport by the laser SSPS method, The figure illustrates a power and energy transmission system in which the deployment means 3 (aircraft 3, HAPS, etc.) including the light-receiving part 2 and the ground part 14 are then electrically connected via a cable 12 to transmit power from the light-receiving part 2 to the ground part 14 and the ground-side power grid 110. The cable 12 may be preferable to use the conductor element 1 or cable 1WIRE of the present application, in which a carbon material (such as CNT) is used for the material part 101 of the element 1 of the present application, reducing the amount of copper used) and the weight of the conductor is reduced compared to copper-only conductors. • The right figure in FIG. 12 shows that the placement means 3 must support said cable 12 so that it is lifted and hangs from the air to the ground, in which case it is preferable that the cable 12 is lightweight. (CNT has a specific gravity of 2.0 and copper has a specific gravity of about 8, CNT/carbon materials are lightweight, and the use of 1WIRE with carbon materials for said cable 12 can reduce the weight of the cable that placement means 3 must lift into the air.) The configuration of FIG. 12 is a system in which the cable 12 crosses the upper and lower layers of the thundercloud, LCP and LCM, to short-circuit the charge of the thundercloud through the 12. FIG. 12 shows a system in which cable 12 crosses the upper and lower layers LCP and LCM of the thundercloud, shorting the charge of the thundercloud through 12. The ground 14 is positively charged, and by connecting the negatively charged portion of the thundercloud with the aforementioned 12, a current flows through 12 due to the short circuit, and electrical energy is transported and transmitted. Although lightning protection is intended in this application, in the configuration of FIGS. 12, 12 and 14 can be used to collect the energy of the thundercloud on the ground, and the thundercloud energy obtained by 12 and 14 can be supplied to the power grid 1100 by means of circuits and devices provided in 14 and others. (The lightning power generation and lightning recharging may be done using 14 and 12.) The 3KAGO may receive energy from the light emitting part 1 by means of the light receiving part 2, and may be propelled and elevated. Aircraft 3, 3KAGO and aerial platform 3 may be equipped with devices that can generate electricity in the air, such as solar cells and aerial wind generators. Aircraft 3, 3KAGO, and aerial platform 3 may be equipped with devices that can generate electricity in the air, such as solar cells, aerial wind generators, etc. They may also be equipped with auxiliary power sources and batteries. Aircraft 3 (aerial platform) connected to the ground 14 shown on the right in FIG. 12 may be equipped with a ladder truck, ladder hoist, or hoist to lift and lower cargo, and may also be equipped with an electric power supply to and from the ground. The aircraft may be equipped with a robotic arm or crane to perform additive manufacturing, removal processing, various operations, and cargo transport. In the case of transmitting energy from the SSPS (laser type, or in some forms of this application, millimeter wave, microwave, or radio wave type) to the ground, this application discloses two forms of transmitting power using cables 12, and converting the power in the form of fuel or chemical substances in the arrangement means 3 and transporting said substances to the ground 14 by aircraft, etc. The other method is to convert the power in the form of fuel and chemicals by means of arrangement means 3 and transport the aforementioned substances to the ground 14 by aircraft, etc. <Industrial applicability> <0011> In the case of the configuration shown in FIG. 13, the system can be used to attempt lightning protection by irradiating a laser from the light-emitting part 1 of a group of satellites to an area 2 where lightning may be generated. (The configuration with light emitting unit 1 in FIG. 13 can irradiate photons toward thunderclouds and the atmosphere in areas where lightning is likely to strike when a satellite with light emitting unit 1 is in LEO, etc., to promote short-circuiting and discharging of capacitors in the thunderclouds, thereby facilitating immediate response to user requests for lightning protection. (On the other hand, in the case of the configuration shown in FIG. 12, it is necessary to deploy the cable 12.)<Description of the code> <0012><Description of FIG. 13>1: A light-emitting part placed in outer space or in the air. Laser emitting part. ultraviolet rays including UV-B and UV—C or photons including X-rays gamma rays. * Without limiting the scope of the invention of this application, when irradiating photons to thunderclouds from the stratospheric or space side to act on thunderclouds and focusing on photons that react and dissociate by ozone, oxygen molecules, nitrogen molecules, atmospheric molecules, etc. and decay in the atmosphere, gamma rays, X-rays, some UV and IR light, millimeter waves and some other Radio waves may be included. 1SSPS: SSPS part that contains 1 light-emitting part. 1SSPS-SYS-SEIZA: light-emitting part of a satellite constellation, e.g., LEO or GEO satellite constellations. ILLR: free electron laser device (output controlled x-ray laser) 1 HNU-X: ionizing radiation photons such as X-rays, laser. 1HNU: photons emitted from the light emitting part 1.2: the part/object that receives the photons of the light receiving part 1.2THCL: thunder cloud. (When a cumulonimbus cloud, etc. is used as a photodetector 2) 2AIR: Aerial air containing 2. LCM: Lightning cloud negative charge region, negative charge on the lower ground side of the thundercloud LCP: Lightning cloud positive charge region, positive charge on the upper thundercloud L-SCN: Lightning cloud positive charge region, positive charge on the upper thundercloud L-SCN: Ionizing part protruding like a nail into the upper layer of the thundercloud L-SCN: Lightning cloud negative charge region, negative charge on the upper layer of the thundercloud L-SCN: Lightning cloud positive charge region, positive charge on the upper layer of the thundercloud L-SCN: A part of a thunderstorm that is expected

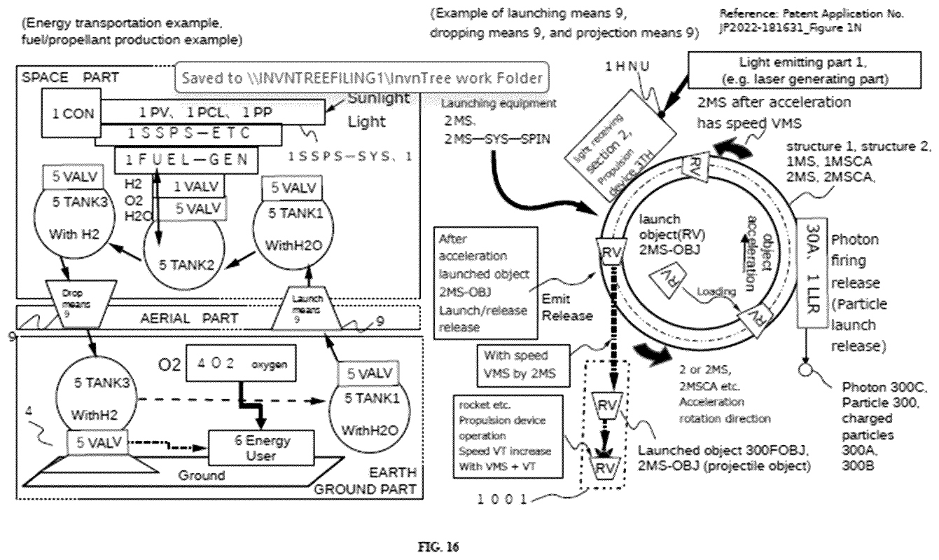

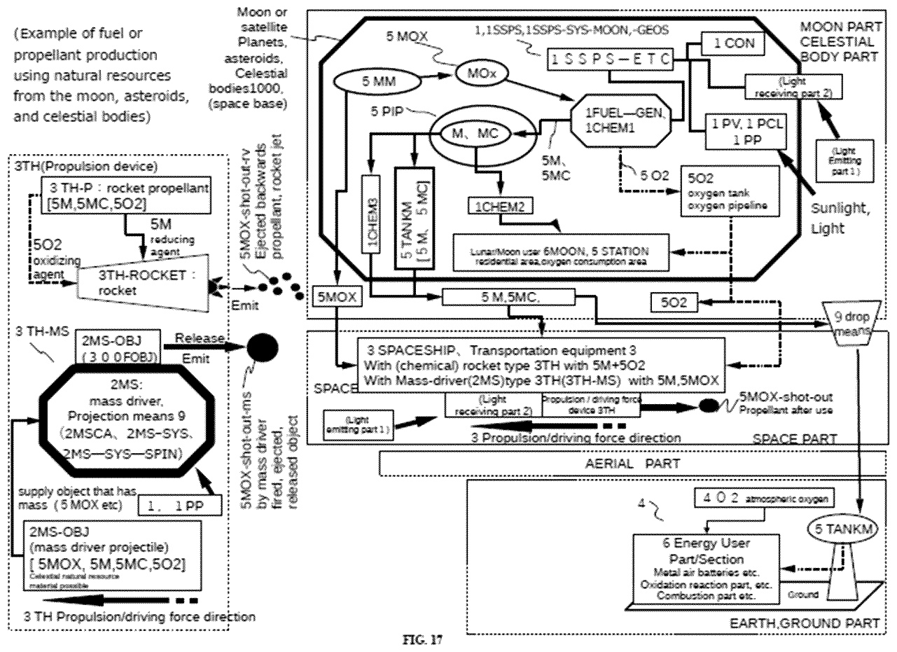

to discharge using the ionized part that sticks out like a nail in the upper layer of the thundercloud as a clue, a discharge point inside a thunderstorm. Insulation breakdown area. IONA-NAIL: (Ionization area that sticks out like a nail driven into a plate in the upper layer of thundercloud created by laser irradiation, plasmaized area, low-resistance area. (Ionized, plasmaized, and low-resistance areas that stick out like nails in the upper layers of a thundercloud created by a laser. A conductor protruding from a plate. Discharge is induced in the thundercloud. It can be a low-resistance portion formed by the focal point FCS-2 of multiple lasers emitted from multiple light-emitting parts 1). IONA-LINE: (A short-circuit conductor or low-resistance portion formed by a straight, conductive laser. VL: voltage of thundercloud (capacitor voltage) 1100: power grid 6: power user <explanation of FIG. 12>10: orbital elevator section space structure. 1: space structure, satellite space base, etc. (Example: Space structure 1 and aerial structure 2, the so-called orbital ring part described in FIG. 1B of Patent Application No. 2022-086263. 1TH and 2 may be provided and propelled and accelerated by receiving photons from 1. Spacecraft, launch vehicles, space structures, orbital rings, aerial structures, and ring structures may be equipped with a 1TH or 3TH and a light receiving unit 2 to transmit photons from the light emitting unit 1 to accelerate, propel, move, fly, float, control attitude, and drive them.) 1TH: Spacecraft propulsion system. 3SPACESHIP (spacecraft, spaceship, launch vehicle, etc., equipped with 2, 1TH and 3TH) 3KAGO: cage section attached and guided by cables 12 of orbital elevator 10 and propelled, elevated and moved by propulsion equipment. 15 3TH: propulsion equipment of 3KAGO, propulsion equipment and its auxiliary equipment, propellant, etc. 2: light receiving section. 12: cable (1WIRE may be used) 14: ground section, 10 ground section 17: Connection 1: light emitting part. 1PP: power plant. 1100: ground side power grid. 1100S: space side power grid. <FIG. 26: Description of the track elevator and aerial platform. 10B pulleys in FIG. 26 may include combination pulleys and may contain the elements of a known traction-type rope elevator, including balance weights, lifting ramps, ropes, wires, slewing wheels, combination pulleys, tugs, hoists, baskets, boarding station doors, control equipment, and a mechanical room. The cage may include a boarding station machine room, control unit, buffers, bits, and brakes. The basket 15 may be equipped with a propeller 3TH including a light receiving unit 2, a basket 15, and a balancing weight 15W. FIG. 26 right shows an elevator 10AIR with a heavy hoist 10B installed in the lower part and a combination pulley 10B in the upper part. 10B can be configured as an elevator 10AIR or a track elevator 10 with a known hoist in the lower part (and with a hoist in the upper or lower part). 10B may include a combination pulley, hoist, and multiple pulleys. 15: cage section of an elevator/ropeway, a cargo compartment, a carrying unit. 15 can also be a cage section 15 that is an aircraft 3/transportation equipment 3 connected by a wire 10WIR with a propulsion unit 3TH (track elevator 10 or aerial ropeway 10). (It can be a cage 15 of a cable 12 of an orbital elevator 10 or an aerial platform 3.) 15W: counterweight of the elevator, cableway, pulley, crane section, and cage 15. 10B: pulley section, (may be a pulley or combination pulley), tug, winder, or winding motor section of the elevator (the winding motor may be a non-contact type motor with magnetic levitation bearings). 12 or 10WIR pulley, winder, and power section)*3TH has a propellant such as water, and the 3TH propellant may be replenished when 15 reaches the foundation 14 section. * 15 and 15W may be aircraft 3 or transport equipment 3, and 3 may have a propellant 3TH and a receiver 2. When the 3TH of 15 and 15W is at an altitude higher than the stratosphere and troposphere where the light of the light emitter 1 (e.g., UVC light) can reach, the 3TH is irradiated by the laser beam from the light emitter 1, and the 3TH is 3KAGO 15 (/15W) and moves up and down, elevating and lowering. When 15W is at the higher altitude mentioned above, the 3TH of 15W is irradiated by the light emitting part 1 and moves 15W to move 15. 10WIR: rope/wire of 15/15W. 14: ground 4LASER: Laser emitting part from the ground. The orbital elevator/airborne platform shown in FIG. 26 is a Ferris wheel/tramp and its carrier, which can be supported and rotated by a pulley 10B or other means at the space/airborne device 17 and the ground section 14, like a Ferris wheel/tramp and its carrier. The 10WIR is equipped with a ring 10WIR that can be supported and rotated by a pulley 10B, etc., and is operated to rotate each 15 in one direction (from space to ground and back to space again like a ropeway) by irradiating a laser to the light receiving unit 2 of each propulsion unit 3TH of a basket 15 attached to the 10WIR using a pulley (like a Ferris wheel or multiple conveyers on a ropeway). The rotation may be operated in a repetitive manner (like a ropeway from space to ground and back to space again). Propellant, water, etc. for the 3TH may be supplied to the 15 at the 14 on the ground. (Each 15 or 15W of 10WIR may be repeatedly lifted up and down from 14 to 17. (The circular path may be repeated from 14 on the ground to the aerial side 17 and back to 14 on the ground, as in a cableway or Ferris wheel. (May be used for acceleration and drive.) *For example, if it is desired to lift and place the device 17 near the space-side structure 2 from the ground, a platform 3 including the device 17 on the left side of FIG. 26 (with the device 17, the propulsion system 3TH and the receiver 2 for photons transmitted from the receiver 1, which elevates and supplies cargo, propellant and water from ground 14 to the propulsion system 3TH Aerial platform 3 with a cage 15, cable 12 and pulley 10B, which is capable of 15. balloon or rocket launched from the ground, or an aerial elevator system 10AIR, an aerial version of a space elevator, including a series of the aforementioned elements), propellant and water are supplied from the ground to 3TH while through 12 and 3. The 3TH can be propelled, levitated, elevated, moved, attitude controlled, launched, and lifted by the propulsion system using the energy from the light-receiving part 2 and the aforementioned propellant. It may be possible to launch and raise the means of arrangement 3 while heating and jetting water and propellant supplied from the ground with the energy obtained from the light-receiving part 2, and to move and place it near the structure 2 on the space side. 17: A connection part with the air or space side part, and a non-contact fishing down mechanism may be provided. 17TR: A transportation device or train section that is suspended contactless from the structure 2 and can be moved and guided along the structure 2. It may be equipped with a light-receiving part 2. It may be propelled and operated by receiving photons from the light emitter 1. <FIG. 27, Description of orbital elevator and space structure. 1100: power and communication network. 1000: ground, earth, moon, planet, satellite, celestial body. 10: orbital elevator. 12: cable. 15: space elevator basket. 17: connection. It may include functional parts of magnetic suspension section (magnetic attraction system, electromagnetic induction levitation support system EDS, etc.). It may be an aircraft 3 or a space plane.) 171: Magnetic suspension means of 17. 171C: Coil (for magnetic suspension and magnetic suspension between 17 and space and aerial structures) 171S: Sensor, gap sensor for magnetic suspension. 171E: Circuit, control circuit, magnetic attraction feedback circuit, magnetic suspension control section. 171R, E: Propulsion devices 1TH and 3T of 17. H. space structure 1, aerial structure 2: structure placed in the air or in space (annular, linear, base station, aircraft/spacecraft), may include magnetic suspension functional part. 17TR: A transport device that is magnetically levitated, magnetically suspended, non-contact supported, guided, moved or propelled by means of said rails. 3TH, may be equipped with a light receiving unit2 and driven. 317: A magnetic suspension means on the side of a structure. The part of a magnetic body, core/magnetic core, magnet PMG, conductor, etc. that magnetically acts upon, attracts or repels 171C. (Part of the magnetic suspension section)*317 can be sectorized or equipped with parts that increase the resistance of 317. * To reduce eddy currents in the rotating 317 and stationary 17, in case the forces due to eddy currents (behavior of Arago's rotating disks and U-shaped magnets) interfere with the magnetic suspension aimed for in this application, elements that can reduce or increase the conductivity of 317 may be used, including (copper reduced and carbon) conductor elements 1, 1 FILM and its gate control circuit may be used. *From the perspective of controlling eddy currents, it may be possible to control the ease of generating eddy currents in the 317 and 317 MG sections. When increasing eddy currents, the gate of 1FILM of 317 is turned on to decrease the resistance of 317 and change the repulsion/force between 317 and 171C. When decreasing eddy current, turn off the gate and increase the resistance. 3171S: sensor, gap sensor. 32: circuit, control circuit. 32-wir: wiring <document name> Scope of claims <claim EW1> A photon generator (1) located in a satellite/space and a photon receiving device (1) irradiated from said photon generator (1). (2) a photodetector (2) located in the stratosphere or at an altitude above the troposphere, which is capable of receiving photons irradiated or emitted from said photon generator (1), and said energy transport method including the steps/procedures of irradiating, emitting, relaying, transmitting and transmitting photons from said photon generator (1) to said photodetector (2), wherein said photons are UV-B The energy transport method, wherein said photons are UV-B or photons with a wavelength shorter than 315 nm, and wherein said photons are photons having characteristics of being absorbed by ozone, oxygen molecules, oxygen atoms, nitrogen molecules, nitrogen atoms, and molecular atoms in the atmosphere through optical and chemical reactions. <A method of low-resistivity of the atmosphere using the energy transport method of claim EW1, comprising the steps/procedures of irradiating, firing, relaying, transmitting and transmitting a laser containing said photons from said light emitting part 1 to said light receiving part 2, which is the atmosphere/thundercloud in the air, wherein said A method of lowering the resistivity of the atmosphere, wherein the laser has a trajectory across, through, or through the atmosphere/thundercloud from the space side to the ground side, and wherein said laser is a laser using photons in the wavelength range of X-rays and gamma rays, and wherein the oxygen molecules, ozone, and oxygen atoms, or nitrogen molecules The method of making the atmosphere low-resistance by ionizing oxygen molecules, ozone, oxygen atoms, nitrogen atoms, or molecular atoms in the atmosphere, and being capable of forming ionized regions, plasmaized regions, and highly conductive regions along said path of said laser. <A lightning protection method using the method of lowering the resistance of the atmosphere as described in claim EW2, wherein said ionized region, plasmaized region, and highly conductive region are formed between the positively charged region of the thundercloud and the negatively charged layer of the thundercloud, and the resistance between the positively charged layer of the thundercloud and the negatively charged layer of the thundercloud is reduced. A method for counteracting and neutralizing lightning charge or a lightning protection method having the feature of reducing the value and destroying the insulation of a charged capacitor consisting of a positively charged layer of a thunder cloud and a negatively charged layer of a thunder cloud and lightning protection. <Document Title> Summary <Summary><Problem> In the case of lightning protection by laser from the ground, the influence of weather was considered, so a method of lightning protection by laser irradiation from outer space was examined. <Methods for Solution> Using a light emitting part 1 (synchrotron radiation generator, free electron laser) located in outer space and in the air, X-rays and gamma rays are irradiated and emitted to a light receiving part 2THCL, which is a thundercloud and raincloud in the air. Said laser may have a laser trajectory that crosses, passes through, or penetrates the thundercloud 2THCL from the space side to the ground side. The ionizing radiation laser such as X-rays and gamma rays ionizes oxygen molecules/ozone/oxygen atoms or nitrogen molecules/nitrogen atoms and other atmospheric molecular atoms in the path of said laser, forming ionized, highly conductive and plasmaized regions of the thunder cloud. Disclosed is an attempt to short-circuit or reduce the insulation (lower the resistance of the atmosphere/thundercloud) between the charged region/layer and the negatively charged region/layer, and to control lightning protection or lightning strike. <Selected Figure> FIG. 13.

<LP0004> (Protection of cable 12 from AO and conductor element 1) Ladder 12 or cable 12 that may react with atomic oxygen AO in this application (e.g. cable 12 of an orbital elevator that touches AO that may exist at high stratospheric altitudes or in low orbital space) is made of carbon fiber as shown in (c) in FIG. 11 The cable or structure may be made of carbon fiber plated or coated with a metallic film (or silicon-based film or barrier film against AO), such as copper, to withstand erosion from atomic oxygen AO, as shown in (C) in FIG. 11. In low orbit and above the stratosphere, atomic oxygen AO, which is formed by the dissociation of the earth's oxygen molecules (by photo-reaction with vacuum ultraviolet light, etc.), is expected to react with carbon materials and plastics including CNT, etc., degrading the materials (eventually decomposing the carbon materials into carbon dioxide, etc.), which may result in the degradation and destruction of the cable 12. However, in order to protect the carbon materials of the cable 12 from AO, the carbon materials may be coated with a metallic film or the like. The aforementioned coating may have the effect of preventing the carbon material from being invaded and degraded by the aforementioned AO, in addition to being able to be driven as a conductor element 1 with a carrier introduction function using the electric double layer transistor structure claimed in the present application as described in FIG. 1 and FIG. 11. The cable 12 of the present application may be made of carbon material and may have a deposited layer, coating, or plating layer of metal film or barrier film with barrier properties against AO. For example, in the left and right configurations in FIG. 12, cable 12 and 1WIRE may be coated with the aforementioned. Since the cable 12 is a 10 km, 20 km, or 100 km long conductor above tropospheric altitude, carbon-based materials or deep eutectic solvents may be used for 101 and 105 of 12 to reduce material costs. <LP0005> (Thundercloud and wire coating) For example, the left and right configurations in FIG. 12 (left: space elevator connected to ground 14 and space structure 1 with cable 12, right: ground 14 and airborne platform 3 connected via cable 12) both have cable 12 and 1WIRE passing through thundercloud, and the upper and A pathway can be formed to short-circuit the positive and negative charges of the lower layer. 1WIRE may be used to form the aforementioned metallic film, etc. with AO barrier properties in the 1COVER section, or in the conductive section where the effect of said metallic film short-circuits the charges of the thundercloud. (Said metallic film may be used for the purpose of lowering the resistance of 1WIRE in order to channel the charge of the thundercloud or to prevent the instantaneous high current generated by the thundercloud charge flowing through 1WIRE from flowing through the electric wire and causing the wire to overheat and generate heat derived from its electrical resistance. In this case, even 1WIRE and 12WIRE that do not have an electric double layer transistor structure or carrier introduction mechanism may be coated with a metal film to protect the wire from AO and to release or channel the electric charge of the thunder cloud.)< (Electric circuits on flexible substrates/substrates such as film substrates, wires, threads, fiber materials, etc., including conductor element 1) Electric circuits using the aforementioned conductor element 1 and conductor 1WIRE, formed on flexible substrates/substrates, which are used in electronic devices, electrical devices, sensors, computers, and other devices. It may constitute an electric circuit used in wireless communication terminals and wireless type tags (2TAG). When carriers can be increased by introducing carriers while having the lightweight and flexible characteristics of carbon materials and organic semiconductor materials, the effect of improving the electrical conductivity of said electrical circuits will occur. This may have the effect of reducing the electrical resistance of the circuit. <LP0007> Silicon oxide/silicon oxide 5MOX (or metal oxide 5MOX) of natural resources obtained from celestial bodies such as the moon, satellites, and asteroids (and other natural resource extraction sites 5 MM on the moon, Mars, and other celestial bodies containing silicon and other resources) is reduced using solar energy, power plant electricity, etc. on the spot on the aforementioned moon, satellite, or asteroid. The 5MC, 5M, and 5O2 may be used as propellant for spacecraft by reducing the silicon compound 5MC, metallic silicon 5M, and oxygen 5O2 using solar energy, power from a power plant, etc. on the moon, satellite, or asteroid. The gravity of the moon, satellites, and asteroids on spacecraft is small. On the other hand, there are planets such as Jupiter that contain a lot of hydrogen but have high gravity like the sun, and it may take a lot of effort to escape from the planet or celestial body in question into space. In this application, we focus on moons and asteroids. For example, if a spacecraft equipped with a rocket/propulsion system 3TH is to navigate through space from the moon to Mars, propellant (liquid hydrogen, chemical rocket fuel, liquid oxygen, water, etc.) launched from the earth alone may be insufficient during the course of the journey. Considering the cost of launching from Earth to space, it may be tempting to generate and procure propellant from resources already existing on celestial bodies in space, such as the Moon, Mars, Venus, planets, asteroids, and satellites. (There is water on the moon, and water can also be broken down into hydrogen and oxygen, which can be used as propellant.) As claimed in this application, the Moon has abundant natural resources such as silicon oxide and metal oxide 5MOX (other than water), which are reduced to 5MC/5M (or reducing agent) and 5O2 (or oxidizing agent), which are then loaded onto spacecraft (FIG. 17, 5M and 5O2 loaded on a spacecraft). 3SPACESHIP and transportation equipment 3), the amount of propellant for the spacecraft 3SPACESHIP can be increased (locally procured), and the effect will be useful in securing propellant when the spacecraft is propelled from the Moon to Mars, Venus, or more distant celestial bodies. The purpose is to increase the operating time of the 3TH propulsion system and to increase the distance that the spacecraft 3 can reach and the speed at which it can travel. The silicon in this case is not bulk metallic silicon to facilitate oxygen reaction, but rather easily reactive powdered silicon 5M (powdered to facilitate contact with oxygen and easy reaction, image of dust explosion of 5M, FIG. 173TH-ROCKET), which can be liquefied and then mixed with oxygen 5OX. 5OX and 5M powder can be reacted in the rocket's propulsion section (rocket, pressure chamber, nozzle) and propelled by the recoil of the heated and injected 5MOX that is released behind the spacecraft, or the spacecraft can be equipped with a light receiving section 2 and the energy obtained by the light receiving section 2 can be given to 5M and 5M (or propellant/solid propellant made based on 5M) may be laser ablated, plasma jetted or heated and released behind the aircraft. <As shown in FIGS. 16 and 17, the launch object 2MS-OBJ may be made of silicon oxide 5MOX (or metal oxide 5MOX), a natural resource obtained from the Moon, satellites, asteroids, and other celestial bodies, and materials extracted from and based on the material (reducing agent 5M, 5MC, obtained from 5MOX, oxidant 5O2, etc.), oxidizing agent 5O2, etc.) may be used. The mass driver 2MS may fire, release, and release the 5MOX, etc., backward in the direction in which the spacecraft 3SPACESHIP wishes to travel, and the reaction/reaction may propel the 2MS, the propulsion system 3TH including the 2MS, the spacecraft 3SPACESHIP, and the aforementioned transportation equipment 3SPACESHIP. 2MS may be driven by energy obtained from the 1SSPS or 1PP. The 2MS may be driven by energy obtained from the 1SSPS or 1PP. As shown in FIG. 16, the 2MS may be equipped with a light receiving unit 2 that receives photons 1HNU from the light emitting unit 1 and a propulsion device 3TH that uses the energy of the photons obtained from the light receiving unit 2. (2MS: Mass driver or launching device 2MS. 2MSCA: Annular 2MS, including annular structure 2. 2MS is equipped with 30A and ILLR to emit and reflect photons backward or in the opposite direction to the direction in which they are to be accelerated, and the reaction/reaction of the photons propels and reflects the annular structure 2 and 2MS-OBJ loaded in the structure 2. 30A: Accelerator, a device that emits photons and accelerates them by the recoil/reaction of the emitted photons. It may be a free electron laser and synchrotron radiation generator ILLR. The annular structure 2 may contain a particle accelerator.30A may be a photon sail and may be equipped with a light receiving unit 2 from a light emitting unit 1, a propulsion device driven by a photon sail or laser, a propulsion device that receives and drives a laser or beam. * Photon receiver 2 and light emitter 1: The light emitter 1 may be driven by power and energy obtained from 1SSPS and 1PPP. * 2MS-OBJ: A mass object such as 5MOX (celestial resource) may be used as the propellant for the mass driver type propulsion system 3TH, loaded into 2MS as 2MS-OBJ, rotated, accelerated, launched, ejected and released, and then 2MS-2MS SYS-SPIN may be propelled by the recoil/reaction of the 2MS-OBJ launch such as 5MOX with mass, and the mass-driven propulsion device 3TH/3TH-MS using that operation may be configured. The 3TH-MS may be configured to use this action. The 3TH-MS may be a transport device 3 that carries the 3TH-MS and propels it into outer space, interplanetary space, or to a distant destination. 1001: The target of the launch vehicle to be launched: the sky, outer space, orbit in outer space, satellite (moon, etc.), planet (Venus Mars), or celestial body. The 2MS-SYS-SPIN accelerates the launch object 2MS-OBJ to a speed within the tolerable range of centrifugal force by injecting photons, and launches it. The 2MS-SYS-SPIN can accelerate the launch object 2MS-OBJ to a speed that can be withstood by centrifugal force, which may have the effect of increasing the speed at which the reaction, reaction, and transport equipment 3 can reach the target. (Explanation of the code in FIG. 17) In the case where the 2MS-SYS-SPIN launch device is used for the 3TH (propulsion device) in FIG. 17 (3TH-MS), the 2MS-OBJ is propelled, accelerated, rotated, and spun by photons to reach the 2MS-OBJ. SYS-SPIN and the launch object 2MS-OBJ loaded and contained in 2MS-SYS-SPIN are accelerated by photons, and then the 2MS-OBJ is ejected from 2MS-SYS-SPIN. The 2MS-OBJ may be ejected, projected, and launched by ejecting and releasing the 2MS-OBJ from the 2MS-SYS-SPIN and propelling the transport device 3 by its recoil/reaction. <The ultraviolet rays emitted from the light emitting part 1 of the present claim are UV-B (315 nm to 280 nm, absorbed by ozone and oxygen molecules), UV-C (280 nm to 100 nm, absorbed by oxygen molecules), UV-B (315 nm to 280 nm, absorbed by ozone and oxygen molecules), UV-B (315 nm to 280 nm, absorbed by ozone and oxygen molecules) and UV-C (280 nm to 280 nm, absorbed by oxygen molecules). UV-B (315 nm to 280 nm, absorbed by ozone and oxygen molecules) and UV-C (280 nm to 100 nm, absorbed by oxygen molecules), which are absorbed by photoreaction. • This application is based on the fact that photons of UV-C with wavelengths near and below 243 nm are absorbed by oxygen molecules due to the photoreaction of the oxygen molecule O2 with a wavelength near 243 nm (said absorption is a dissociation reaction and photoreaction of the oxygen molecule into two oxygen atoms), and thus the said 243 nm (about 240 nm or below) and below is expected to prevent photons from reaching the ground. (In this application, we may use the fact that photons with a wavelength of around 243 nm or less have enough energy to break the bond between oxygen and oxygen, and can cause a photoreaction to make an oxygen molecule into two oxygen atoms.) The oxygen molecules are 10 times more concentrated in the troposphere than in the stratosphere, and as a result, the absorption of photons with wavelengths shorter than 243 nm is 10 times stronger in the troposphere than in the stratosphere. The method of the present application, when a photon beam or laser of high density and high power density with a wavelength shorter than 243 nm is artificially transmitted in a linear fashion from the stratosphere to the ground (in an amount greatly exceeding the amount of ultraviolet rays from sunlight), even if the ozone in the natural environment cannot absorb the photons with a wavelength shorter than 243 nm, the ozone in the stratosphere will not be able to absorb the photons with a wavelength shorter than 243 nm. The intention is to use a layer of oxygen molecules 10 times larger than that in the stratosphere near the ground and in the troposphere to absorb the photons even if they cannot be absorbed by ozone absorption in the natural environment. • As a similar concept, this application can use absorption (nitrogen-nitrogen bond dissociation reaction/photoreaction) by photoreaction between nitrogen molecules and photons of shorter wavelengths than around 126 nm (or 100 nm or less) instead of photoreaction by oxygen molecules and light of around 240 nm. When using nitrogen molecules, nitrogen molecules, like oxygen, are a component of the atmosphere and have the advantage of being more abundant than oxygen (21% oxygen, 78% nitrogen). Therefore, nitrogen molecules may absorb more light than oxygen molecules in the stratosphere and troposphere, especially as they move toward the ground, and light in the vicinity of the wavelengths that can be absorbed by nitrogen molecules may be irradiated from the light emitting unit 1. The photon and the nitrogen molecule may be photoreacted to form a nitrogen atom, which may then be used in another chemical reaction. For example, a nitrogen compound (nitrogen compound, NH3, NOX) may be synthesized from a nitrogen atom produced by photoreacting a photon of 100 nm or less irradiated from the light emitting unit 1 of this application to the light receiving unit 2 in the atmosphere. The energy obtained from the light emitting part 1 of this application may be used to unbind atmospheric or raw material substances. For example, it may be used to unbind the molecular bonds of water molecules and also for subsequent chemical reactions and substance synthesis. <This application can be used to dissolve strong nitrogen bonds in nitrogen molecules using high-energy photons at around 126 nm to produce nitrogen compounds. O—O bonds in oxygen molecules, N—N bonds in nitrogen molecules, HO and H—OH bonds in water molecule H2O, C—H and C—C bonds in carbon compounds, and O—The dissociated molecules and atoms may be used to synthesize, generate, and manufacture substances that will become products. (Since the configuration of the present application is expected to use photon energy to break strong nitrogen bonds, etc., as described above, this feature can be used to dispose of difficult-to-dissolve substances that cannot be easily broken down (such as some plastics and polychlorinated biphenyl PCBs) by using photons with energy that can break molecular bonds 1HNU and this photoreceiver 2 may be used to dissolve said persistent substances by breaking their bonds as described above). <Examples of dissociation of oxygen molecules and subsequent use of this application (1) O2->1HNU->2O (atomic oxygen AO) (2) O+CX (flame retardant plastics and other organic materials CX)->CO2 (O oxidizes CX and dissolves it into carbon dioxide)<In the field of silver halide photography, it is well known that when silver halide (silver chloride AgCl, etc.) is irradiated with ultraviolet photons, a photo-redox reaction occurs and silver is deposited. It may be used in this application to irradiate a compound containing a metal (light receiving part 2 containing said compound) with said photons (especially photons of shorter wavelength than UV-B) to produce a metal. The energy possessed by said photons and the heat generated by said photon and laser irradiation may be used in reacting, decomposing and generating the above compounds. <LP0002> <Use of photons and lasers absorbed by oxygen emitted from the light-receiving part 1 for propulsion of aircraft, spacecraft and launch vehicles> In the method of energy transport using photons and lasers of shorter wavelengths than the ultraviolet light of this application, aircraft 3, airborne platforms, aerial structures, space structures, The energy can be delivered to the ground, airborne, space, and cage sections of aircraft3, aerial platforms, aerial structures, space structures, orbital ring structures, partial orbital rings, space fountains, and orbital elevators, and the energy required for flight, levitation, propulsion, movement, attitude maintenance, and direction change of the above devices, structures, and transportation equipment can also be delivered to the ground, airborne, space, and cage sections. • In the present application, for the light-receiving part 2 that receives the photons emitted or irradiated from the light-receiving part 1, the means 3 for placing the light-receiving part 2 in the air, the means 3 may be a part or means that is not an aircraft such as an orbital elevator but is in the air. The light receiving part 2 may be included in the cage part 3KAGO.3 of the orbital elevator. The placement means 3 may be a portion fixed to the ground and levitated/floated in the air (may be an aerial platform). • For example, in the case of a photon sail of an aircraft 3 or a cage section 3 (15) of an elevator or a propulsion device 3TH which is propelled by the recoil of a heated and injected/radiated propellant, the energy to drive the 3TH is the energy received from the irradiation of photons and lasers of shorter wavelength than said ultraviolet radiation which is absorbed by the above-mentioned oxygen. (For example, a laser may be used to heat the propellant water. (For example, the laser may be used to heat the propellant water, and the water may be injected through the nozzle of the propulsion device or the like to configure the device to propel, fly, or float. In addition, if the 3TH is a rocket or other device that jets propellant in a certain direction, it may have a thrust deflector or other device that changes the direction of the jet or nozzle. The 3KAGO cage of an orbital elevator may be equipped with a light-receiving section 2 and a 3TH with a thrust deflector to control the switching of the direction of the thrust up and down for lifting and lowering the 3KAGO.) The 3KAGO may be used to operate and propel the aircraft 3, aerial structure 2, orbital ring 2, space structure 1, orbital ring 1, cage 15 of orbital elevator, and transportation system described in Patent Application No. 2022-015274 and Patent Application No. 2022-086263. (For an aircraft positioned in the air, a photon laser of a shorter wavelength than said ultraviolet light may be used to propel and launch the transportation equipment 3 into the air and space by irradiating a photon laser of a shorter wavelength than said ultraviolet light from the light emitting part 1 on the space side to the light receiving part 2 of the aircraft 3 transportation equipment 3 in the air, and propel said transportation equipment 3) • Transportation equipment 3 in the air from the light emitting part 1 on the space side When irradiating said laser/photon of said ultraviolet rays to the equipment 3, the effect that said photons are less likely to reach the ground part due to the feature of being absorbed by oxygen is produced. (When the high power laser energy from the SSPS does not reach the ground in space or at high altitude, a focal point FCS-2 can be formed and used for propulsion of the transportation equipment with light-receiving part 2 at that point, which is useful for propulsion of the equipment to be propelled by the energy input from space.). For example, a photoelectric device corresponding to ultraviolet rays can be incorporated into the solar plane 3, and the solar cell can drive the solar plane during the daytime (while the 3 acquires water such as rainwater), and the laser 1 of said ultraviolet rays can be irradiated during the nighttime and converted into electricity by said photoelectric device and propelled by a propeller motor, or the water can be heated by said laser using said ultraviolet rays The water may be heated by the ultraviolet laser (the heat generated by the absorption of the ultraviolet laser by a photon absorber may be used) and propelled by a propeller motor. The water may be heated by the ultraviolet laser (heat generated by absorbing the ultraviolet laser in a photon absorber) and propelled by the recoil of the water jet. The intention of this application is to ensure safety on the ground by focusing on ultraviolet photons absorbed by oxygen when providing energy from the light emitting unit 1 on the space side to the airborne transportation equipment 3 and users on the ground, and by making it difficult for the photons to reach the ground. <LP0003> <Claim LP1> Energy transport using a light emitting part 1 and photon generating part (1) located on the moon, on a satellite, or in space, and a light receiving part (2) located in the stratosphere or in the air at a height above the troposphere that is capable of receiving photons irradiated or emitted from said photon generating part (1) The photons are UV-B or photons with a wavelength shorter than 315 nm, and the photons are ozone, oxygen, oxygen atoms, or nitrogen molecules. The energy transport method, wherein said photon is a photon having a characteristic of being absorbed by a photoreaction or chemical reaction with ozone, oxygen molecules, oxygen atoms, or nitrogen molecules. <Claim LP2> The energy transport method according to claim LP1, wherein said photons are photons that are absorbed by oxygen and nitrogen molecules, photons with wavelengths below those absorbed by oxygen and nitrogen molecules (wavelengths near 243 nm and near 126 nm), and photons that are absorbed through photochemical and dissociative reactions. <Claim LP3> A method of producing a substance used in the production of fuel, fertilizer, nitrogen compounds, and substances using a process of breaking nitrogen nitrogen bonds in nitrogen molecules by using an energy transport method using photons of wavelengths (around 126 nm) or less that are absorbed by nitrogen molecules as described in claim LP2. (A production method with the intention/features of using the process of breaking the nitrogen nitrogen bonds of nitrogen molecules by using high energy photons in the vicinity of 126 nm to break the strong nitrogen bonds of nitrogen molecules to produce nitrogen compounds) <Claim LP4> A production method using an energy transport method using photons having effects such as being absorbed by raw materials and material molecules such as nitrogen molecules, oxygen molecules, water molecules and carbon containing substances as described in claim LP1 and breaking their bonds. A method of producing a substance used in the production of fuel, fertilizer, or material using a process of unbinding raw material molecules (a process of dissociating molecules using photons) by using an energy transport method using photons having the effect of unbinding, etc.

An element in which a carrier introduction portion 104 is formed in a material portion 101 by applying a voltage VGS between a first electrode 106 and a second electrode 102, and in which the conductivity of said material portion 101 including said carrier introduction portion 104 can be changed, said material portion 101 of said element includes the channel portion of the transistor, said carrier introduction portion 104 includes said channel portion, said first electrode 106 of said element is the gate electrode 106 of the transistor, said second electrode 102 of said element is the source electrode 102 of the transistor, and said element can change the conductivity of said gate electrode 10 A conductor using said element having the feature that the capacitor portion comprising the insulator 105 of said transistor, said material portion 101, and said gate electrode 106 can be charged by said voltage VGS applied to 6. <Claim 3> A conductor according to claim 1, wherein said transistor is an electric double layer transistor. <claim 4> A conductor using said material portion 101 comprising a porous membrane, said material portion 101 having a space that is a gap relative to the total volume of said material portion 101, and said material portion 101 having a surface area of the interface where said material portion 101 and said insulator 105 are in contact that is greater than the total area of said material portion 101. A conductor as claimed in claim 3. <A conductor as claimed in claim 4, wherein said conductor element is used in an insulated or bare wire, and wherein the cross-section of said conductor comprises, from the center of said cross-section, an inner conductor portion 106 operating as a gate electrode 106, said insulator surrounding said inner conductor portion 106 105 and said material portion 101 which becomes an outer conductor surrounding the outside of said insulator 105, or the cross-section of said conductor has, from the center of said cross-section, an outer conductor portion 106 which acts as a gate electrode 106, said insulator 105 surrounding said outer conductor portion 106, and said material portion 101 which becomes an inner conductor having said material portion 101 which becomes a conductor. <Concerning the conductor as claimed in claim 3, the conductor including a control portion that controls the gate electrode 106 of said conductor element, a portion that drives said gate electrode 106, and a sensor in the input device of said control portion. <claim 11> An electric circuit using a conductor according to claim 3, formed on a flexible substrate/substrate, and used in a computer/radio type tag (2TAG) with wireless communication capability. <claim 6> A device for transmitting electric power using a conductor as claimed in claim 1 and claim 2, wherein said conductor containing a material having a lower specific gravity than copper or a carbon material or carbon nanotube CNT is used for said material portion 101 in order to reduce the weight of said device, and is used in a ground portion 14 and a space structure, space plane or portion of a space side orbital elevator, or an aerial aircraft, means of placement in the air, aerial platform, balloon, or rocket, and is capable of transmitting electric power between the ground portion and said space portion or said aerial portion. <claim 7> A device having the feature of forming a metallic film/atomic oxygen barrier film as a cover layer (e.g. 1COVER) on the surface of said material portion 101 in order to prevent a reaction between said material/carbon material and atomic oxygen present in outer space/low orbit or in the air/over the stratosphere, and to prevent damage to said conductor and deterioration of said material. The device according to claim 6 with said conductor (1WIRE). <A transmission device capable of transmitting electric power and energy from outer space to the terrestrial portion of the earth, using a photon generator (1) located in a satellite/space and a light receiving unit (2) located in the air that is capable of receiving photons irradiated/emitted from said photon generator (1). said transmission device including the steps/procedures of irradiating, emitting, relaying, transmitting and transmitting photons from said photon generating unit (1) to said light receiving unit (2), generating electric power using said photons received at said light receiving unit (2) and transmitting said electric power from said air to said ground via said conductor Said transmission device including the steps/procedures, wherein said photons are photons having the characteristics of reacting with and being absorbed by ozone, oxygen molecules, nitrogen molecules, atmospheric molecules, atmospheric atoms, and atmosphere. (<Claim 9> said transistor may be an electric double layer transistor)<Claim 10> lightning protection device using the device described in claim 6, wherein said conductor is placed so that it crosses the thundercloud 2THCL/charged atmosphere, or in the vicinity of the thundercloud, and the charge stored in the thundercloud/atmosphere is transmitted from said conductor to a ground area (or a place in the ionosphere or other atmosphere). (2) A lightning protection device and lightning protection method characterized in that it induces and transmits the electric charge stored in the thundercloud and atmosphere from the conductor to the ground (or to a place where the thundercloud charge can flow or escape, such as the ionosphere). < (A method of transmitting and transporting energy in the form of photons through space to celestial bodies, planets, satellites, and the earth equipped with atmospheric components and atomic molecules that react photonically to photons, comprising: a photon generator (1) located on a satellite or in space; and a lightning protection device (2) that is capable of receiving photons irradiated or emitted from said photon generator (1). The energy transport method using a photon generator (1) located in a satellite/space and a photon receiver (2) located at an altitude above the stratosphere or troposphere, which is capable of receiving photons irradiated/emitted from the photon generator (1), including the steps/procedures of irradiating, emitting, relaying, transmitting and transporting photons from the photon generator (1) to the photon receiver (2), wherein said photons are UV-B-B or photons of shorter wavelengths than 315 nm and 280 nm, said photons being photons having characteristics of being absorbed by ozone, oxygen molecules, oxygen atoms, nitrogen molecules and nitrogen atoms through photoreaction and chemical reaction. <A photon having a wavelength capable of causing a photodissociation reaction of oxygen molecules, a wavelength capable of dissociating oxygen molecules into oxygen atoms, or a wavelength shorter than 243 nm, said photon being a photon having a characteristic of being absorbed by oxygen molecules, oxygen atoms, nitrogen molecules, nitrogen atoms and photoreaction or chemical reaction, The energy transport method according to claim 12, wherein said photon is a photon with a wavelength that can cause a photodissociation reaction of nitrogen molecules, a photon with a wavelength that can dissociate nitrogen molecules into nitrogen atoms, or a photon with a wavelength shorter than 126 nm, and said photon has a characteristic of being absorbed by nitrogen molecules, nitrogen atoms and photoreaction/chemical reaction. <Claim 17> A method of reducing the resistivity of the atmosphere using the energy transport method described in claim 12, including a process of irradiating and firing a laser using photons in the wavelength range of X-rays and gamma rays from said light emitting unit 1 to a receiving unit 2 which is the atmosphere and thundercloud in the air, wherein said laser is A method of reducing atmospheric resistivity, wherein the laser has a path of travel across, through, or through the atmosphere/lightning cloud from the space side to the ground side, and ionizes oxygen molecules, ozone, and oxygen atoms, or nitrogen molecules, nitrogen atoms, and molecular atoms in the atmosphere in said path to form an ionized region/plasmaized region. The lightning protection method using the method of making the atmosphere low-resistance, which can form an electrically low-resistance area by ionizing oxygen molecules, ozone, oxygen atoms, or nitrogen molecules, nitrogen atoms, or molecular atoms in the atmosphere, and forming an ionized area or plasmaized area, and the first area where charge is accumulated in the atmosphere and upper layer of thundercloud, or the first area where positive charge is accumulated (LCP) and the second area where charge is accumulated in the atmosphere and lower layer of thundercloud, or the second area where negative charge is accumulated (LCM). The lightning protection method, wherein said low-resistance region is formed between the first region (LCP), in which a positive charge is accumulated, and the second region, in which an atmospheric/lightning cloud lower level charge is accumulated, or the second region (LCM), in which a negative charge is accumulated, thereby reducing the resistance of insulation between said first region and second region and inducing breakdown and short circuit between said first region and second region. <claim 16> (said method of energy transport using fuel material production and transport instead of using cables 12), wherein the energy is obtained using the method of energy transport described in claim 12 to obtain energy to a reactor, photocatalytic reactor, light reactor, chemical plant, aircraft, space plane, transport including light receiving part 2 or light receiving part 2 A substance production method for producing a fuel or substance from a raw material substance in a machine. *<Claim 14> <Claim 15> A transportation machine, aircraft, spacecraft, launch vehicle, launch device, space structure, spacecraft, spacecraft, equipped with said light-receiving part 2, which is driven, propelled, levitated, flown, moved, operated driven, propelled, levitated, flown or moved by obtaining energy using the energy transport method described in claim 12. Robot, manned humanoid robot, puppet device or apparatus. * * * * *

### <FIG. 29>

Example including the process of slowing down space muon SM1 or fast muons and irradiating and coupling them to the target atoms.

(A) A dome-shaped moderator array and moderator 2MUDECE covering the celestial sphere and the sky decelerate fast cosmic muons, capture them in the capture unit 2CAP, and irradiate the decelerated muons to T1 to attempt transmutation. (B) An example in which a laser is directly irradiated to the target T1 of raw material atoms and molecules to form an electric field 2LASER-EF and a laser wake field with intensity for deceleration of cosmic muons, the cosmic muons are decelerated by the electric field, and the decelerated muons are combined with raw material atoms to attempt muon nuclear fusion and muon Transmutation is attempted by combining the decelerated muons with raw material atoms.

<FIG. 29> (A) An example of a transmutation (or fusion) experiment in which a dome-shaped moderator array covering the celestial/upper sky side is used to decelerate a high-speed cosmic Muon and irradiate it to T1, as seen from T1 located on the ground side.

SM1: Cosmic muon (cosmic ray muon, cosmic ray muon particle) flying from the sky. High-speed cosmic muon SM1. Cosmic rays collide with the earth's atmosphere (atmosphere) and the cosmic ray pions/mesons are produced by the collision of atmospheric molecules and spacecraft particles, and cosmic ray muons are produced from these mesons. Cosmic ray pions can be produced at an altitude of about 20 km, and muons fall at an altitude of 5 km or lower.

(The aircraft transport equipment 3 with the system in FIG. 17 (a) is at an altitude to receive cosmic muons. Aircraft 3 can use the space muons for transmutation. Other transports 3 near the ground or at sea can also receive cosmic muons).

Cosmic rays: Particles flying through space with high energy.

M1: Muon.

MIL: decelerated muon, (muonic atom). Decelerated Muon MIL. Decelerated slow muon (MIL)

MDC-LASER: A laser source and laser generator for said accelerator when the muon moderator uses an accelerator with a laser wake field as the decelerator. The light source may use existing laser devices. The light source may use synchrotron radiation.

### MDC: Decelerator.

2MUDECE: Decelerator. Muon decelerator (accelerator may be used for deceleration) (Accelerator 2AC or A1 may be used for deceleration, which may be an accelerator using a laser wake field).

2MUDECE-ARRAY: Array of 2MUDECEs, which may have photons/lasers distributed to the 2MUDECEs. It may also include electrical, power, signal and laser circuits for driving the 2MUDECEs.

2MUCAP: MUON CAPTURE TRANSPORT Device, a device that captures and moves muons. Solenoid, etc.

T1: Target, FEED. According to one embodiment, the system 1F-SYS/1EXP-SYS may attempt to combine fuel and source atoms for muon catalytic fusion (or between source atoms) with muons decelerated by the moderator 2MUDECE in a configuration using muon Catalytic fusion or nuclear transmutation may also be attempted.

In addition, raw material atoms and fuel atoms of hydrogen, boron, carbon, nitrogen, etc. for fusion and transmutation described in this application may be used in the system 1F-SYS/1EXP-SYS shown in FIGS. 13(b) and (a).

The configuration, system, and equipment for decelerating space muons shown in FIG. 17 may be mounted on the transport device 3. If space muons can be used for muon transmutation, a large accelerator can be eliminated, and the size of the transport equipment 3 can be made more compact by eliminating the large accelerator for muon generation. To make the space muon muon decelerator compact, accelerators 2AC and A1, which can also be accelerators that use a laser wake field, can be used to decelerate the muons.

(The configuration that accelerates electrons and negatively charged particles to GeV class by a laser wake field is well known, and the application of this configuration is envisioned for decelerating negative muons, which are also negatively charged particles.)

In addition, for the purpose of compactly installing a muon meson generator and a fast muon decelerator in a transport device 3, a device 2MU, 2MESON-GENERATOR, or 2PARTICLE-COLLIDER for meson generation can be configured in an accelerator 2AC or A1, which can also be an accelerator using a laser wake field.

(B) Example of attempting muon fusion or muon transmutation of T1 by decelerating muons by irradiating a laser beam directly onto the target T1 of raw material atoms and molecules.

2LASER-PLASMA: Plasma generated by laser and T1 when T1 is plasmaized to form a laser wake field.

2LASER-EF: Electric field generated by laser and T1, laser wake field formed in T1.

T1, FEED: Target atoms, raw material atoms and fuel atoms to be transmuted and fused.

2LASER: Laser source.

MDC-LASER: A laser used in a laser using-type decelerator (in the figure, the laser can be generated by external energy or by generating photons and gamma rays using the energy of alpha and gamma rays from nuclear fusion and transmutation).

AEC: The AEC is the alpha ray energy converter, which can be extracted as photon energy from the alpha ray bremsstrahlung.)

(B) 2LASER-EF: Laser wake field LWF and electric field 2LASER-EF formation formed by laser. Electric field decelerating muons.

2LASER-PLASMA: Plasma created by irradiating a laser onto T1, which may contain T1 and may be coupled to T1, which is also plasma, after decelerating muons.

SM1: Space muon, space muon source

M1: Muon, muon source

MIF: Fast muon

MIL: Decelerated muon

As a matter of public knowledge, tauon can make muon.

### <Velocity of Muons>

Cosmic rays contain muons, whose energy is in the GeV range, and the speed of cosmic muons is high (close to the speed of light). (close to the speed of light)

It is thought that cosmic muons are faster than muons produced on the ground or in known accelerators and muon generators. Assuming that a muon particle is moving at the speed of light c, it is said to travel about 660 meters in 2.2 microseconds. Cosmic space muons are too energetic to pass through matter.

Since the muons used in this application are to be bound to the raw material atoms, it is preferable to use a configuration that allows them to be bound at low speed rather than a configuration that allows them to pass through the raw material atoms at high speed.

For example, the muon used in this application may need to be slower than the space muon.

Muons such as carbon-12 may be irradiated and bound to the atoms to be transmuted at low speed and at a speed that allows binding.

On the earth's surface, about 170 fast muon particles of cosmic origin pass over an area of 1 m2 per second. Even if (hypothetically) fast muons want to transmute or fuse nuclei to be transmuted by muon-catalyzed fusion, such as boron, carbon, nitrogen, etc., space muons pass through them at high speed, so natural, fast cosmic space muons may be unlikely to cause muon-catalyzed fusion or Therefore, muon-catalyzed nuclear fusion and muon-catalyzed nuclear transmutation, which are intended in this application, may not occur easily with natural and fast space muons. Therefore, in this application, muons that are slow enough to cause muon-catalyzed transmutation and muon-catalyzed fusion (obtained from mesons, pions, etc. that can be produced by known ground-based devices that can produce mesons) may be used, even if they are slowed down.

### <Muon Transmutation System Using a Cosmic Space Muon Decelerator >

Muons are obtained from a meson generator, but then the muons are deceleration using a device section/unit/device MUDECE (2MUDECE, 2MUDECE-ARRAY) that decelerates the muon, and muon catalytic transmutation and fusion are desired to be performed. (The muons may be injected into atoms.) The cosmic space muons may then be used in the muon-catalyzed transmutation and fusion system of the present application if they can be decelerated.

Muon moderators/decelerator that combine negative muons with a pulsed power supply and a moderator cell have been considered and are public knowledge.

A huge aircraft/airship such as an airship (which can easily take the physical distance for muon deceleration) is floated in the air, a muon decelerator of a large scale is configured and installed in the aircraft to decelerate muons, muons are captured and transported by solenoids, etc., and irradiated to the target area of the muon catalytic transmutation, The energy generated by the transmutation may be used to propel the aircraft, and the aircraft's energy and power may be generated and supplied using a power generation unit (power generation unit 1PP, which converts alpha ray energy into heat to boil water to drive a steam turbine, or AEC, which converts alpha ray energy into power and energy). The power may be generated and supplied using requirements for laser wake fields for muon deceleration and acceleration cavities/accelerators using the laser wake fields.

The laser wake field and the acceleration cavity/accelerator using the laser wake field can accelerate electrons (negative muons), but the accelerator can also be used to decelerate negative muons (MUDECE (2MUDECE, 2MUDECE-ARRAY)) (if possible, by placing it in the direction to decelerate the advancing negative muons). The accelerator with a laser wake field may be used in a MUDECE.

The accelerator using a laser wakefield has a plasma device section that plasmaizes a laser target and generates an electric field due to laser irradiation.

The electric field intensity of the laser wakefield accelerator will be higher than that of existing accelerators that generate electric and magnetic fields using magnets and radiofrequency waves, and it is expected that the accelerator will be smaller than existing accelerators that use radiofrequency waves and electromagnets for particle acceleration.

As shown in FIG. 29 (a), (example), a space muon decelerator array 2MUDECE-ARRAY may be configured to cover all directions and celestial spheres in the air from the ground by making 2MUDECE smaller. Then, it may be possible to configure 3 transport devices including the transmutation system 1EXP-SYS including 2MUDECE-ARRAY and the power generation unit 1GENR including it.

A muon decelerator array that covers the target section T1 in a dome-like shape may be configured to randomly fly or fly towards 2MUDECE-ARRAY and T1 at various angles from the air to the ground side (e.g., the two space muons in (A) in Figure/FIG. 29), in advance of the space muons The application may be able to decelerate the space muons by the aforementioned decelerator array installed, and collect the decelerated muons to inject and irradiate them into the target section T1.

The slow muons may be coupled to the raw material atoms in the T1 section concerned to encourage fusion and transmutation of the raw material atoms in T1.

As shown in FIG. 29 (b), a laser is irradiated from the 2LASER/MDC-LASER laser source to the target T1 to generate plasma (2LASER-PLASMA) in T1, and a high intensity electric field 2LASER-E F, and laser wake field 2LASER-EF are generated and formed, and the electric field 2LASER-EF decelerates fast muons or fast space muons SM1 injected into T1 and into 2LASER-EF, (2 The decelerated muon is then bound to the source atom in T1 to which the muon is to be bound, and the muon binding can cause a muon transmutation reaction or muon fusion in the source atom of T1. Therefore, said configuration may be used in the present application.

The target atom T1 may be irradiated with a laser to form an electric field that decelerates the fast muon, fast space muon SM1, or muon M1, which decelerates the fast muon into a slow muon, and the slow muon may be used for transmutation and fusion of the target atom T1.

### <Prevent Explosive Transmutation>

By controlling the ratio of carbon 12 (or carbon isotope A), which is the raw material atom and transmutation fuel atom of muon transmutation (muon catalytic transmutation), and carbon 13 (isotope B mentioned above), which is the catalytic poison atom of muon transmutation (muon catalytic transmutation), in the carbon target T1, the muon transmutation (Since it may be possible to change the number of catalytic reactions/reaction cycles of muon catalytic transmutation, it is good to be able to control the proportion of carbon 12 (or carbon isotope A) and carbon 13 (isotope B mentioned above) in the carbon target in the present application.

According to the present application, when I/we want to prevent explosive transmutation and have a controlled reaction for power generation, we will be able to introduce and dope atoms that will serve as a controlled stopping point for the reaction.

(The transmutation of transmutation feedstock atoms can be controlled by doping atoms that inhibit transmutation, as in the relationship between nuclear fuel and control rods in a fission reactor).

### <Control Rods and Control Grids for Muon Fusion (if Needed)>

Given that control rods are known to control fission reactions by moderating neutrons in fission reactors, control grids may be inserted and removed as necessary to provide an additional muon trap made of heavy elements and high-Z atoms between the moderator and the fuel. It is not always possible to control the muon fusion reaction only by controlling the decelerating/moderating operation of the decelerator that decelerates the muons when negative muons are irradiated from outside for some reason or when the number of cosmic ray-derived negative muons increases due to cosmic ray activity conditions.

When space muons increase due to increased solar wind or solar activity, or when muons are introduced from outside due to accidents, control rod devices may be inserted in addition to electric field generation devices to try to control the reaction so that the transmutation system does not transmute too many muons.

### <Requirements for Laser Wake Fields for Muon Deceleration and Acceleration Cavities/Accelerators Using the Laser Wake Fields>

The laser wake field and the acceleration cavity/accelerator using the laser wake field can accelerate electrons (negative muons), but the acceleration cavity/accelerator can also be used as a negative muon deceleration unit (MUDECE (2MUDECE, 2MUDECE-ARRAY), if possible, by placing it in the direction to decelerate the advancing negative muons. It may also be used in the laser wakefield accelerator has a plasma device section that plasmaizes a helium laser target and generates an electric field by laser irradiation.

The electric field strength of the laser wakefield accelerator is higher than that of existing accelerators that generate electric and magnetic fields using magnets and radiofrequency waves, and it is expected that the accelerator can be made smaller than existing accelerators that use radiofrequency waves and electromagnets for particle acceleration.

(As shown in (A) in FIG. 29, a space muon moderator array 2MUDECE-ARRAY, which covers the entire sky and celestial sphere from the ground, could be constructed by downsizing 2MUDECE. Then, it may be possible to configure a nuclear transmutation system 1EXP-SYS including 2MUDECE-ARRAY and a transportation device 3 including a power generation unit 1GENR including it. By configuring a muon moderator array that covers the target section T1 like a dome, the space muons that randomly fly and come toward 2MUDECE-ARRAY and T1 at various angles from the air to the ground side are decelerated by the aforementioned moderator array installed in advance and the decelerated muons are collected and transported to the target. The present invention could make it possible to collect the muons and inject and irradiate them into the target section T1).

As shown in (b) of FIG. 29, a laser is irradiated from the 2LASER/MDC-LASER laser source to the target T1 to generate plasma (2LASER-PLASMA) in T1, and a high intensity electric field 2LASER-E F and laser wake field 2LASER-EF are generated and formed, and the electric field 2LASER-EF slows down fast muons or fast space muons SM1 injected into T1 and into 2LASER-EF (2 The slow muon or decelerate muon is then bound to the source atom in T1 to which the muon is to be bound, and the muon binding can cause a muon transmutation reaction or muon fusion in the source atom of T1. Therefore, said configuration may be used in the present application.

The target atom T1 may be irradiated by a laser to form an electric field that decelerates the fast muon, fast cosmic space muon SM1, or muon M1, and the fast muon is decelerated to a slow muon, and the slow muon may be used for transmutation and fusion of the target atom T1.

### <FIG. 30>

2MU, 2MESON-GENERATOR, 2PARTICLE-COLLIDER: Means of muon generation, meson generation, and particle collision.

MUON-CAPTURE-TRANSPORT-SOLENOID: means to capture and transport muon from mesons such as pions and K mesons. A solenoid that traps pions by magnetic field, moves pions, and transports muons while pions change into muons.

MUDECE: Means of decelerating muon. Negative muon decelerator. A low-speed muon generator; MUDECE may be provided in the MUON-CAPTURE-TRANSPORT-SOLENOID portion. Negative muon decelerators combining a pulse power supply and a deceleration cell have been studied and are known, and may be used. It is preferable to use a negative muon decelerator that can decelerate to a lower speed. The energy of the negative muon generated by the accelerator and meson generator should be about 300 keV (=8 MeV/c) or higher, and it is desirable to be able to decelerate it to 30 keV or lower, for example. The laser wake field and the acceleration cavity/accelerator section using the laser wake field may be placed in the opposite or decelerating direction if possible, and used to decelerate the negative muon.

1F-SYS: fusion system using muon

1EXP-SYS: Experimental system using muon, transmutation system (transmutation system for LLFP and MA)

FP: fusion section, muonfusion section, part of fusion section core.

NCTP: transmutation section, muontransmutation section, part of transmutation core.

Muonic-Atom-Generator: A part that generates muonic atoms A (or B) by binding negative muon to nucleus A (or B).

MA1: Muonic atom A (or B). (Atom A/B irradiated to the target)

FUSIONED-T1-AB-X: Atom X. Atom X produced by fusion/transmutation of nuclei A and B by muon.

T1-AB: Target T1 part of muon consisting of a compound/mixture of nuclei A and B bound together.

Atoms A and B can be different in Z. They can also be the same in Z. T1-AB is a compound or mixture of nuclei A and B. T1-AB can be a mixture of atoms A and B by colliding atom A with atom B or A and B in close proximity.

FUSIONED-T1-MA1B-X: Atom X, produced by fusion/transmutation of muonic atoms A and B by muon; atom Y may be produced from atom X via a radioactive decay process.

T1-B: Target for nucleus B (or A); T1-B is the muon/muonic atom irradiation part is movable T1 and T1-B. (T1-B can be a movable T1 film surface or solid liquid surface. can also be a film surface or a solid liquid surface. (T1-B can be a film surface of a movable T1 or a solid liquid surface, or a gas or plasma beam, depending on the element).

(The muon target MU-DISK-TGT, which may be the solid movable disk type shown in FIG. 11, is ground with the grinding wheel MU-DISK-GRINDING-DEVICE. (Atom X may be produced from atom A and atom B on target T1 with muontransmutation and then removed and recovered with a grinding wheel or other grinding or cutting means.)

T1-IN: Atom supply process/means. Supply section for atoms A and B.

T1-OUT: Atom removal process/means. Atom X removal section.

### <Example of Radioactive Element Conversion>

system may be used to convert high-level waste wastes and atoms generated by driving fission reactors and other nuclear reactors into lower-level radioactive atoms.

Using this application system, fission products (Long-Lived-Fission-Products (LLFPs) such as 79Se and 93Zr, which have a long life of several thousand years or more, and Am, Cm, and Np, minor Actinides (Minor-Actinide: MA), such as Am, Cm, and Np, may be irradiated with muons.

Muon irradiation may be performed in inaccessible areas due to high-energy waste, in nuclear reactors under decommissioning, in nuclear reactors, and in nuclear reactors containing nuclear fuel debris to transmute the nuclei in the waste.

Although this application/proposal is an idea and it is not clear whether it can be implemented in practice or not, muons can be generated using a muon generator and directed to a reactor or a building section (nuclear fuel debris section/building in a nuclear reactor) that contains inaccessible nuclear fuel debris due to radioactive waste deposited by accidents, etc. (from said section, the muons can be irradiated to the nuclear fuel debris section in a nuclear reactor). An attempt may be made to transmute LLFPs and other materials in the fuel debris by irradiating them (from a meson-producing launch site, which may be located at a remote site).

### <Ionization Cooling>

Ionization cooling may be used to decelerate negative muons. Ionization cooling is based on a properly prepared muon beam passing through an appropriate material (absorber) and losing momentum/decelerating due to ionization.

The use of absorbers made of hydrogen or lithium, which are atoms with low atomic number Z, is preferred. Cooling with absorbers of both liquid hydrogen and lithium hydride is known according to the following literature1. (Ref. 1: International Muon Ionization Cooling Experiment MICE collaboration, Nature volume 578, pages 53-59 (2020))

A portion of a solenoid cooling and deceleration channel is constructed and operated to cool and decelerate muon ionization using both liquid hydrogen and a lithium hydride absorber.

*It may be possible to use a target part T1 that wants to have muon fusion and transmutation of atoms with low atomic number Z in the absorber, such as azan containing nitrogen 15 and hydrogen or borane containing boron and hydrogen (such as carbon 12) that will bind muons and promote transmutation in this application.

*Muons may be combined with hydrogen ions and decelerated into muonic atoms.

Muons may be combined with boron, nitrogen, or other atoms heavier than hydrogen to make muonic boron atoms, muonic nitrogen atoms MP1, MA1, etc. (MP1 and MA1 are decelerated) and then fed into the fuel material target section T1 containing hydrogen. (In the configuration of B in FIG. 16, the muonic atom MA1 of atom A may be formed, and MA1 may be decelerated by means of some electric field (magnetic field), and then MA1 may be irradiated, injected, and collided with the target section T1-B, which may contain atom B for fusion and transmutation, to cause muon fusion and transmutation. Frictional Cooling

### <Frictional Cooling>

A carbon film may be placed on the target section T1, which is irradiated with negative muons, and the muons may be decelerated by friction (frictional deceleration and frictional cooling) as they pass through the carbon film with velocity. The muon may be decelerated by a carbon film containing carbon-12 (or a frictionally cooled carbon film consisting of carbon-12) for frictional cooling (frictional deceleration), or the muon decelerated in that carbon film may combine with carbon-12, and then carbon-12 may be transmuted by muon transmutation.

In addition to the carbon film, solid/liquid parts that can be T1/FEED with low Z, such as boron hydride, can also be considered, including elements such as hydrogen with low Z. The ionization cooling effect can also be used.

### <Moderator Using a Moderating Cavity>

The configuration using a pulse power supply and decelerating cell described in the following reference is well known and may be used for the muon decelerator in this application. (References: Proceedings of the 16th Annual Meeting of the Particle Accelerator Society of Japan Jul. 31-Aug. 3, 2019, Kyoto, Japan, PASJ2019 FRPI 008)

### <Muon Decelerator Using a Pulsed Laser>

FIG. 29A shows the muon moderator 2MUDECE and the transmutation system 1EXP-SYS using a laser wake field with a pulsed laser.

*One form of this application is to implement a configuration that can irradiate a pulsed laser capable of forming a laser wake field or an electric field to a target section T1. The aforementioned T1 can be a fusion or transmutation target. According to one form, a fusion/transmutation system may use atoms with a small atomic number Z, such as carbon, nitrogen, boron, and hydrogen, as T1.

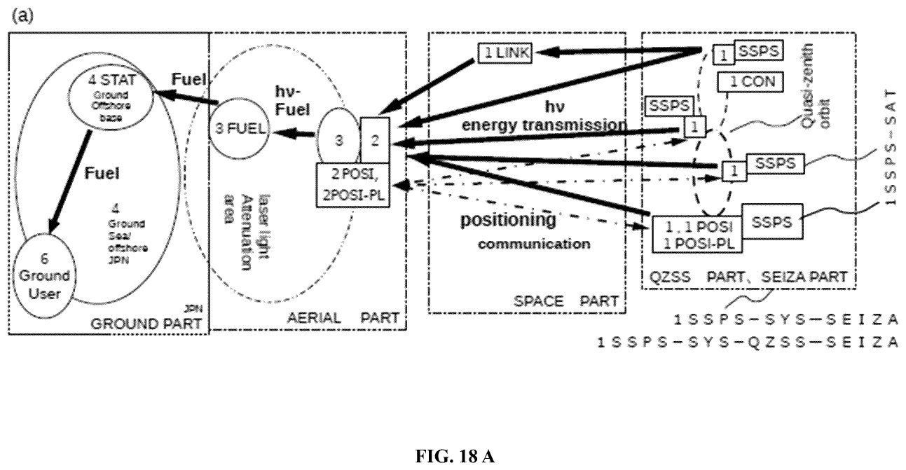

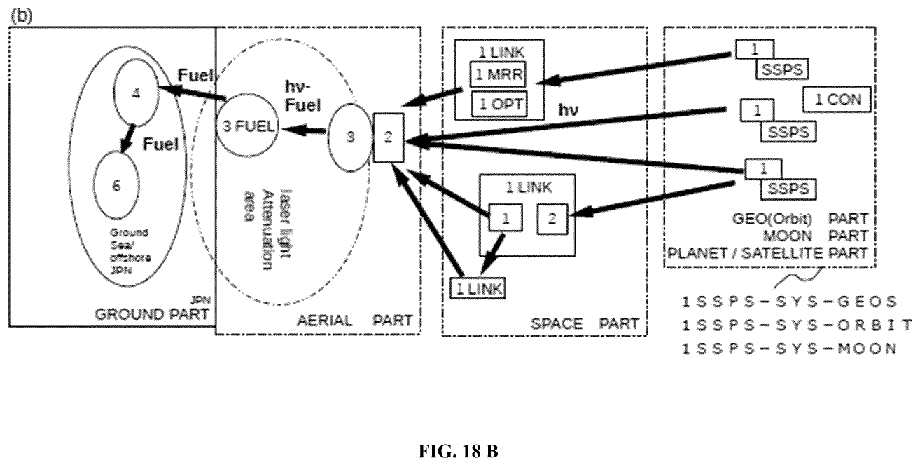

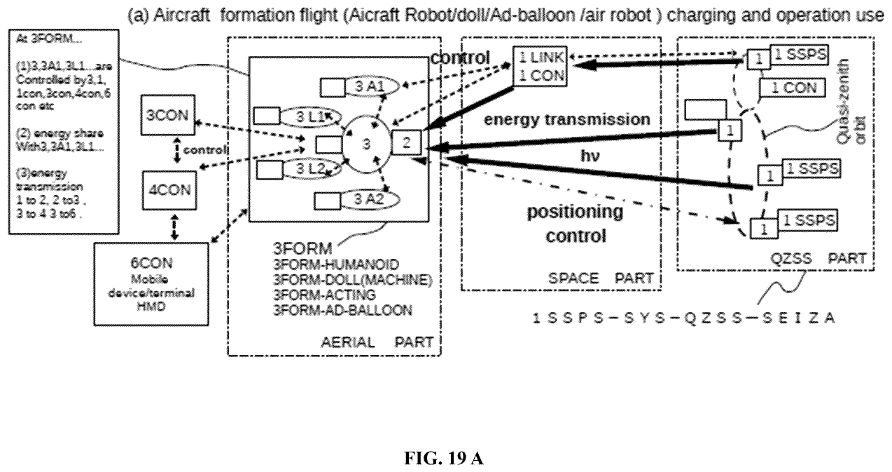

In a muon-catalyzed fusion reaction between hydrogen atoms (H, D, T), for example, helium is generated and muons are trapped in the helium, stopping the catalytic fusion reaction, but the energy generated by the fusion of hydrogen atoms exceeds the energy available from obtaining and using cosmic rays and cosmic muons from nature. Therefore, it may be possible to attempt fusion of hydrogen atoms in the system 1EXP-SYS, which has a part to decelerate cosmic muons, such as shown in FIG. 18, or in the structure 3 or transportation equipment 3 that includes the system.

(* Although the configuration described above decelerates the muons using an electric field, it is possible to change the orbit of the fast muons using a magnetic field. Muons may be injected into the target section T1 by combining an electric field for decelerating and a magnetic field for decelerating and changing the orbit.)

<Muon Decelerator Using an Element that Generates an Electric Field>

The device may be capable of applying a pulse voltage/potential difference between the electrodes at the power supply unit so that the electric field can be generated in pulses.

### (Related Applications, Incorporation by Reference)

“This application claims the benefit of foreign priority to Japanese Patent Application No. JP2022-086263, filed May 26, 2022, which is incorporated by reference in its entirety.”

“This application claims the benefit of foreign priority to Japanese Patent Application No. JP2022-181631, filed Nov. 14, 2022, which is incorporated by reference in its entirety.”

“This application claims the benefit of foreign priority to Japanese Patent Application No. JP2022-123161, filed Aug. 2, 2022, which is incorporated by reference in its entirety.”

“This application claims the benefit of foreign priority to Japanese Patent Application No. JP2023-007722, filed Jan. 22, 2023, which is incorporated by reference in its entirety.”

“This application claims the benefit of foreign priority to Japanese Patent Application No. JP2023-063114, filed Apr. 9, 2023, which is incorporated by reference in its entirety.”

“This application claims the benefit of foreign priority to PCT Application No. PCT/JP2023/016185, filed Apr. 24, 2023, which is incorporated by reference in its entirety.”

“This application claims the benefit of foreign priority to PCT Application No. PCT/JP2023/017215, filed May 7, 2023, which is incorporated by reference in its entirety.”

“This application claims the benefit of foreign priority to Japanese Patent Application No. JP2024-058388, filed Mar. 31, 2024, which is incorporated by reference in its entirety.”

“This application claims the benefit of foreign priority to Japanese Patent Application No. JP2024-065053, filed Apr. 14, 2024, which is incorporated by reference in its entirety.”

“This application claims the benefit of foreign priority to Japanese Patent Application No. JP2024-072096, filed Apr. 26, 2024, which is incorporated by reference in its entirety.”

“This application claims the benefit of foreign priority to PCT Application No. PCT/JP2024/016620, filed Apr. 28, 2024, which is incorporated by reference in its entirety.”

“This application claims the benefit of foreign priority to Japanese Patent Application No. JP2024-082974, filed May 22, 2024, which is incorporated by reference in its entirety.”

“This application claims the benefit of foreign priority to Japanese Patent Application No. JP2024-123704, filed Jul. 30, 2024, which is incorporated by reference in its entirety.”

“This application claims the benefit of foreign priority to PCT Application No. PCT/JP2024/033185, filed Sep. 18, 2024, which is incorporated by reference in its entirety.”

“This application claims the benefit of foreign priority to Japanese Patent Application No. JP2024-175429, filed Oct. 6, 2024, which is incorporated by reference in its entirety.”

“This application claims the benefit of foreign priority to Japanese Patent Application No. JP2024-122912, filed Jul. 29, 2024, which is incorporated by reference in its entirety.”

“This application claims the benefit of foreign priority to Japanese Patent Application No. JP2024-011380, filed Jan. 29, 2024, which is incorporated by reference in its entirety.”

“This application claims the benefit of foreign priority to Japanese Patent Application No. JP2023-150635, filed Sep. 18, 2023, which is incorporated by reference in its entirety.”

“This application claims the benefit of foreign priority to Japanese Patent Application No. JP2023-151787, filed Sep. 19, 2023, which is incorporated by reference in its entirety.”

“This application claims the benefit of foreign priority to Japanese Patent Application No. JP2023-174791, filed Oct. 6, 2023, which is incorporated by reference in its entirety.”

“This application claims the benefit of foreign priority to Japanese Patent Application No. JP2023-174037, filed Oct. 6, 2023, which is incorporated by reference in its entirety.”

“This application claims the benefit of foreign priority to Japanese Patent Application No. JP2023-174180, filed Oct. 6, 2023, which is incorporated by reference in its entirety.”

“This application claims the benefit of foreign priority to Japanese Patent Application No. JP2023-196029, filed Nov. 17, 2023, which is incorporated by reference in its entirety.”

“This application claims the benefit of foreign priority to Japanese Patent Application No. JP2023-196327, filed Nov. 19, 2023, which is incorporated by reference in its entirety.”

What is claimed is:

1-18. (canceled)

19. An element comprising:
The element capable of charging a capacitor portion composed of an insulator, a material portion, and a gate electrode of the transistor by a voltage applied to the gate electrode.
The element capable of forming a carrier introduction portion (104) in a material portion (101) by applying a voltage (VGS) between a first electrode (106) and a second electrode (102), thereby changing the conductivity of the material portion (101) including the carrier introduction portion (104).
The material portion (101) of the element including a channel portion of a transistor and the carrier introduction portion (104).
The first electrode (106) of the element is the gate electrode (106) of the transistor.
The second electrode (102) of the element is the source electrode (102) of the transistor.
The element has the feature that the capacitor portion composed of the insulator (105), the material portion (101) and the gate electrode (106) of the transistor can be charged by the voltage (VGS) applied to the gate electrode (106).
The Conductor element using the elements.

20. An element according to claim 1, further comprising:
The element in which a capacitor portion comprising an insulator, a material portion and a gate electrode of the transistor can be charged by a voltage applied to the gate electrode.
The element wherein the material portion has a comb shape, a porous film, or a space that is a gap relative to the total volume of the material portion, or wherein the surface area of the interface between the material portion and the insulator in contact is larger than the total area of the material portion.
The Conductor element using the elements.

21. An element according to claim 1, further comprising:
An element in which a carrier introduction area is formed in a metallic film by applying a voltage between a first electrode and a second electrode, and in which the conductivity of the metallic film including the carrier introduction area is changeable,
the metallic film of the element includes a channel portion of an electric double layer transistor and the carrier introduction portion includes the channel portion,
the first electrode of the element is the gate electrode of the electric double layer transistor, and the second electrode of the conducting element is the source electrode of the electric double layer transistor,
the element having the feature that the capacitor portion composed of the insulator containing the ionic liquid of the electric double layer transistor,
the metallic film and the gate electrode can be charged by the voltage applied to the gate electrode,
The charge carriers of the metal film are conduction electrons of the metal film, the metallic film is deposited or deposited on the material portion to cover the surface of the material portion,
the conductor element comprising the metallic film contacting/touching the insulator, the metal film and the insulator contacting/touching each other, having the feature that when charging the capacitor portion, an anion or negative charge is introduced or arranged on the insulator side and a positive charge is introduced on the metal film side,
An element having the feature that the carrier introduction part is the part where the positive charge is introduced into the metallic film.

22. An element according to claim 1, further comprising:
The element included in electrode of battery.
The element connected in control unit of battery.
The element conductivity can be changeable by using gate electrode (106) voltage controlled by the control unit.
The Conductor element using the elements.

23. A device comprising:
The device that using a photon/particle emitting/moving unit (1).

6. A device according to claim 5, further comprising:
The device accelerates projectile or load using recoil or reaction that moves, or emits, or reflects the photon/particle.

24. A device according to claim 6, further comprising:
The device accelerates centrifugal gun/launcher projectile or load using recoil or reaction that moves, or emits, or reflects the photon/particle.

25. A device according to claim 5, further comprising:
The device using photon/particle beam generating/emitting unit (1).
The receiving section (2) is the atmosphere or thundercloud in the air.
The device includes the beam has a beam travel path that goes through the atmosphere or thunderclouds from the space side toward the ground side.

26. A device according to claim 5, further comprising:
The device that using a photon emitting unit (1).
The device include low volatility or non-volatile liquid (NVLQ).
The liquid (NVLQ) can be inserted, placed, immersed, or filled between the photon irradiating section and the light receiving section (2).

27. A device according to claim 5, further comprising:
The device that using a photon emitting unit (1).
The device that using a photon receiving section (2).
The receiving section (2) is nitrogen molecules or atoms.
The photon has the characteristic of being absorbed by nitrogen molecules or atoms or molecules containing nitrogen through reactions or photo chemical reactions.

28. A device according to claim 5, further comprising:
The device that using a photon emitting unit (1).
The device that using a photon receiving section (2).
The photon has the characteristic of being absorbed by the oxygen or nitrogen or atmosphere or gas molecules or atoms through reactions or photo chemical reactions.
The device that using a photon beam or laser beam emitting unit (1).
The photon receiving section (2) is placed in the space or outer space or stratosphere or the photon reachable aerial or space.
The device used beam energy transportation or space solar beam energy transportation.
The device charge electric power or get the photon energy by receive the photon at the photon receiving section (2) from the emitting unit (1).

29. A device comprising:
The device include particle emitter or particle generator or particle.
The device include particle receiver.
The device include decelerator or accelerator.

30. A device according to claim 12, further comprising:
The device include particle emitter or particle generator.
The device include muon particle receiver.
The device used beacon/communication/measurement/transmutation.
The particle receiver include raw material atoms.
The device capable of coupling/bonding the muon or tauon particles to the raw material atoms to be transmuted.

31. A device according to claim 12, further comprising:
The particle receiver include raw material atoms.
The device having the feature that muon particles, or tauon particles, can be decelerated using the decelerator,
The device capable of coupling/bonding the muon particles, or tauon particles, decelerated by the decelerator to the raw material atoms to be transmuted,
The device using the decelerator having a feature that enables the muon particles to be decelerated in the decelerator.
The decelerator use a laser wake field, or field, or by means of an electric field or magnetic field.

32. A device according to claim 14, further comprising:
The decelerator use by means of a laser wake field, or by means of an electric field.

33. A device according to claim 14, further comprising:
The particle is cosmic ray muon particles.
The device having the feature that the muon particles is produced using cosmic rays, or the muon particles is cosmic ray muon particles.

34. A device according to claim 14, further comprising:
The device use by means of an electric field.
The alpha/charged particles that generated/produced by the transmutation can be moved using electric field, or electrodes, or by means of an electric field.

35. A device according to claim 17, further comprising:
The power generator device include the device.
The alpha/charged particles that generated/produced by the transmutation can be moved using the electric field.
The alpha/charged particles that generated/produced by the transmutation move to gas or fluid or wall or metal wall or iron wall or metal or electrodes or metal/iron walls of hole/cup/pot/container/vessel.
The alpha/charged particles created/generated/produced by transmutation heat gases or fluids, or heat walls or metal walls or iron walls or metal walls of hole/cup/pot/container/vessel or heat electrodes as the particles move/collide with walls or metal walls or iron walls or electrodes.
The device can provide heated gases or fluids.
The device is equipped with a heat exchanger.

36. A device according to claim 14, further comprising:
The device having the feature that the muon particles can be bonded to atoms of plasma or liquid or gas or fluid or solid or material or textile or tissues or fiber or net or film or substrate or disk or target or plate or board or cup or waste or radioactive material,
The transmutation produces atoms with changed atomic numbers from the raw material atoms.

37. A device according to claim 14, further comprising:
The device having the feature that the muon particles can be bonded to atoms of liquid or gas or fluid or solid or material or target, or portion that want to remove, or lesion portion,
or portion of living thing
or brain/nervous system, organs, bones/teeth, internal substances/tissues
or cancer portion
or lesion protein portion in nerves or lesion portion in nerves,
or lesion portion in head/brain/nerves,
or radioactive waste or radioactive material,
The transmutation produces atoms with changed atomic numbers from the raw material atoms.
